(19) United States
(12) Patent Application Publication
(10) Pub. No.: US 2026/0242537 A1
(43) Pub. Date: Aug. 20, 2026

(54) POLYMER, FILM, COMPOSITION, INK, ELECTRONIC ELEMENT, PHOTOELECTRIC CONVERSION ELEMENT, SOLAR CELL MODULE, AND IMAGE SENSOR

(71) Applicant: SUMITOMO CHEMICAL COMPANY, LIMITED, Tokyo (JP)

(72) Inventors: Tomoya KASHIKI, Osaka-shi (JP); Daisuke INOKUCHI, Niihama-shi (JP); Giovanni FERRARA, Tokyo (JP); Tomoya NAKATANI, Tsukuba-shi (JP); Takashi YAMADA, Tsukuba-shi (JP); Yuki YOKOI, Osaka-shi (JP); Takafumi ARAKI, Osaka-shi (JP)

(73) Assignee: SUMITOMO CHEMICAL COMPANY, LIMITED, Tokyo (JP)

(21) Appl. No.: 19/117,527

(22) PCT Filed: Sep. 21, 2023
(86) PCT No.: PCT/JP2023/034319

§ 371 Date: Apr. 1, 2025

(30) Foreign Application Priority Data
Oct. 6, 2022 (JP) 2022-161969

(51) Int. Cl. C08G 61/12; C09D 5/24; C09D 11/102; H10K 39/10; H10K 39/32

(52) U.S. Cl. CPC C08G 61/12; C09D 5/24; C09D 11/102; H10K 39/10; H10K 39/32

(57) ABSTRACT

Provided is a polymer that suppresses dark current in a photoelectric conversion element.

A polymer contains a structural unit having a main chain and a side chain, a weighted average of formula weights of the side chains weighted by a molar ratio of the structural units contained in the polymer is 160 or more, and an absorption edge intensity is 0.08 or less.

### TECHNICAL FIELD

The present disclosure relates to a polymer, a film, a composition, an ink, an electronic element, a photoelectric conversion element, a solar cell module, and an image sensor.

### BACKGROUND ART

Non-Patent Document 1 discloses a photodetection element using PTB7 as a polymer.

### PRIOR ART DOCUMENT

### Non-Patent Document

Non-Patent Document 1: Tiening, W.; Yue, W.; Lijie, Z.; Longfeng, L.; Yufeng, H.; Zhenbo, D.; Qiuhng, C.; Zhidong, L.; Yanbing, H.; Feng, T. Organic Electronics. 2019, 138-145.

### SUMMARY OF THE INVENTION

### Problems to be Solved by the Invention

A photoelectric conversion element is, for example, an extremely useful device from the viewpoint of energy saving and reduction of a carbon dioxide emission amount, and has attracted attention. Therefore, a polymer and the like applicable to the photoelectric conversion element are also attracting attention.

The photoelectric conversion element is an element including at least a pair of electrodes including an anode and a cathode, and an active layer provided between the pair of electrodes. In the photoelectric conversion element, any one of the electrodes is formed of a transparent or translucent material, and light is incident on the active layer from the transparent or translucent electrode side. Charges (holes and electrons) are generated in the active layer by energy (hν) of light incident on the active layer, the generated holes move toward the anode, and the electrons move toward the cathode.

Then, the charges that have reached the anode and the cathode are taken out to the outside of the element.

The photoelectric conversion element is used as, for example, a photodetection element. The photoelectric conversion element used as a photodetection element is used in a state where a voltage is applied, and light incident on the element is converted and detected as a current. However, even in a state where no light is incident, a weak current flows through the photoelectric conversion element. The current is known as dark current, and is a factor that lowers the accuracy of photodetection.

For this reason, it is required to suppress dark current in the photoelectric conversion element.

A problem to be solved by an embodiment of the present disclosure is to provide a polymer that suppresses dark current in a photoelectric conversion element.

A problem to be solved by another embodiment of the present disclosure is to provide a film and a composition containing the polymer according to the present disclosure.

A problem to be solved by still another embodiment of the present disclosure is to provide an ink containing the polymer according to the present disclosure.

A problem to be solved by still another embodiment of the present disclosure is to provide an electronic element containing the polymer according to the present disclosure.

A problem to be solved by still another embodiment of the present disclosure is to provide a photoelectric conversion element that suppresses dark current.

A problem to be solved by still another embodiment of the present disclosure is to provide a solar cell module including the photoelectric conversion element according to the present disclosure.

A problem to be solved by still another embodiment of the present disclosure is to provide an image sensor including the photoelectric conversion element according to the present disclosure.

### Means for Solving the Problems

Means for solving the above problems includes the following means.
<1> A polymer containing a structural unit having a main chain and a side chain,
in which a weighted average of formula weights of the side chains weighted by a molar ratio of the structural units contained in the polymer is 160 or more, and
an absorption edge intensity is 0.08 or less.
<2> The polymer according to <1>, in which the side chain is at least one selected from the group consisting of an alkyl group optionally having a substituent, an aryl group optionally having a substituent, and a monovalent heterocyclic group optionally having a substituent.
<3> The polymer according to <1>, in which the polymer contains at least one selected from the group consisting of a structural unit represented by the following Formula (I) and a structural unit represented by the following Formula (Y1).

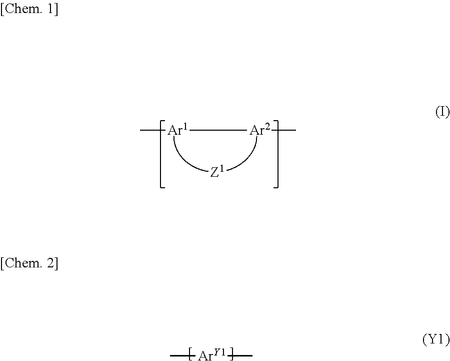

(in Formula (I),
Z¹ is a divalent group,
Ar¹ and Ar² each independently represent a trivalent aromatic hydrocarbon ring group or a trivalent heterocyclic group, and
in Formula (Y1), Ar^{Y1} represents an arylene group, a divalent heterocyclic group, or a divalent group in which an arylene group and a divalent heterocyclic group are bonded, and these groups optionally have a substituent.)
<4> The polymer according to <3>, in which the polymer contains two different types of structural units represented by Formula (I). <5> The polymer according to <3> or <4>, in which in the structural unit represented by Formula (I), Z¹ is a group represented by the following Formula (Z-1), the following Formula (Z-2), the following Formula (Z-3), the following Formula (Z-4), the following Formula (Z-5), the following Formula (Z-6), or the following Formula (Z-7).

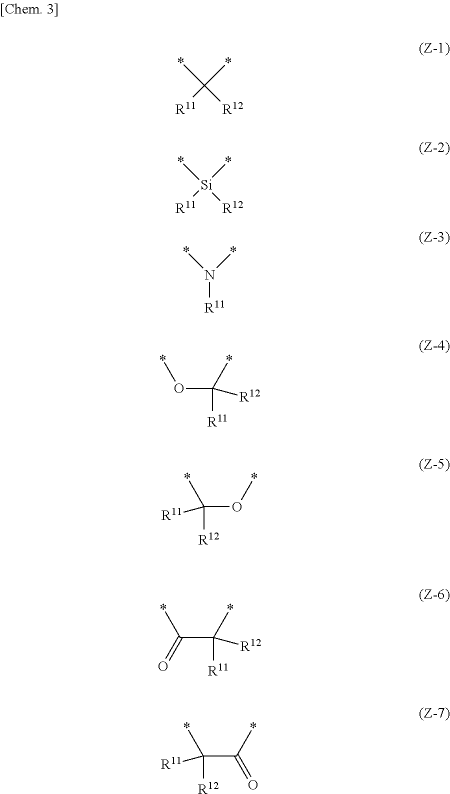

(in Formulas (Z-1) to (Z-7),
* represents a bond, and
R¹¹ and R¹² each independently represent a hydrogen atom or a monovalent group optionally having a substituent and may be the same as or different from each other.)
<6> The polymer according to any one of <3> to <5>, in which the structural unit represented by Formula (Y1) is a structural unit represented by the following Formula (Y1-B5), the following Formula (Y1-B6), the following Formula (Y1-B7), the following Formula (Y1-B8), the following Formula (Y1-B9), or the following Formula (Y1-B10).

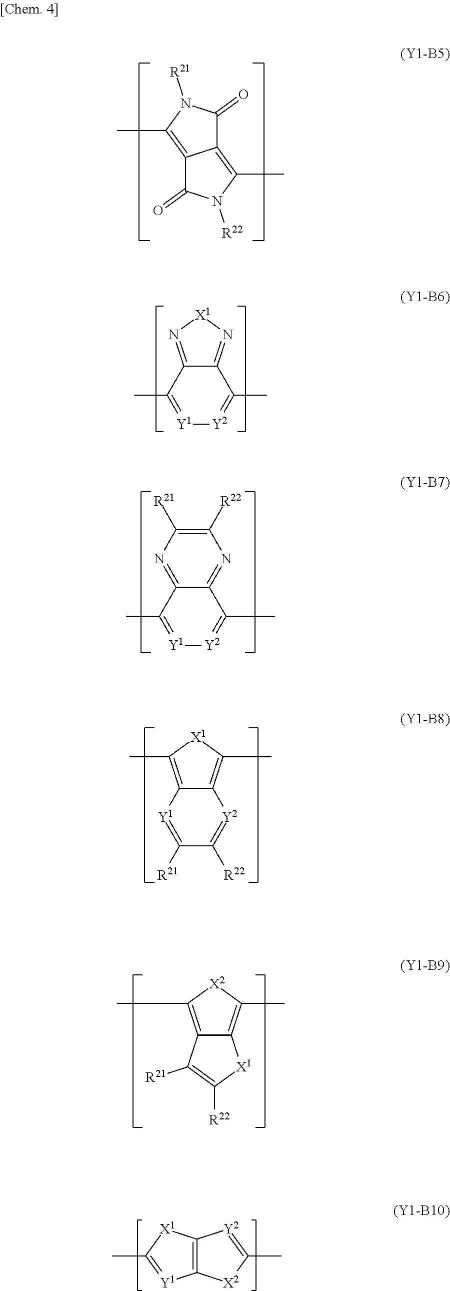

(in Formulas (Y1-B5) to (Y1-B10),
X¹ and X² each independently represent a sulfur atom, an oxygen atom, or a selenium atom,
Y¹ and Y² each independently represent a nitrogen atom or a group represented by ═CR^{2b}—, and
R²¹, R²², and R^{2b} each independently represent a hydrogen atom or a substituent.)
<7> The polymer according to <5> or <6>, in which in Formulas (Z-1) to (Z-7), at least one of R¹¹ and R¹² is a group represented by the following Formula (SC).

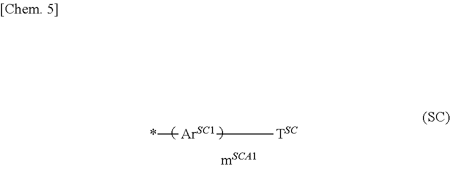

(in Formula (SC),
m^{SCA1} represents an integer of 1 or more and 10 or less,
Ar^{SC1} represents an arylene group optionally having a substituent, and
T^{SC} represents an aryl group optionally having a substituent.)
<8> The polymer according to any one of <3> to <7>, in which the structural unit represented by Formula (I) is a structural unit represented by the following Formula (I-8).

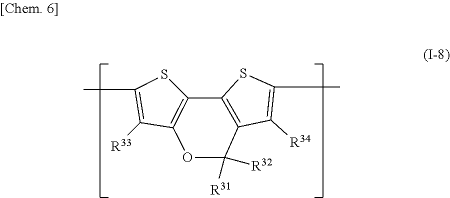

(in Formula (I-8), R³¹ to R³⁴ each independently represent a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, an amide group, an acid imide group, an imino group, an amino group, a silyl group, a silyloxy group, a silylthio group, a silylamino group, a heterocyclic group, a heterocyclic oxy group, a heterocyclic thio group, an arylalkenyl group, an arylalkynyl group, a carboxyl group, or a cyano group, and these groups optionally have a substituent.)
<9> The polymer according to any one of <1> to <8>, in which a weight average molecular weight is 6,000 or more.
<10> A polymer containing at least one selected from the group consisting of a structural unit represented by the following Formula (I) and a structural unit represented by the following Formula (Y1):

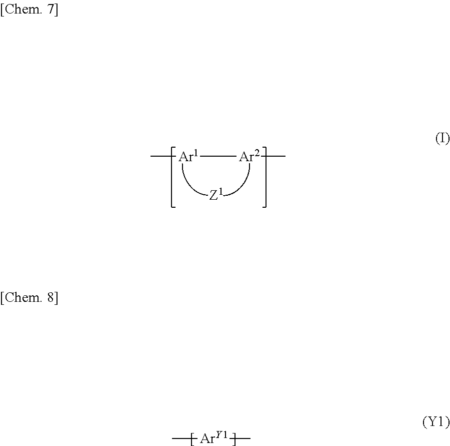

(in Formula (I),
Z¹ is a group represented by the following Formula (Z-1), the following Formula (Z-2), the following Formula (Z-3), the following Formula (Z-4), the following Formula (Z-5), the following Formula (Z-6), or the following Formula (Z-7), and
A^{r1} and A^{r2} each independently represent a trivalent aromatic hydrocarbon ring group or a trivalent heterocyclic group,
in Formula (Y1), Ar^{Y1} represents an arylene group, a divalent heterocyclic group, or a divalent group in which an arylene group and a divalent heterocyclic group are bonded,
in the groups represented by the following Formulas (Z-1) to (Z-7), at least one of R¹¹ and R¹² is a group represented by the following Formula (SC), and
in Formula (SC), m^{SCA1} represents an integer of 1 or more and 10 or less, Ar^{SC1} represents an arylene group, T^{SC} represents an aryl group, and these groups optionally have a substituent.)

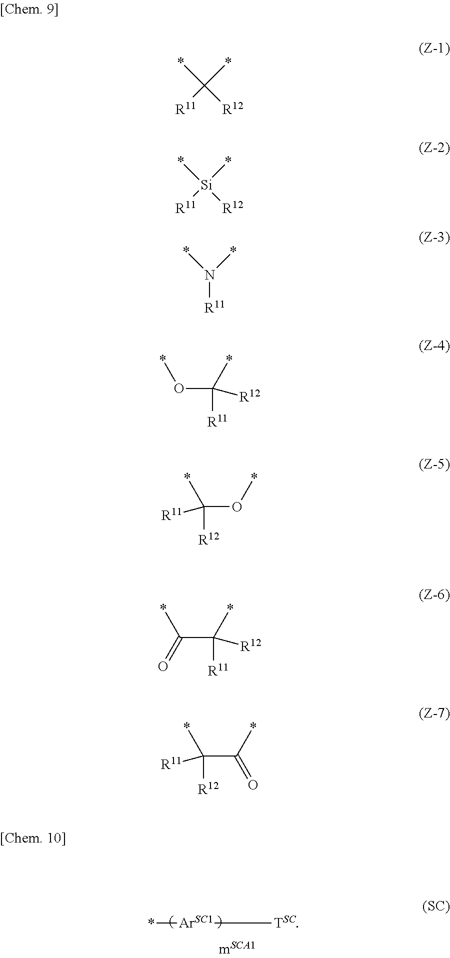

<11> A film containing the polymer according to any one of <1> to <10>.
<12> The film according to <11>, in which the film contains an electron-accepting compound.
<13> The film according to <11> or <12>, in which an absorption edge intensity is 0.17 or less.
<14> A composition containing the polymer according to any one of <1> to <10> and an electron-accepting compound.
<15> An ink containing the polymer according to any one of <1> to <10> and a solvent.
<16> An electronic element containing the polymer according to any one of <1> to <10>.
<17> A photoelectric conversion element including: a first electrode;
a second electrode; and
an active layer disposed between the first electrode and the second electrode,
in which the active layer contains the polymer according to any one of <1> to <10>.
<18> A solar cell module including the organic photoelectric conversion element according to <17>.
<19> An image sensor including the organic photoelectric conversion element according to <17>.

### Effect of the Invention

According to an embodiment of the present disclosure, there is provided a polymer that suppresses dark current in a photoelectric conversion element.

According to another embodiment of the present disclosure, there are provided a film and a composition containing the polymer according to the present disclosure.

According to still another embodiment of the present disclosure, there is provided an ink containing the polymer according to the present disclosure.

According to still another embodiment of the present disclosure, there is provided an electronic element containing the polymer according to the present disclosure.

According to still another embodiment of the present disclosure, there is provided a photoelectric conversion element that suppresses dark current.

According to still another embodiment of the present disclosure, there is provided a solar cell module including the photoelectric conversion element according to the present disclosure.

According to still another embodiment of the present disclosure, there is provided an image sensor including the photoelectric conversion element according to the present disclosure.

### BRIEF DESCRIPTION OF THE DRAWINGS

FIG. 1 is an example of an ultraviolet-visible-near-infrared absorption spectrum of a polymer according to the present disclosure.

FIG. 2 is a schematic cross-sectional view of an embodiment of the photoelectric conversion element according to the present disclosure.

FIG. 3 is a graph obtained by plotting predicted dark current against measured dark current.

### MODE FOR CARRYING OUT THE INVENTION

Hereinafter, embodiments of the present disclosure will be described. These descriptions and Examples are illustrative of embodiments and are not intended to limit the scope of the invention.

In the numerical ranges described in stages in the present specification, an upper limit value or a lower limit value described in one numerical range may be replaced with an upper limit value or a lower limit value of the numerical range described in another stage. In addition, in the numerical range described in the present specification, the upper limit value or the lower limit value of the numerical range may be replaced with a value shown in Examples.

Each component may contain a plurality of corresponding materials.

When referring to the amount of each component in the composition, if there are a plurality of materials corresponding to each component in the composition, it means the total amount of the plurality of materials present in the composition unless otherwise specified.

A main chain refers to a chain that becomes the longest stem in a polymer molecular structure.

A side chain represents a monovalent group branched from the main chain.

The “aromatic hydrocarbon ring group” means a remaining atomic group excluding one or more hydrogen atoms directly bonded to a carbon atom constituting an aromatic hydrocarbon ring which may be unsubstituted or optionally have a substituent and may have two or more condensed rings. For example, the aromatic hydrocarbon ring group may be referred to as a “p-valent aromatic hydrocarbon ring group” (p represents an integer of 1 or more), and in this case, it means a remaining atomic group excluding p hydrogen atoms directly bonded to carbon atoms constituting an aromatic hydrocarbon ring optionally having a substituent.

In addition, the aromatic hydrocarbon ring group may also be referred to as an “aromatic hydrocarbon ring group in which q rings are condensed” (q represents an integer of 2 or more), and in this case, it means an aromatic hydrocarbon ring group in which q rings are condensed.

The “heterocyclic group” means a remaining atomic group excluding one or more hydrogen atoms directly bonded to carbon atoms or heteroatoms constituting a heterocyclic ring which may be unsubstituted or optionally have a substituent and may have two or more condensed rings. For example, the aromatic hydrocarbon ring group may be referred to as a “p-valent heterocyclic group” (p represents an integer of 1 or more), and in this case, it means a remaining atomic group excluding p hydrogen atoms directly bonded to carbon atoms or heteroatoms constituting a heterocyclic ring optionally having a substituent.

In addition, the aromatic hydrocarbon ring group may also be referred to as a “heterocyclic group in which q rings are condensed” (q represents an integer of 2 or more), and in this case, it means a heterocyclic group in which q rings are condensed.

Examples of the “substituent A” include a halogen atom, an alkyl group (including a cycloalkyl group), an alkenyl group, an alkynyl group, an alkoxy group, an alkylthio group, an aryl group, an aryloxy group, an arylthio group, a monovalent heterocyclic group, a substituted amino group, an acyl group, an imine residue, an amide group, an acid imide group, a substituted oxycarbonyl group, a cyano group, an alkylsulfonyl group, and a nitro group. Note that, when the number of carbon atoms is used in the present specification, the number of carbon atoms usually does not include the number of carbon atoms in the substituent A.

Examples of the halogen atom include a fluorine atom, a chlorine atom, a bromine atom, and an iodine atom.

The number of carbon atoms in the alkyl group is preferably 1 or more and 50 or less, more preferably 1 or more and 30 or less, and still more preferably 1 or more and 20 or less.

Examples of the alkyl group include a methyl group, an ethyl group, an n-propyl group, an isopropyl group, an n-butyl group, an isobutyl group, a tert-butyl group, an n-pentyl group, an isoamyl group, a 2-ethylbutyl group, an n-hexyl group, a cyclohexyl group, an n-heptyl group, a cyclohexylmethyl group, a cyclohexylethyl group, an n-octyl group, a 2-ethylhexyl group, a 3-n-propylheptyl group, an adamantyl group, an n-decyl group, a 3,7-dimethyloctyl group, a 2-ethyloctyl group, a 2-n-hexyl-decyl group, an n-dodecyl group, a tetradecyl group, a hexadecyl group,

an octadecyl group, an eicosyl group, a cyclopentyl group, a cyclohexyl group, a cycloheptyl group, and an adamantyl group.

The number of carbon atoms in the alkenyl group is preferably 2 or more and 30 or less and more preferably 3 or more and 20 or less.

Examples of the alkenyl group include a vinyl group, a 1-propenyl group, a 2-propenyl group, a 2-butenyl group, a 3-butenyl group, a 3-pentenyl group, a 4-pentenyl group, a 1-hexenyl group, a 5-hexenyl group, and a 7-octenyl group.

The number of carbon atoms in the alkynyl group is preferably 2 or more and 20 or less and more preferably 3 or more and 20 or less.

Examples of the alkynyl group include an ethynyl group, a 1-propynyl group, a 2-propynyl group, a 2-butynyl group, a 3-butynyl group, a 3-pentynyl group, a 4-pentynyl group, a 1-hexynyl group, and a 5-hexynyl group.

The number of carbon atoms in the alkoxy group is preferably 1 or more and 40 or less and more preferably 1 or more and 10 or less.

Examples of the alkoxy group include a methoxy group, an ethoxy group, an n-propyloxy group, an isopropyloxy group, an n-butyloxy group, an isobutyloxy group, a tert-butyloxy group, an n-pentyloxy group, an n-hexyloxy group, a cyclohexyloxy group, an n-heptyloxy group, an n-octyloxy group, a 2-ethylhexyloxy group, an n-nonyloxy group, an n-decyloxy group, a 3,7-dimethyloctyloxy group, a 3-heptyldodecyloxy group, and a lauryloxy group.

The number of carbon atoms in the alkylthio group is preferably 1 or more and 40 or less and more preferably 1 or more and 10 or less.

Examples of the alkylthio group include a methylthio group, an ethylthio group, a propylthio group, an isopropylthio group, a butylthio group, an isobutylthio group, a tert-butylthio group, a pentylthio group, a hexylthio group, a cyclohexylthio group, a heptylthio group, an octylthio group, a 2-ethylhexylthio group, a nonylthio group, a decylthio group, a 3,7-dimethyloctylthio group, a laurylthio group, and a trifluoromethylthio group.

The aryl group is a monovalent aromatic hydrocarbon ring group.

The number of carbon atoms in the aryl group is preferably 6 or more and 30 or less and more preferably 6 or more and 20 or less.

Examples of the aryl group include a phenyl group, a 1-naphthyl group, a 2-naphthyl group, a 1-anthracenyl group, a 2-anthracenyl group, a 9-anthracenyl group, a 1-pyrenyl group, a 2-pyrenyl group, a 4-pyrenyl group, a 2-fluorenyl group, a 3-fluorenyl group, a 4-fluorenyl group, a 2-phenylphenyl group, a 3-phenylphenyl group, and a 4-phenylphenyl group.

The number of carbon atoms in the aryloxy group is preferably 6 or more and 60 or less and more preferably 6 or more and 48 or less.

Examples of the aryloxy group include a phenoxy group, a 1-naphthyloxy group, a 2-naphthyloxy group, a 1-anthracenyloxy group, a 9-anthracenyloxy group, and a 1-pyrenyloxy group.

The number of carbon atoms in the arylthio group is preferably 6 or more and 60 or less and more preferably 6 or more and 48 or less.

Examples of the arylthio group include a phenylthio group and a C1-C12 alkyloxyphenylthio group (C1-C12 indicates that the number of carbon atoms in a group described immediately after that is 1 or more and 12 or less, and the same applies to the following), a C1-C12 alkylphenylthio group, a 1-naphthylthio group, a 2-naphthylthio group, and a pentafluorophenylthio group.

The number of carbon atoms in the monovalent heterocyclic group is preferably 2 or more and 60 or less and more preferably 4 or more and 20 or less.

Examples of the monovalent heterocyclic group include a thienyl group, a pyrrolyl group, a furyl group, a pyridyl group, a piperidyl group, a quinolyl group, an isoquinolyl group, a pyrimidinyl group, and a triazinyl group.

The substituted amino group means an amino group having a substituent. Examples of the substituent of the amino group include an alkyl group, an aryl group, and a monovalent heterocyclic group, and an alkyl group, an aryl group, or a monovalent heterocyclic group is preferable.

The number of carbon atoms in the substituted amino group is preferably 2 or more and 30 or less.

Examples of the substituted amino group include a dialkylamino group such as a dimethylamino group or a diethylamino group; and a diarylamino group such as a diphenylamino group, a bis(4-methylphenyl)amino group, a bis(4-tert-butylphenyl)amino group, or a bis(3,5-di-tert-butylphenyl)amino group.

The number of carbon atoms in the acyl group is preferably 2 or more and 20 or less and more preferably 2 or more and 18 or less.

Examples of the acyl group include an acetyl group, a propionyl group, a butyryl group, an isobutyryl group, a pivaloyl group, a benzoyl group, a trifluoroacetyl group, and a pentafluorobenzoyl group.

The imine residue means a remaining atomic group obtained by excluding one hydrogen atom directly bonded to a carbon atom or a nitrogen atom constituting a carbon atom-nitrogen atom double bond from an imine compound. The “imine compound” means an organic compound having a carbon atom-nitrogen atom double bond in the molecule. Examples of the imine compound include aldimine, ketimine, and a compound in which a hydrogen atom bonded to a nitrogen atom constituting a carbon atom-nitrogen atom double bond in aldimine is substituted with an alkyl group or the like.

The number of carbon atoms in the imine residue is preferably 2 or more and 20 or less and more preferably 2 or more and 18 or less.

Examples of the imine residue include a group represented by the following structural formula. In the following structural formulas, * represents a bond.

In the following structural formula, “Me” represents a methyl group.

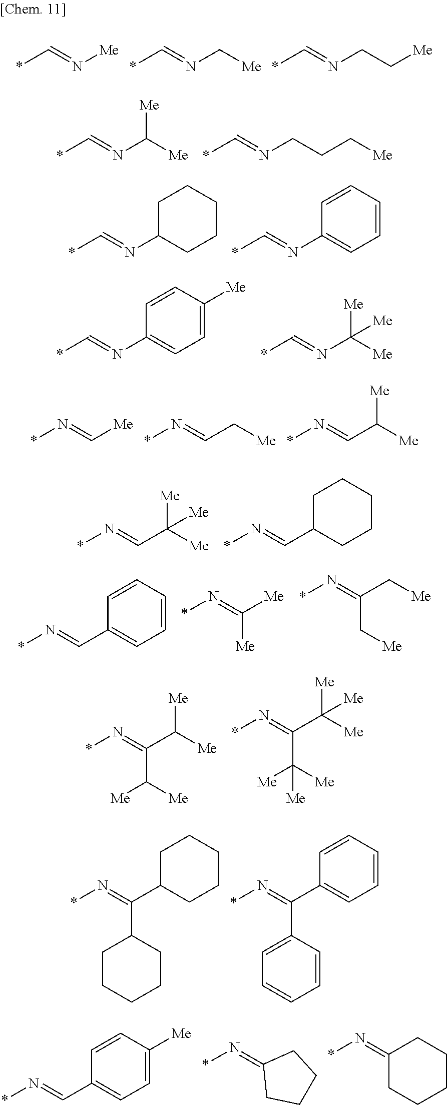

The number of carbon atoms in the amide group is preferably 1 or more and 20 or less and more preferably 1 or more and 18 or less.

Examples of the amide group include a formamide group, an acetamide group, a propioamide group, a butyroamide group, a benzamide group, a trifluoroacetamide group, a pentafluorobenzamide group, a diformamide group, a diacetamide group, a dipropioamide group, a dibutyroamide group, a dibenzamide group, a ditrifluoroacetamide group, and a dipentafluorobenzamide group.

The acid imide group means a remaining atomic group excluding one hydrogen atom bonded to a nitrogen atom from an acid imide.

The number of carbon atoms in the acid imide group is preferably 4 or more and 20 or less.

Examples of the acid imide group include a group represented by the following structural formula. In the following structural formulas, * represents a bond.

In the following structural formula, “Me” represents a methyl group.

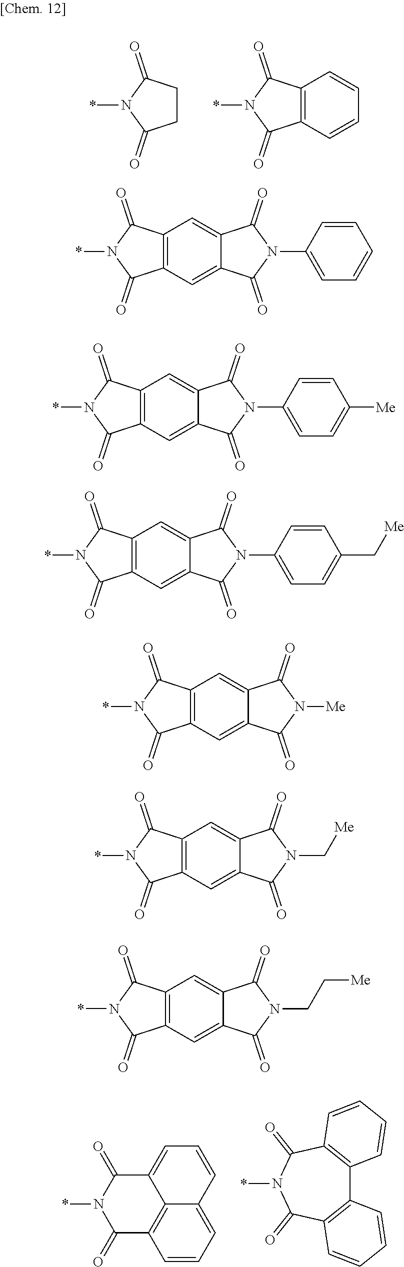

The substituted oxycarbonyl group means a group represented by R′—O—(C═O)—. Here, R′ represents an alkyl group, an aryl group, an arylalkyl group, or a monovalent heterocyclic group.

The number of carbon atoms in the substituted oxycarbonyl group is preferably 2 or more and 60 or less and more preferably 2 or more and 48 or less.

Examples of the substituted oxycarbonyl group include a methoxycarbonyl group, an ethoxycarbonyl group, a propoxycarbonyl group, an isopropoxycarbonyl group, a butoxycarbonyl group, an isobutoxycarbonyl group, a tert-butyloxycarbonyl group, a pentyloxycarbonyl group, a hexyloxycarbonyl group, a cyclohexyloxycarbonyl group, a heptyloxycarbonyl group, an octyloxycarbonyl group, a 2-ethylhexyloxycarbonyl group, a nonyloxycarbonyl group, a decyloxycarbonyl group, a 3,7-dimethyloctyloxycarbonyl group, a dodecyloxycarbonyl group, a trifluoromethoxycarbonyl group, a pentafluoroethoxycarbonyl group, a perfluorobutoxycarbonyl group, a perfluorohexyloxycarbonyl group, a perfluorooctyloxycarbonyl group, a phenoxycarbonyl group, a naphthoxycarbonyl group, and a pyridyloxycarbonyl group.

The number of carbon atoms in the alkylsulfonyl group is preferably 1 or more and 30 or less.

Examples of the alkylsulfonyl group include a methylsulfonyl group, an ethylsulfonyl group, and a dodecylsulfonyl group.

### <Polymer>

A polymer according to the present disclosure is a polymer containing a structural unit having a main chain and a side chain, in which a weighted average of formula weights of the side chains weighted by a molar ratio of the structural units contained in the polymer is 160 or more, and an absorption edge intensity is 0.08 or less

With the above configuration, the polymer according to the present disclosure suppresses dark current in a photoelectric conversion element. The reason is presumed as follows.

When a photoelectric conversion element is manufactured using the polymer according to the present disclosure, carrier generation due to thermal excitation is suppressed by setting the weighted average of the formula weights of the side chains to 160 or more. In addition, a polymer having an absorption edge intensity of 0.08 or less has a small spread in energy order, and the generation of carriers due to thermal excitation is similarly suppressed.

From the above, it is presumed that the polymer according to the present disclosure suppresses dark current in the photoelectric conversion element.

### (Structure of Polymer)

The polymer according to the present disclosure contains a structural unit having a main chain and a side chain.

In the structural unit, a structure of the main chain is not particularly limited, and is preferably a structure containing a condensed ring.

The structure of the main chain is more preferably a structure in which repeating units containing a condensed ring are bonded and connected, and the repeating units containing a condensed ring may be plural kinds.

From the viewpoint of suppressing dark current, in the structural unit, the side chain is preferably at least one selected from the group consisting of an alkyl group optionally having a substituent, an aryl group optionally having a substituent, and a monovalent heterocyclic group optionally having a substituent, and more preferably at least one selected from the group consisting of an alkyl group optionally having a substituent and an aryl group optionally having a substituent.

The alkyl group as a side chain may be linear or branched, or may be a cycloalkyl group.

The number of carbon atoms in the alkyl group as a side chain is preferably 1 or more and 30 or less.

The alkyl group as a side chain optionally has a substituent, and examples of the substituent include the above-described substituent A.

Specific examples of the alkyl group as a side chain include a chain alkyl group such as a methyl group, an ethyl group, a propyl group, an isopropyl group, a butyl group, an isobutyl group, a sec-butyl group, a tert-butyl base, a pentyl group, an isopentyl group, a 2-methylbutyl group, a 1-methylbutyl group, a hexyl group, an isohexyl group, a 3-methylpentyl group, a 2-methylpentyl group, a 1-methylpentyl group, a heptyl group, an octyl group, an isooctyl group, a 2-ethylhexyl group, a 3,7-dimethyloctyl group, a nonyl group, a decyl group, an undecyl group, a dodecyl group, a tetradecyl group, a hexadecyl group, an octadecyl group, or an eicosyl group, and a cycloalkyl group such as a cyclopentyl group, a cyclohexyl group, or an adamantyl group.

The aryl group as a side chain has the same meaning as a monovalent aromatic hydrocarbon ring group, and the number of carbon atoms is preferably 6 or more and 60 or less.

The aryl group as a side chain optionally has a substituent, and examples of the substituent include the above-described substituent A.

Specific examples of the aryl group as a side chain include a phenyl group, a 1-naphthyl group, a 2-naphthyl group, a 1-anthracenyl group, a 2-anthracenyl group, a 9-anthracenyl group, a 1-pyrenyl group, a 2-pyrenyl group, a 4-pyrenyl group, a 2-fluorenyl group, a 3-fluorenyl group, a 4-fluorenyl group, a 2-phenylphenyl group, a 3-phenylphenyl group, and a 4-phenylphenyl group.

The number of carbon atoms in the monovalent heterocyclic group as a side chain is preferably 2 or more and 60 or less and more preferably 4 or more and 20 or less.

Examples of the monovalent heterocyclic group as a side chain include a thienyl group, a pyrrolyl group, a furyl group, a pyridyl group, a piperidyl group, a quinolyl group, an isoquinolyl group, a pyrimidinyl group, and a triazinyl group.

The monovalent heterocyclic group as a side chain optionally has a substituent, and examples of the substituent include the above-described substituent A.

From the viewpoint of suppressing dark current, the polymer according to the present disclosure contains at least one selected from the group consisting of a structural unit represented by the following Formula (I) and a structural unit represented by the following Formula (Y¹).

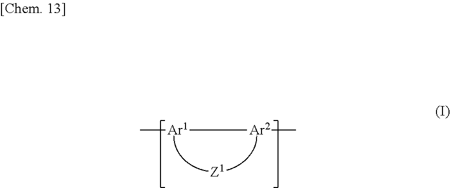

In Formula (I), Z¹ is a divalent group, Ar¹ and Ar² each independently represent a trivalent aromatic hydrocarbon ring group or a trivalent heterocyclic group, and these groups optionally have a substituent.

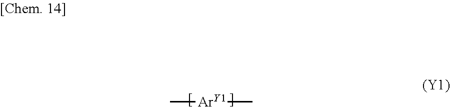

In Formula (Y1), Ar^{Y1} represents an arylene group, a divalent heterocyclic group, or a divalent group in which an arylene group and a divalent heterocyclic group are bonded, and these groups optionally have a substituent.

### —Structural Unit Represented by Formula (I)—

Examples of the trivalent aromatic hydrocarbon ring group represented by Ar¹ or Ar² in Formula (I) include a remaining atomic group excluding three hydrogen atoms directly bonded to carbon atoms constituting the following aromatic hydrocarbon ring.

Examples of the aromatic hydrocarbon ring include a benzene ring, a naphthalene ring, an anthracene ring, and a pyrene ring.

Examples of the trivalent heterocyclic group represented by Ar¹ or Ar² in Formula (I) include a remaining atomic group excluding three hydrogen atoms directly bonded to carbon atoms or heteroatoms constituting the following aromatic heterocyclic ring.

Examples of the aromatic heterocyclic ring include an oxadiazole ring, a thiadiazole ring, a thiazole ring, an oxazole ring, a thiophene ring, a pyrrole ring, a phosphole ring, a furan ring, a pyridine ring, a pyrazine ring, a pyrimidine ring, a triazine ring, a pyridazine ring, a quinoline ring, an isoquinoline ring, a carbazole ring, a dibenzophosphole ring, a phenoxazine ring, a phenothiazine ring, a dibenzoborole ring, a dibenzosilole ring, and a benzopyran ring.

The trivalent aromatic hydrocarbon ring group represented by Ar¹ or Ar² may have a substituent, and examples thereof include the above-described substituent A.

From the viewpoint of suppressing dark current, in the structural unit represented by Formula (I), Z¹ is preferably a group represented by the following Formula (Z-1), the following Formula (Z-2), the following Formula (Z-3), the following Formula (Z-4), the following Formula (Z-5), the following Formula (Z-6), or the following Formula (Z-7).

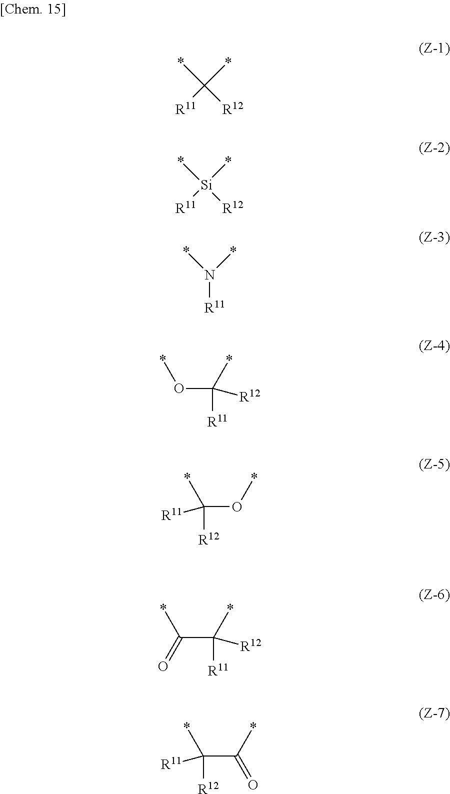

In Formulas (Z-1) to (Z-7), * represents a bond, and R¹¹ and R¹² each independently represent a hydrogen atom or a monovalent group and may be the same as or different from each other.

In a case where the polymer according to the present disclosure contains a structural unit represented by Formula (I) and Z¹ in Formula (I) is a group represented by the following Formula (Z-1), the following Formula (Z-2), the following Formula (Z-3), the following Formula (Z-4), the following Formula (Z-5), the following Formula (Z-6), or the following Formula (Z-7), monovalent groups represented by R¹¹ and R¹² in Formulas (Z-1) to (Z-7) correspond to side chains, and other portions correspond to main chains.

Examples of the monovalent group include a halogen atom, an alkyl group, an alkoxy group, an alkylthio group, an aryl group, an aryloxy group, an arylthio group, an arylalkyl group, an arylalkoxy group, an arylalkylthio group, an acyl group, an acyloxy group, an amide group, an acid imide group, an imino group, an amino group, a silyl group, a silyloxy group, a silylthio group, a silylamino group, a heterocyclic group, a heterocyclic oxy group, a heterocyclic thio group, an arylalkenyl group, an arylalkynyl group, a carboxyl group, and a cyano group.

The monovalent group optionally has a substituent, and examples of the substituent include the above-described substituent A.

From the viewpoint of suppressing dark current, the monovalent group is preferably at least one selected from the group consisting of an alkyl group, an aryl group, and a heterocyclic group.

Examples of the alkyl groups represented by R¹¹ and R¹² include the same as the above-described alkyl group which is a side chain of the polymer according to the present disclosure, and preferred aspects are also the same.

Examples of the aryl groups represented by R¹¹ and R¹² include the same as the above-described aryl group which is a side chain of the polymer according to the present disclosure, and preferred aspects are also the same.

Examples of the heterocyclic groups represented by R¹¹ and R¹² include the same as the above-described monovalent heterocyclic group which is a side chain of the polymer according to the present disclosure, and preferred aspects are also the same.

From the viewpoint of suppressing dark current, at least one of R¹¹ and R¹² in Formulas (Z-1) to (Z-7) is preferably a group represented by the following Formula (SC).

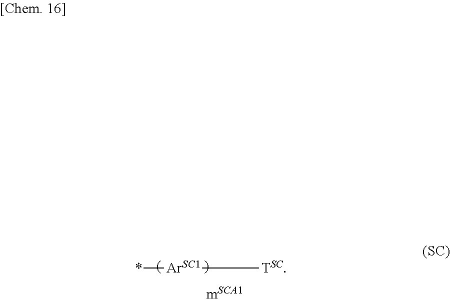

In Formula (SC), m^{SCA1} represents an integer of 1 or more and 10 or less, Ar^{SC1} represents an arylene group optionally having a substituent, and T^{SC} represents an aryl group optionally having a substituent.

m^{SCA1} is preferably an integer of 1 or more and 5 or less, more preferably an integer of 1 or more and 3 or less, and still more preferably an integer of 1 or more and 2 or less.

The arylene group is a divalent aromatic hydrocarbon ring group.

The number of carbon atoms in the arylene group represented by Ar^{SC1} is preferably 6 or more and 60 or less and more preferably 6 or more and 20 or less.

Examples of the arylene group include a remaining atomic group excluding two hydrogen atoms directly bonded to carbon atoms constituting the following aromatic hydrocarbon ring.

Examples of the aromatic hydrocarbon ring include a benzene ring, a naphthalene ring, an anthracene ring, and a pyrene ring.

The arylene group represented by Ar^{SC1} optionally has a substituent, and examples of the substituent include the above-described substituent A.

The number of carbon atoms in the aryl group represented by T^{SC} is preferably 6 or more and 30 or less and more preferably 6 or more and 20 or less.

Examples of the aryl group include a phenyl group, a 1-naphthyl group, a 2-naphthyl group, a 1-anthracenyl group, a 2-anthracenyl group, a 9-anthracenyl group, a 1-pyrenyl group, a 2-pyrenyl group, a 4-pyrenyl group, a 2-fluorenyl group, a 3-fluorenyl group, a 4-fluorenyl group, a 2-phenylphenyl group, a 3-phenylphenyl group, and a 4-phenylphenyl group.

The aryl group represented by T^{SC} optionally has a substituent, and examples of the substituent include the above-described substituent A.

Examples of the structural unit represented by Formula (I) include structural units represented by the following Formulas (I-1) to (I-9).

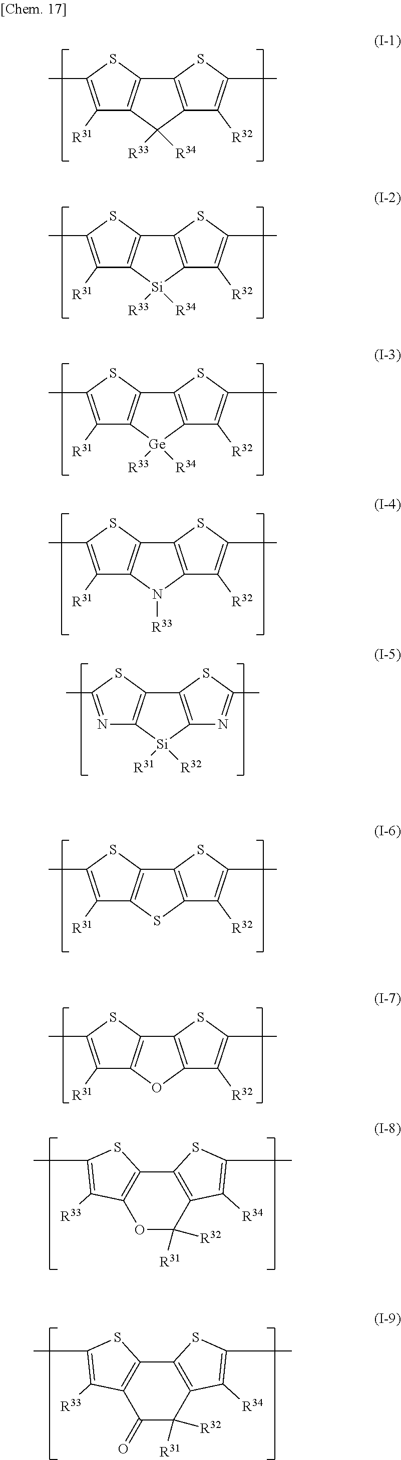

In Formulas (I-1) to (I-9), R³¹, R³², R³³, and R³⁴ each independently represent a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, an amide group, an acid imide group, an imino group, an amino group, a silyl group, a silyloxy group, a silylthio group, a silylamino group, a heterocyclic group, a heterocyclic oxy group, a heterocyclic thio group, an arylalkenyl group, an arylalkynyl group, a carboxyl group, or a cyano group, and these groups optionally have a substituent. Examples of the substituent include the above-described substituent A.

From the viewpoint of suppressing dark current, R³¹, R³², R³³, and R³⁴ are preferably at least one selected from the group consisting of a hydrogen atom, an alkyl group, an aryl group, and a heterocyclic group.

In a case where the structural unit represented by Formula (I) is a structural unit represented by any one of Formulas (I-1) to (I-9), and in a case where R³¹ to R³⁴ in Formulas (I-1) to (I-9) are other than a hydrogen atom, these groups correspond to side chains.

From the viewpoint of suppressing dark current, the structural unit represented by Formula (I) is preferably a structural unit represented by Formula (I-8).

The polymer according to the present disclosure may contain only one structural unit represented by Formula (I), or may contain two or more different types of structural units.

From the viewpoint of suppressing dark current, the polymer according to the present disclosure preferably contains two different types of structural units represented by Formula (I).

### —Structural Unit Represented by Formula (Y1)—

In Formula (Y1), Ar^{Y1} represents an arylene group, a divalent heterocyclic group, or a divalent group in which an arylene group and a divalent heterocyclic group are bonded, and these groups optionally have a substituent.

The number of carbon atoms in the arylene group represented by Ar^{Y1} (that is, the divalent aromatic hydrocarbon ring group) is preferably 6 or more and 60 or less and more preferably 6 or more and 20 or less.

In a case where Ar^{Y1} is an arylene group, the structural unit represented by Formula (Y1) is preferably the following Formula (Y1-A1), the following Formula (Y1-A2), the following Formula (Y1-A3), the following Formula (Y1-A4), the following Formula (Y1-A5), or the following Formula (Y1-A6).

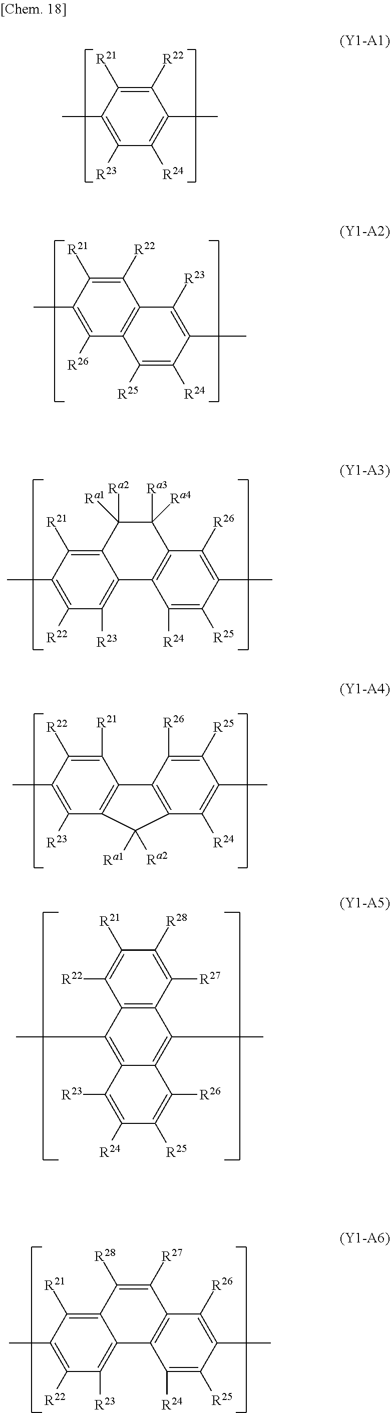

In Formulas (Y1-A1) to (Y1-A6), R²¹ to R²⁸ and R^{a1} to R^{a4} each independently represent a hydrogen atom or a substituent. R^{a1} to R^{a4} may be bonded to each other to form a ring together with atoms to which R^{a1} to R^{a4} are bonded.

Examples of the substituent include the above-described substituent A.

In a case where the structural unit represented by Formula (Y1) is a structural unit represented by any one of Formulas (Y1-A1) to (Y1-A6), and in a case where R²¹ to R²⁸ and R^{a1} to R^{a4} in Formulas (Y1-A1) to (Y1-A6) are other than a hydrogen atom, these groups correspond to side chains.

Examples of the divalent heterocyclic group represented by Ar^{Y1} include a remaining atomic group excluding two hydrogen atoms directly bonded to carbon atoms or heteroatoms constituting the following heterocyclic ring.

Examples of the heterocyclic ring include a pyridine ring, a diazobenzene ring, a triazine ring, an azanaphthalene ring, a diazanaphthalene ring, a carbazole ring, a dibenzofuran ring, a dibenzothiophene ring, a dibenzosilole ring, a phenoxazine ring, a phenothiazine ring, an acridine ring, a dihydroacridine ring, a furan ring, a thiophene ring, an azole ring, a diazole ring, a triazole ring, and a heterocyclic ring in which two or more of these heterocyclic rings are condensed.

In a case where Ar^{Y1} is a divalent heterocyclic group, the structural unit represented by Formula (Y1) is preferably the following Formula (Y1-B1), the following Formula (Y1-B2), the following Formula (Y1-B3), the following Formula (Y1-B4), the following Formula (Y1-B5), the following Formula (Y1-B6), the following Formula (Y1-B7), the following Formula (Y1-B8), the following Formula (Y1-B9), or the following Formula (Y1-B10).

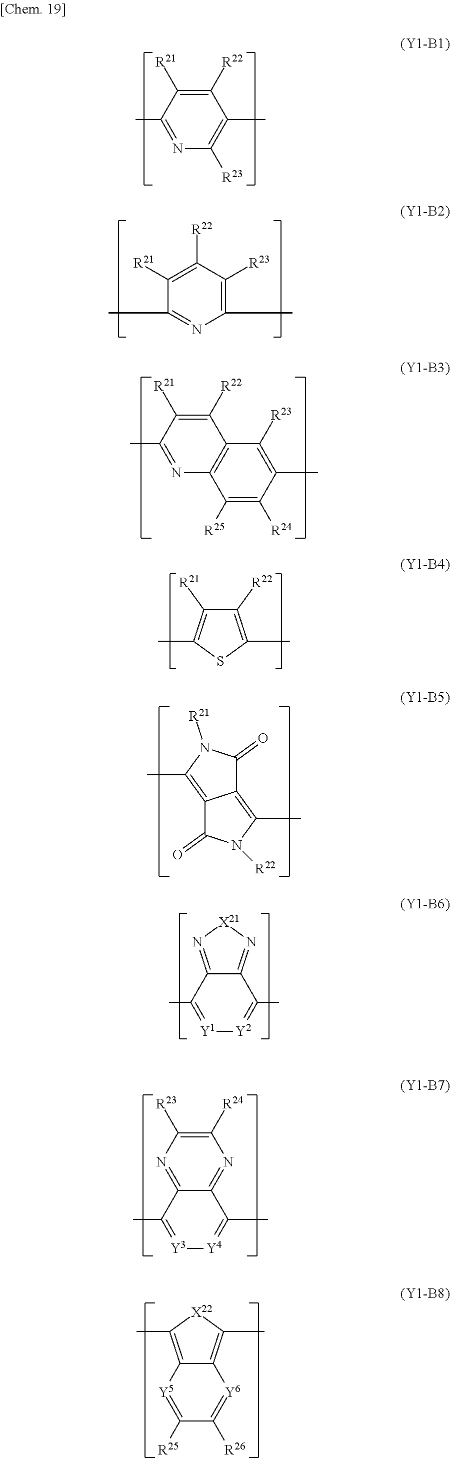

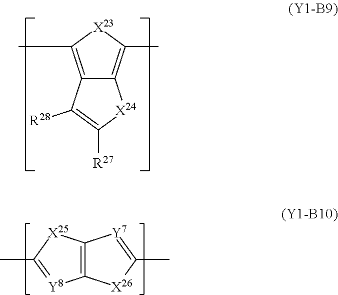

In Formulas (Y1-B1) to (Y1-B10), X²¹ to X²⁶ each independently represent a sulfur atom, an oxygen atom, or a selenium atom, Y¹ to Y⁸ each independently represent a nitrogen atom or a group represented by ═CR^{2b}—, and R²¹ to R²⁸ and R^{2b} each independently represent a hydrogen atom or a substituent.

Examples of the substituent include the above-described substituent A.

In a case where the structural unit represented by Formula (Y1) is a structural unit represented by any one of Formulas (Y1-B1) to (Y1-B10), and in a case where R²¹ to R²⁵ and R^{2b} in Formulas (Y1-B1) to (Y1-B10) are other than a hydrogen atom, these groups correspond to side chains.

In a case where Ar^{Y1} is a divalent group in which an arylene group and a divalent heterocyclic group are bonded, the structural unit represented by Formula (Y1) is preferably represented by the following Formula (Y1-C1), the following Formula (Y1-C2), the following Formula (Y1-C3), or the following Formula (Y1-C4).

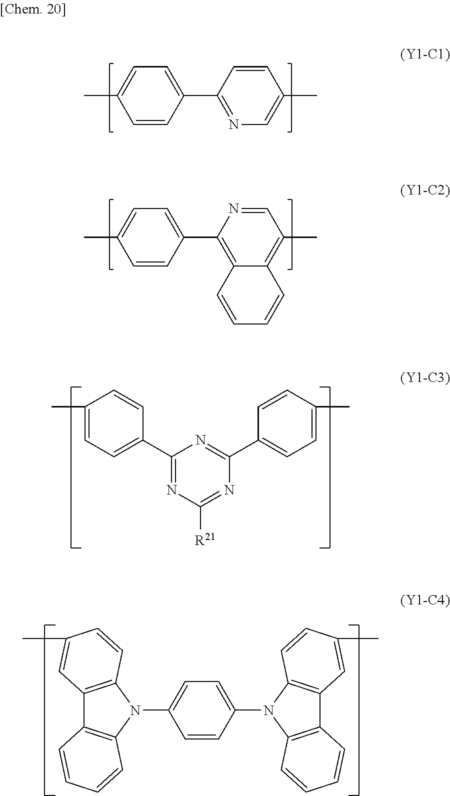

In Formulas (Y1-C1) to (Y1-C4), R²¹ represents a hydrogen atom or a substituent.

Examples of the substituent include the above-described substituent A.

In a case where the structural unit represented by Formula (Y1) is a structural unit represented by Formula (Y1-C3), and in a case where R²¹ in Formula (Y1-C3) is other than a hydrogen atom, the group corresponds to a side chain.

In a case where the structural unit represented by Formula (Y1) is a structural unit represented by Formula (Y1-C1), Formula (Y1-C2), or Formula (Y1-C4), a side chain is not included.

From the viewpoint of suppressing dark current, the structural unit represented by Formula (Y1) is preferably a structural unit represented by the following Formula (Y1-B5), the following Formula (Y1-B6), the following Formula (Y1-B7), the following Formula (Y1-B8), the following Formula (Y1-B9), or the following Formula (Y1-B10).

### —Mol % of Structural Unit—

In the polymer according to the present disclosure, a total content of the structural unit represented by Formula (I) and the structural unit represented by Formula (Y1) is 1 mol % or more and 100 mol % or less, preferably 10 mol % or more and 100 mol % or less, more preferably 30 mol % or more and 100 mol % or less, still more preferably 50 mol % or more and 100 mol % or less, particularly preferably 70 mol % or more and 100 mol % or less, and most preferably 90 mol % or more and 100 mol % or less, with respect to the total content of the structural units contained in the polymer.

In the polymer according to the present disclosure, a total content of the structural unit represented by Formula (I) is 1 mol % or more and 90 mol % or less, preferably 10 mol % or more and 80 mol % or less, more preferably 30 mol % or more and 70 mol % or less, and still more preferably 50 mol % or more and 60 mol % or less, with respect to the total content of the structural units contained in the polymer.

In a case where the polymer according to the present disclosure contains two different types of structural units represented by Formula (I), and in a case where one structural unit represented by Formula (I) is the structural unit represented by Formula (I) and the other structural unit represented by Formula (I) is the structural unit represented by Formula (I′), a content of the structural unit represented by Formula (I′) is 1 mol % or more and 90 mol % or less, preferably 10 mol % or more and 80 mol % or less, more preferably 30 mol % or more and 70 mol % or less, and still more preferably 50 mol % or more and 60 mol % or less, with respect to a total content of the structural unit represented by Formula (I) and the structural unit represented by Formula (I′).

In the polymer according to the present disclosure, a total content of the structural unit represented by Formula (Y1) is 1 mol % or more and 90 mol % or less, preferably 10 mol % or more and 80 mol % or less, more preferably 30 mol % or more and 70 mol % or less, and still more preferably 50 mol % or more and 60 mol % or less, with respect to the total content of the structural units contained in the polymer.

The polymer according to the present disclosure may contain structural units other than the structural unit represented by Formula (I) and the structural unit represented by Formula (Y1).

In a case where the polymer according to the present disclosure contains other structural units, a content of the other structural units is 0 mol % or more and 30 mol % or less, preferably 0 mol % or more and 20 mol % or less, more preferably 0 mol % or more and 10 mol % or less, and still more preferably 0 mol %, with respect to the total content of the structural units contained in the polymer.

Examples of the polymer according to the present disclosure include a polymer P-1 and a polymer P-2 shown in Table 1.

Here, in Table 1, “Formula (I)” means a structural unit represented by Formula (I).

In Table 1, “Formula (I′)” means a structural unit represented by Formula (I) different from “Formula (I)” in Table 1 in a case where the polymer contains two different types of structural units represented by Formula (I).

In Table 1, “Formula (Y1)” means a structural unit represented by Formula (Y1).

In Table 1, “other” means structural units other than the structural unit represented by Formula (I) and the structural unit represented by Formula (Y1).

In Table 1, “p”, “q”, “r”, and “s” represent a molar ratio (mol %) of each structural unit. p+q+r+s=100, and 70≤p+q+r+≤100.

TABLE 1

| | Structural unit and molar ratio thereof | | | |
|---|---|---|---|---|
| | Formula (I) | Formula (I′) | Formula (Y1) | Others |
| Polymer | p | q | r | s |
| P-1 | 0.1 to 99.9 | 0 | 0.1 to 99.9 | 0 to 30 |
| P-2 | 0.1 to 99.8 | 0.1 to 99.8 | 0.1 to 99.9 | 0 to 30 |

Specific examples of the polymer according to the present disclosure are described in the following Tables 2-1 to 2-10, but are not limited thereto.

Note that the following Tables 2-1 to 2-10 may be collectively referred to as Table 2.

TABLE 2-1

| Poly- | |
|---|---|
| mer | Structural formula |
| G- 002 | 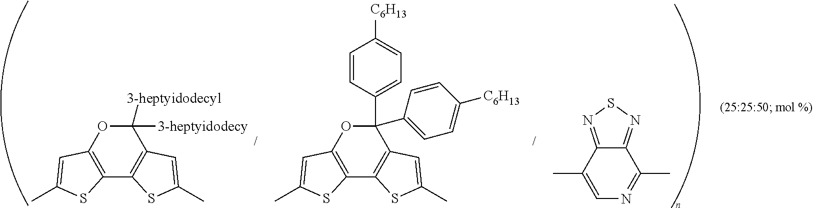 |
| | 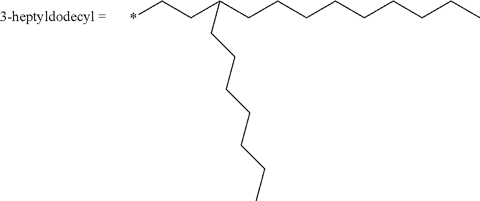 [SMILES: *CCC(CCCCCCC)CCCCCCCCC] |
| G- 009 | 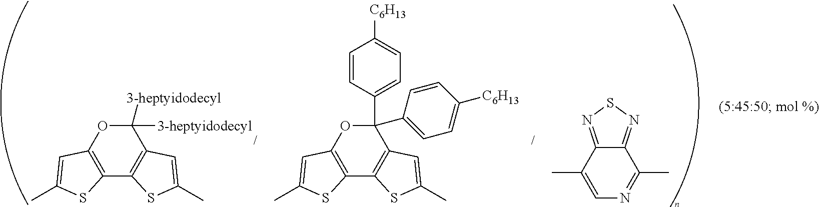 |
| G- 010 | 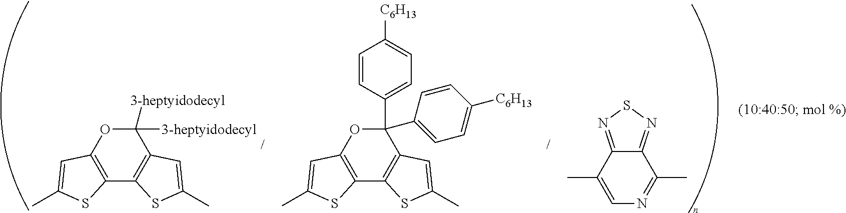 |
| G- 019 | 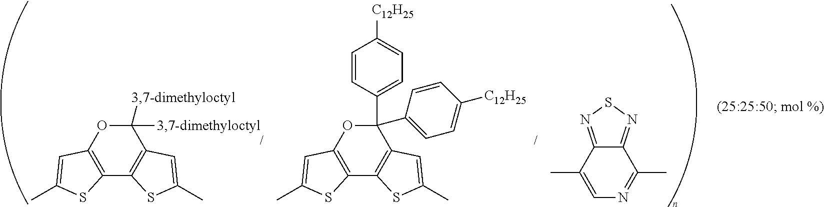 |

TABLE 2-2

| Poly- | |
|---|---|
| mer | Structural formula |
| G- 020 | 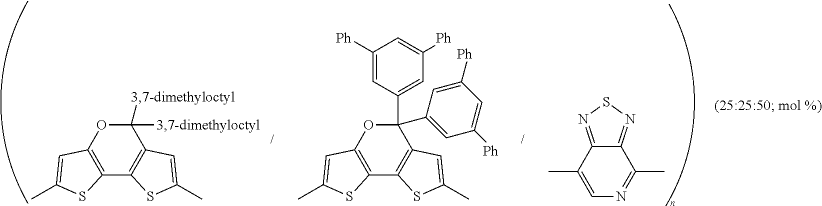 |
| G- 022 | 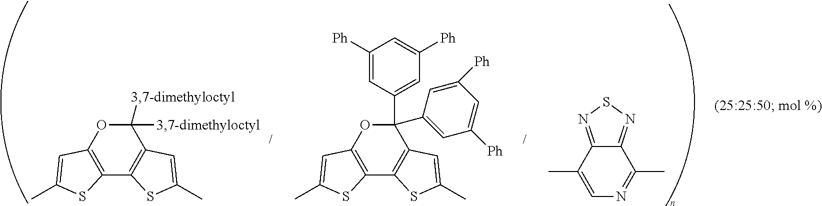 |
| G- 023 | 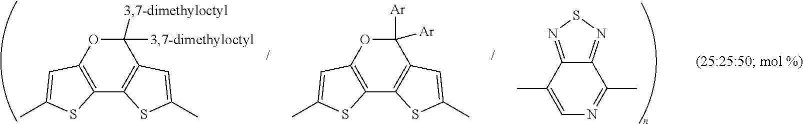 |
| | 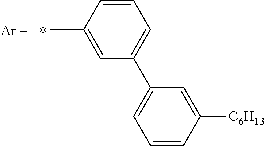 |
| G- 030 | 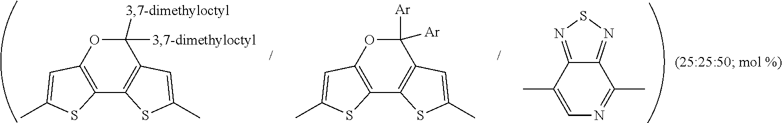 |
| | 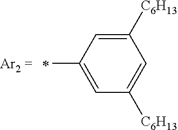 |

TABLE 2-3

| Polymer | Structural formula |
|---|---|
| G- 035 | 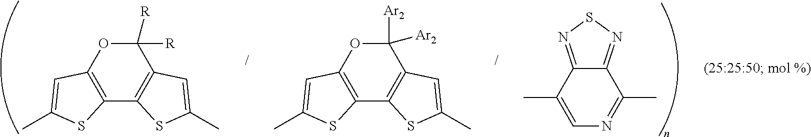 |
| | 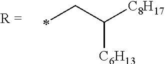 |
| | 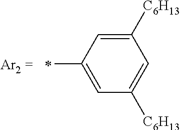 |
| G- 101 | 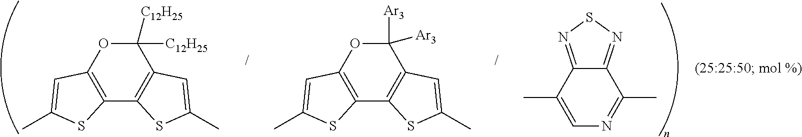 |
| | 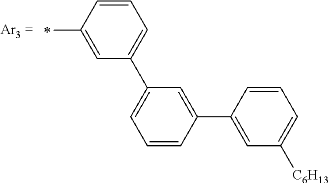 |

TABLE 2-4

| Polymer | Structural formula |
|---|---|
| G- 102 | 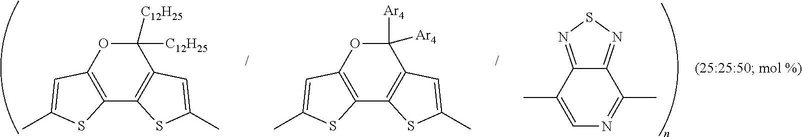 |
| | 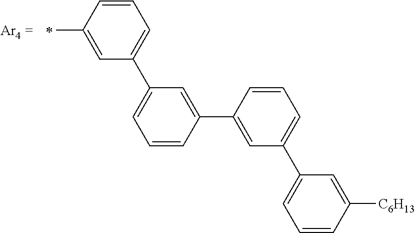 |
| G- 103 | 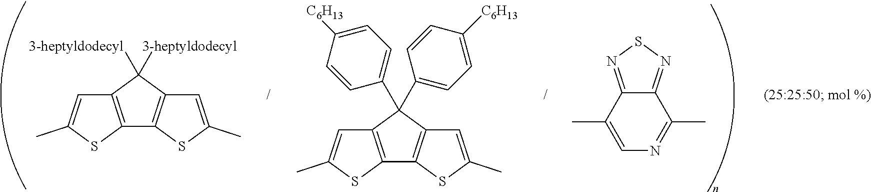 |
| | 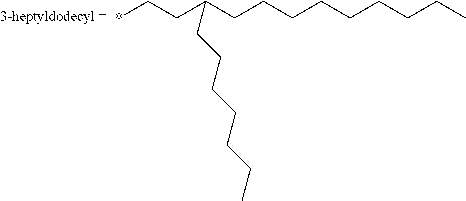 [SMILES: *CCC(CCCCCCC)CCCCCCCCC] |
| G- 104 | 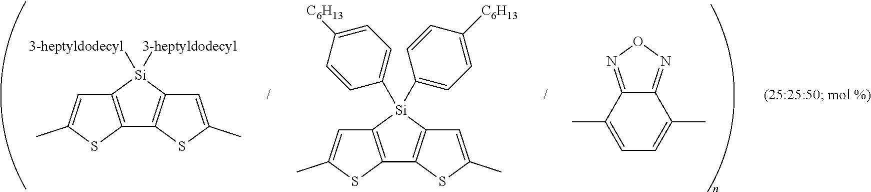 |

TABLE 2-5

| Polymer | Structural formula |
|---|---|
| G- 105 | 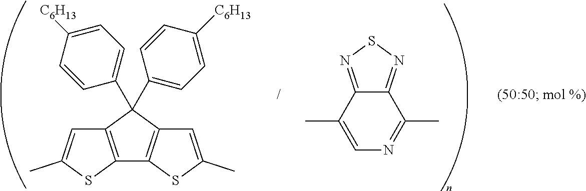 |
| G- 106 | 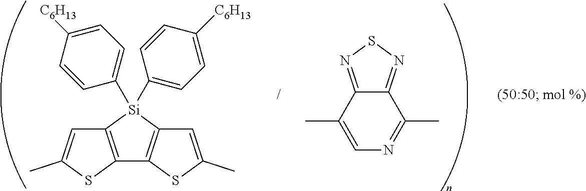 |
| G-107 | 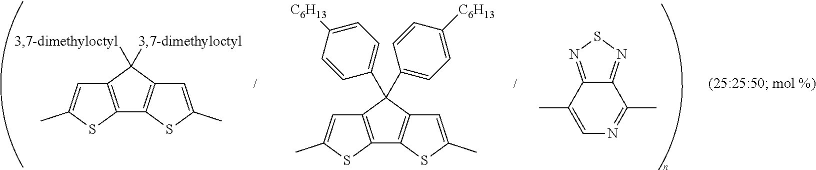 |
| | 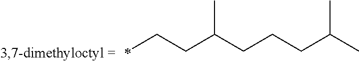 |
| G- 108 | 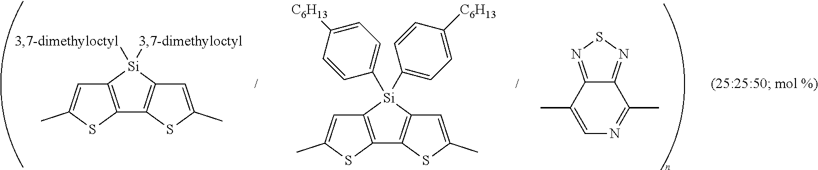 |
| G- 109 | 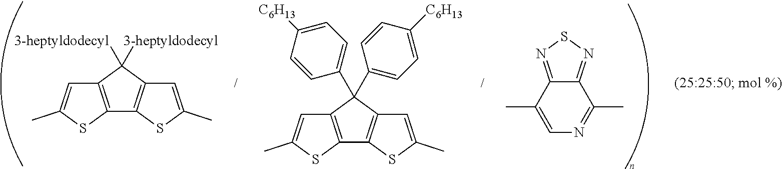 |

TABLE 2-6

| Poly- | |
|---|---|
| mer | Structural formula |
| G- 110 | 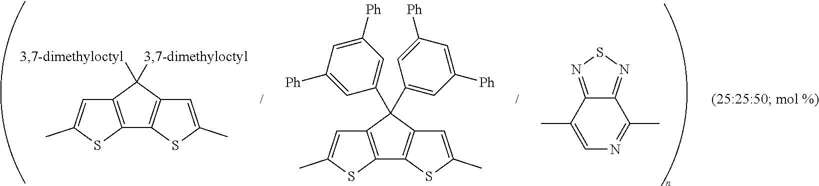 |
| G- 111 | 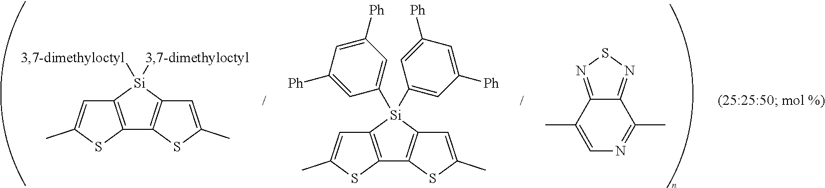 |
| G- 112 | 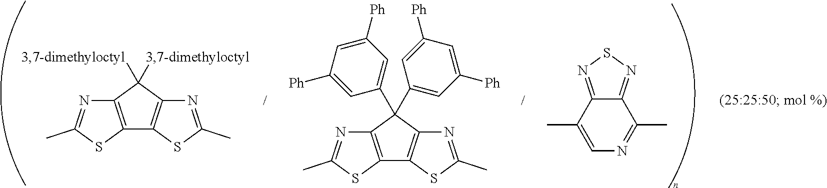 |
| G- 113 | 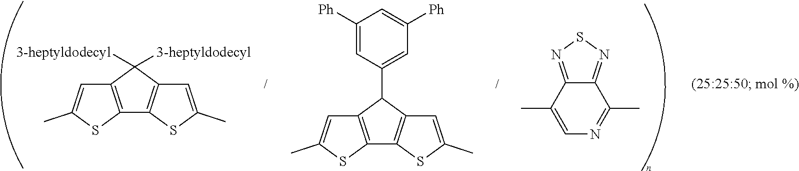 |
| G- 114 | 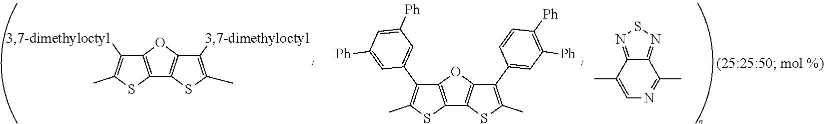 |

TABLE 2-7

| Poly- | |
|---|---|
| mer | Structural formula |
| G- 115 | 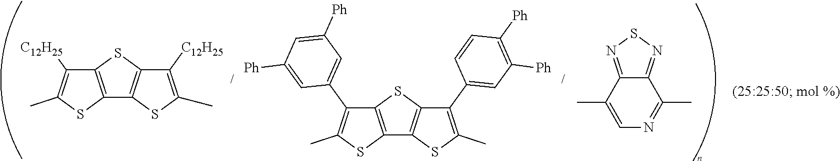 |
| G- 116 | 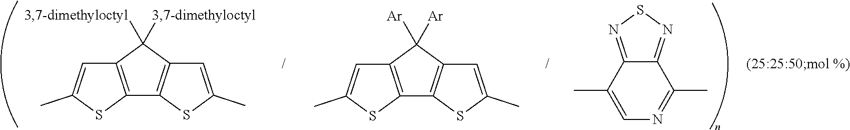 |
| | 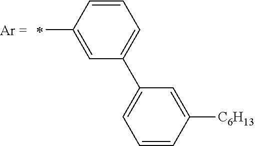 |
| G- 117 | 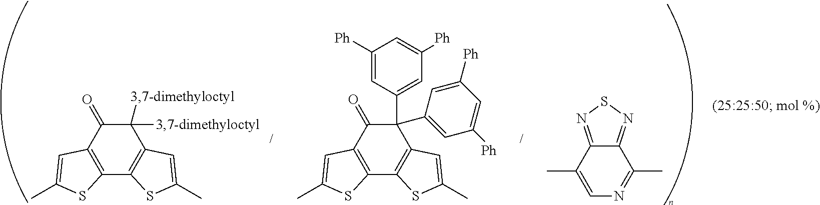 |
| G- 118 | 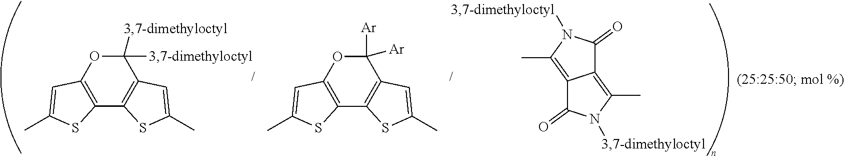 |
| | 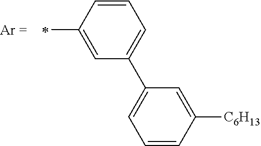 |

TABLE 2-8

| Polymer | Structural formula |
|---|---|
| G-119 | 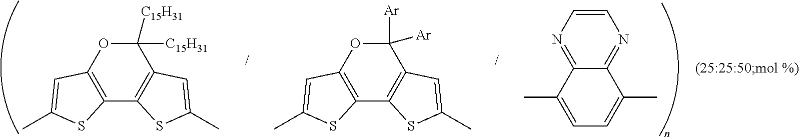 |
| | 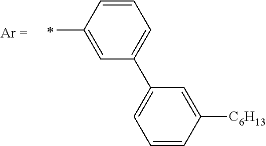 |
| G- 120 | 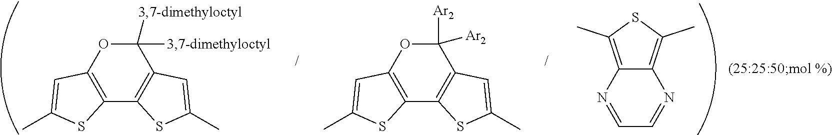 |
| | 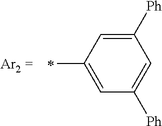 |
| G- 121 | 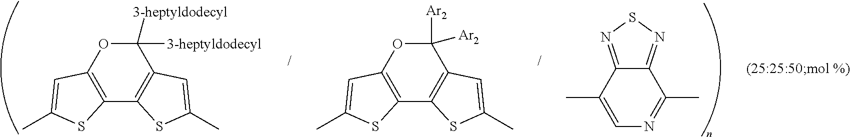 |
| | 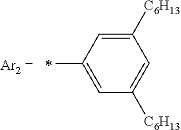 |

TABLE 2-9

| Polymer | Structural formula |
|---|---|
| G- 122 | 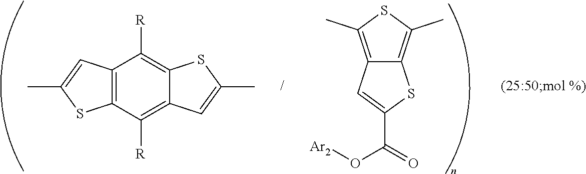 |
| | 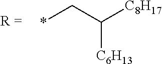 |
| | 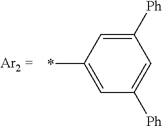 [SMILES: *c1cc(-c2ccccc2)cc(-c2ccccc2)c1] |
| G- 123 | 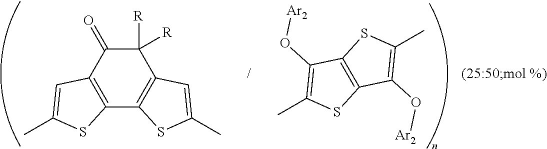 |
| | 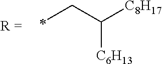 |
| | 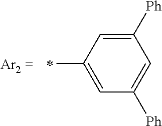 |

TABLE 2-10

| Polymer | Structural formula |
|---|---|
| G- 124 | 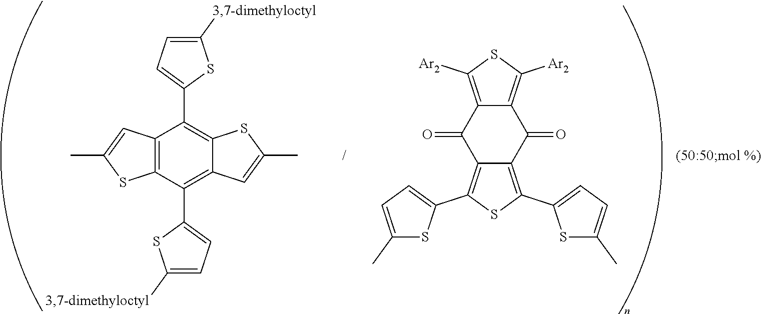 |
| | 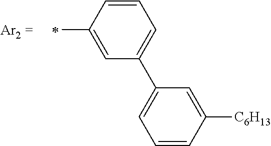 |

### —Weight Average Molecular Weight of Polymer—

From the viewpoint of suppressing dark current, the polymer according to the present disclosure preferably has a weight average molecular weight of 6,000 or more, more preferably 6,000 or more and 100,000 or less, more preferably 7,000 or more and 90,000 or less, and still more preferably 8,000 or more and 80,000 or less.

The weight average molecular weight is a weight average molecular weight in terms of polystyrene determined by size extrusion chromatography (SEC).

### —Weighted Average of Side Chains—

In the polymer according to the present disclosure, a weighted average of formula weights of the side chains weighted by a molar ratio of the structural units contained in the polymer (hereinafter, also referred to as “specific side chain average formula amount”) is 160 or more, and from the viewpoint of suppressing dark current, the weighted average is preferably 160 or more and 300 or less, more preferably 165 or more and 250 or less, and still more preferably 170 or more and 230 or less.

The specific side chain average formula amount is calculated as follows.

The side chain is specified for each structural unit contained in the polymer. Then, a total value of the formula weights of the side chains specified for each structural unit is calculated. Subsequently, a weighted average of the total value of the formula weights of the side chains weighted by the molar ratio of the structural units is calculated, and the value is taken as the specific side chain average formula amount.

Hereinafter, a method for calculating the specific side chain average formula amount will be described more specifically.

For example, a case where the polymer contains the structural unit represented by Formula (I), the structural unit represented by Formula (I′), and the structural unit represented by Formula (Y1) will be described. Here, the structural unit represented by Formula (I) has a side chain A and a side chain B. The structural unit represented by Formula (I′) has a side chain C. The structural unit represented by Formula (Y1) does not have a side chain.

### Identification of Side Chain

First, the side chain is specified for each structural unit contained in the polymer. In the structural unit represented by Formula (I), side chains are a side chain A and a side chain B. In the structural unit represented by Formula (I′), a side chain is a side chain C.

### Calculation of Total Value of Formula Weights

Subsequently, a total value of the formula weights of the side chains specified for each structural unit is calculated. In the structural unit represented by Formula (I), a total value of a formula amount of the side chain A and a formula amount of the side chain B (hereinafter, the value is referred to as “side chain AB formula amount”) is calculated. In the structural unit represented by Formula (I′), a formula amount of the side chain C (hereinafter, the value is referred to as a “side chain C formula amount”) is calculated.

### Calculation of Weighted Average of Total Value of Formula Weights of Side Chains

Subsequently, a weighted average of the total value of the formula weights of the side chains weighted by the molar ratio of the structural units is calculated. The calculation formula is as follows.

$$Specific side chain average formula amount ( ( Side chain AB formula amount \times Molar ratio of structural unit represented by Formula ( I ) ) + ( Side chain C formula amount \times Molar ratio of structural unit represented by Formula ( {I}^{′} ) ) ) / 100 \qquad Formula 1$$

Note that, in the above formula, the molar ratio of each structural unit is a percentage of the number of moles of each structural unit to the total number of moles of structural units contained in the polymer.

Here, for example, in a case where the polymer contains 25 mol % of the structural unit represented by Formula (I), 25 mol % of the structural unit represented by Formula (I′), and 50 mol % of the structural unit represented by Formula (Y1), the above formula is as represented by the following Formula 2.

$$Specific side chain average formula amount = ( ( Side chain AB formula amount \times 25 ) + ( Side chain C formula amount \times 25 ) ) / 100 \qquad Formula 2$$

### —Absorption Edge Intensity—

The polymer according to the present disclosure has an absorption edge intensity of 0.08 or less, and from the viewpoint of suppressing dark current, the absorption edge intensity is preferably 0.01 or more and 0.08 or less, more preferably 0.03 or more and 0.079 or less, and still more preferably 0.04 or more and 0.075 or less.

### Measurement of Absorption Edge Intensity of Polymer

The absorption edge intensity is measured using an ultraviolet-visible infrared spectrophotometer.

As the ultraviolet-visible infrared spectrophotometer, for example, Varian Cary 5E Uv-vis-IR spectrum measurement device can be used.

A method for measuring the absorption edge intensity will be described below with reference to FIG. 1. Note that FIG. 1 is an example of an ultraviolet-visible infrared absorption spectrum of the polymer according to the present disclosure.

A thin film formed of a polymer and having a thickness of 100 nm is produced. Using the thin film as a measurement target, an ultraviolet-visible infrared absorption spectrum is obtained using an ultraviolet-visible infrared spectrophotometer (FIG. 1). A measurement wavelength is set in a range of 300 nm to 1,700 nm (scan rate: 600 nm/min). A vertical axis of the ultraviolet-visible infrared absorption spectrum is an absorption intensity expressed logarithmically. A horizontal axis represents a wavelength. A baseline of an ultraviolet-visible infrared absorption spectrum is linearly approximated, an extension line A thereof and a tailing portion of absorption existing on a long wavelength side are linearly approximated, and an absorption intensity at an intersection point C of the extension line B is defined as an absorption edge intensity.

### (Method for Producing Polymer)

A method for producing a polymer according to the present disclosure is preferably performed by reacting a compound represented by the following Formula (I-R) with a compound represented by the following Formula (Y1-R).

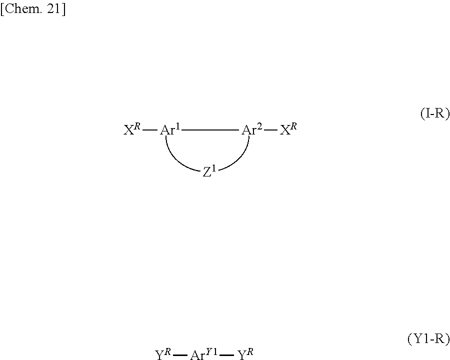

In Formula (I-R), Z¹, Ar¹, and Ar² have the same meanings as Z¹, Ar¹, and Ar² in Formula (I), and preferred aspects are also the same.

In Formula (I-R), X^{R} represents a boron-containing group. Examples of the boron-containing group include an atomic group represented by the following Formula (XR-1). In Formula (XR-1), * means a bond.

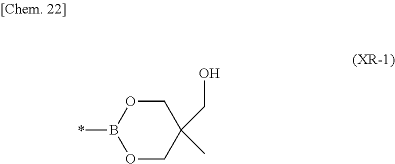 [SMILES: *B1OCC(C)(CO)CO1]

Ar^{Y1} in Formula (Y1-R) has the same meaning as Ar^{Y1} in Formula (Y1), and a preferred aspect is also the same.

In Formula (Y1-R), Y^{R}s each independently represent a halogen atom.

In the method for producing a polymer according to the present disclosure, the method for reacting the compound represented by the following Formula (I-R) with the compound represented by the following Formula (Y1-R) is not particularly limited, and from the viewpoint of ease of synthesis of a polymer, a method using the Suzuki-Miyaura coupling reaction or the Stille coupling reaction is preferable.

Examples of the method for performing the Suzuki-Miyaura coupling reaction or the Stille coupling reaction include a method in which a reaction is performed in an arbitrary solvent in the presence of a base using a palladium catalyst as a catalyst.

### <Composition>

A composition according to the present disclosure contains the polymer according to the present disclosure and an electron-accepting compound.

The composition according to the present disclosure may contain a solvent and other components as necessary.

A preferred aspect of the polymer contained in the composition according to the present disclosure is as described in the description of the polymer according to the present disclosure.

### (Electron-Accepting Compound)

The electron-accepting compound contained in the composition according to the present disclosure may be a low molecular weight compound or a high molecular weight compound. Examples of the electron-accepting compound include an oxadiazole derivative, anthraquinodimethane and a derivative thereof, benzoquinone and a derivative thereof, naphthoquinone and a derivative thereof, anthraquinone and a derivative thereof, tetracyanoanthraquinodimethane and a derivative thereof, a fluorenone derivative, a diphenyldicyanoethylene and a derivative thereof, a diphenoquinone derivative, a metal complex of 8-hydroxyquinoline and a derivative thereof, fullerene such as C₆₀ fullerene and a fullerene derivative that is a derivative thereof (hereinafter, may be referred to as a fullerene compound), and a phenanthrene derivative such as bathocuproine.

The electron-accepting compound may be fullerene such as C₆₀ fullerene and a fullerene derivative which is a derivative thereof, or may be a non-fullerene compound. Hereinafter, the fullerene and the fullerene derivative may be referred to as a fullerene compound. The non-fullerene compound means a compound other than fullerene and a fullerene derivative.

### —Fullerene Compound—

Examples of the fullerene include C₆₀ fullerene, C₇₀ fullerene, C₇₆ fullerene, C₇₈ fullerene, and C₈₄ fullerene. Examples of the fullerene derivative include derivatives of these fullerenes. The fullerene derivative means a compound in which at least a part of fullerene is modified.

Examples of the fullerene derivative include compounds represented by the following Formulas.

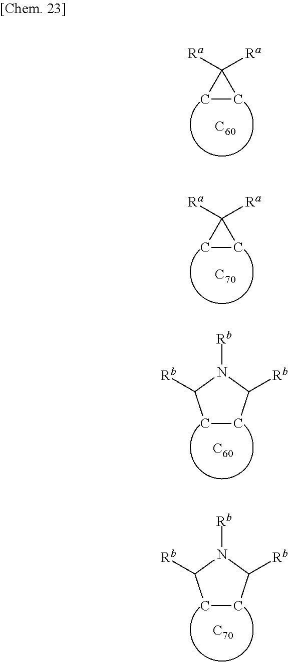

In the above formula,
R^{a} represents an alkyl group, a cycloalkyl group, an aryl group, a monovalent heterocyclic group, or a group having an ester structure, and these groups optionally have a substituent. The plurality of R^{a}'s may be the same as or different from each other.
R^{b} represents an alkyl group, a cycloalkyl group, or an aryl group, an arylalkyl group, and these groups optionally have a substituent. The plurality of R^{b}'s may be the same as or different from each other.

Examples of the substituent include the above-described substituent A.

Examples of the group represented by R^{a} and having an ester structure include groups represented by the following formulas.

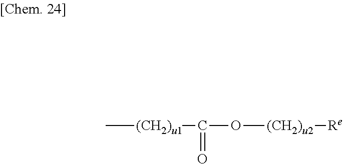

In the above formula, u1 represents an integer of 1 or more and 6 or less. u2 represents an integer of 0 or more and 6 or less. Re represents an alkyl group, a cycloalkyl group, an aryl group, or a monovalent heterocyclic group, and these groups optionally have a substituent.

Examples of the substituent include the above-described substituent A.

Examples of the C₆₀ fullerene derivative include the following compounds.

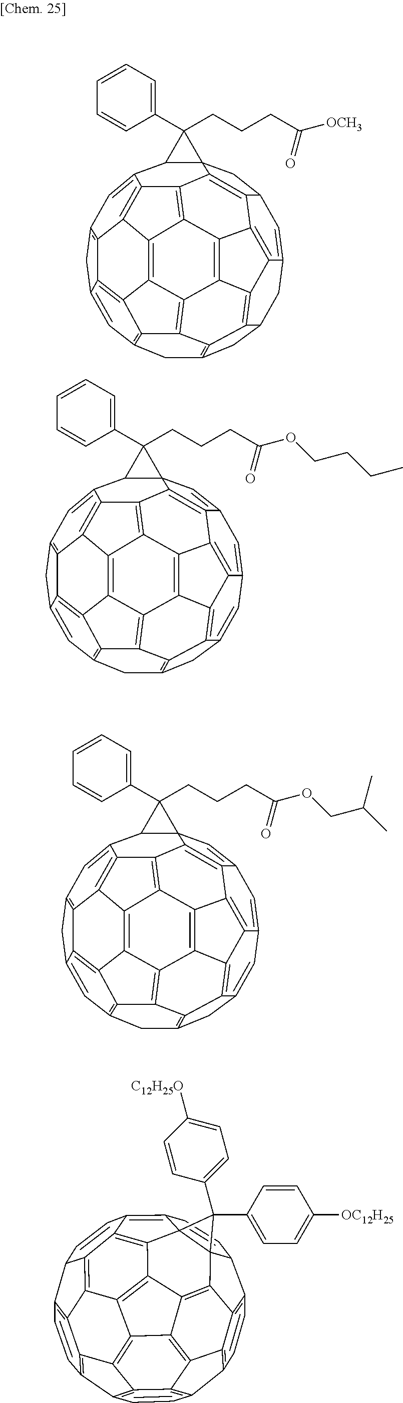

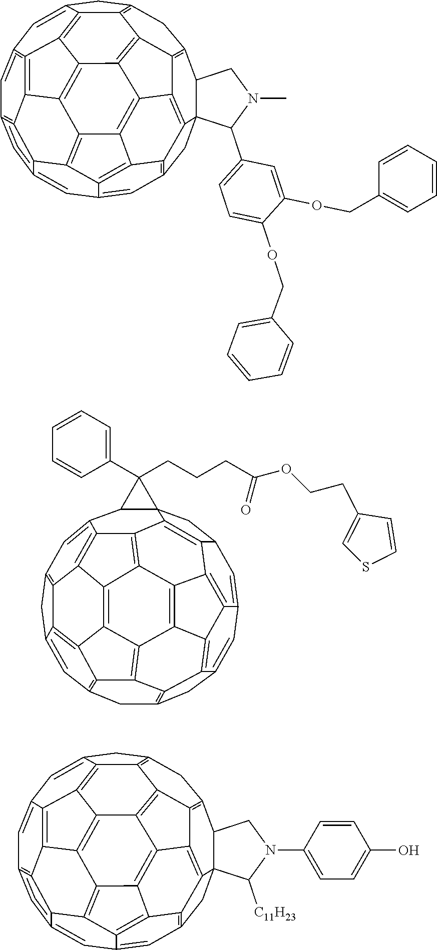

Examples of the C₇₀ fullerene derivative include the following compounds.

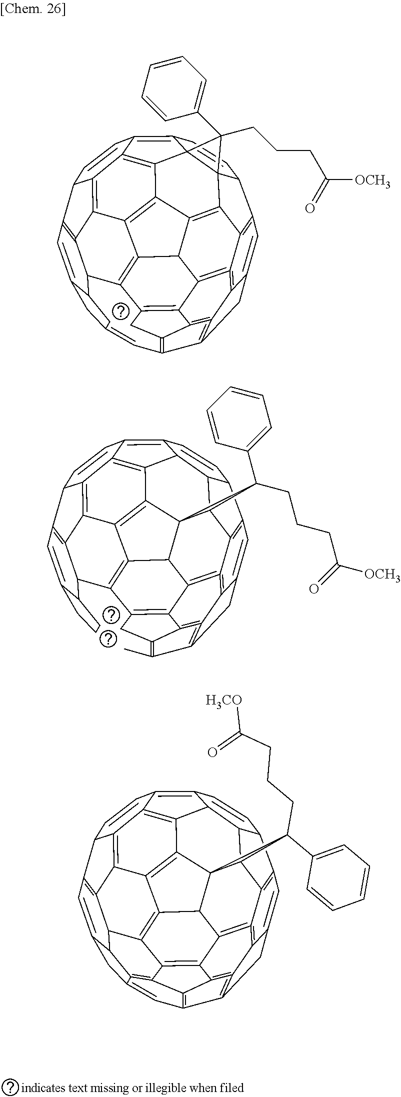

Specific examples of the fullerene derivative include [6,6]-phenyl-C61 butyric acid methyl ester (C60PCBM), [6,6]-phenyl-C71 butyric acid methyl ester (C70PCBM), [6,6]-phenyl-C85 butyric acid methyl ester (C84PCBM), and [6,6]-thienyl-C61 butyric acid methyl ester.

### —Non-Fullerene Compound—

The non-fullerene compound is not particularly limited, and conventionally known compounds can be applied.

From the viewpoint of suppressing dark current, the non-fullerene compound is preferably a compound having a perylene tetracarboxylic acid diimide structure or a compound having an A-D-A type structure represented by the following Formula (VI).

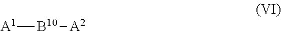

In the Formula (VI),
A¹ and A² each independently represent an electron-withdrawing group, and B¹⁰ represents a group having a π-conjugated system.

Examples of the electron-withdrawing group represented by A¹ or A² include a group represented by —CH═C(—CN)₂ and groups represented by the following Formulas (a-1) to (a-9).

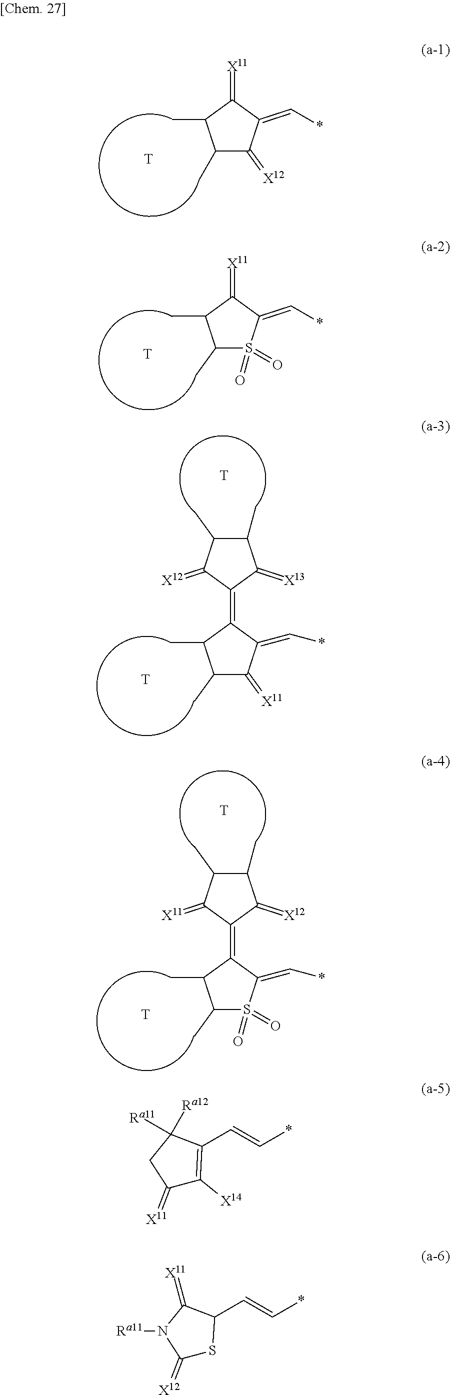

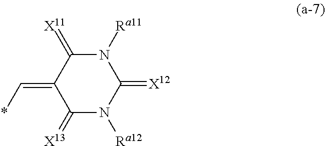

In Formulas (a-1) to (a-7),

T represents a carbocyclic ring or a heterocyclic ring. Each of the carbocyclic ring and the heterocyclic ring may be a single ring or a condensed ring. In a case where these rings have a plurality of substituents, the plurality of substituents may be the same as or different from each other. Examples of the substituent include the above-described substituent A.

Examples of the carbocyclic ring as T include an aromatic carbocyclic ring, and an aromatic carbocyclic ring is preferable. Specific examples of the carbocyclic ring as T include a benzene ring, a naphthalene ring, an anthracene ring, a tetracene ring, a pentacene ring, a pyrene ring, and a phenanthrene ring, a benzene ring, a naphthalene ring, and a phenanthrene ring are preferable, a benzene ring and a naphthalene ring are more preferable, and a benzene ring is still more preferable. The carbocyclic ring optionally has a substituent, examples of the substituent include the above-described substituent A, and the substituent is preferably at least one selected from the group consisting of a fluorine atom and an alkyl group having 1 or more and 6 or less carbon atoms.

Examples of the heterocyclic ring as T include an aromatic heterocyclic ring, and an aromatic heterocyclic ring is preferable. Specific examples of the heterocyclic ring as T include a pyridine ring, a pyridazine ring, a pyrimidine ring, a pyrazine ring, a pyrrole ring, a furan ring, a thiophene ring, an imidazole ring, an oxazole ring, a thiazole ring, and a thienothiophene ring, a thiophene ring, a pyridine ring, a pyrazine ring, a thiazole ring, and a thienothiophene ring are preferable, and a thiophene ring is more preferable. The heterocyclic ring optionally has a substituent, examples of the substituent include the above-described substituent A, and the substituent is preferably at least one selected from the group consisting of a fluorine atom and an alkyl group having 1 or more and 6 or less carbon atoms.

X¹¹, X¹², and X¹³ each independently represent an oxygen atom, a sulfur atom, an alkylidene group, or a group represented by ═C(—CN)₂, and are preferably an oxygen atom, a sulfur atom, or a group represented by ═C(—CN)₂.

X¹⁴ represents a hydrogen atom, a halogen atom, a cyano group, an alkyl group, an alkyloxy group, an aryl group or a monovalent heterocyclic group.

These groups optionally have a substituent, and examples of the substituent include the above-described substituent A.

R^{a11} and R^{a12} each independently represent a hydrogen atom, an alkyl group, a halogen atom, an alkoxy group, an aryl group, or a monovalent heterocyclic group, and preferably represent an alkyl group or an aryl group. These groups optionally have a substituent, and examples of the substituent include the above-described substituent A.

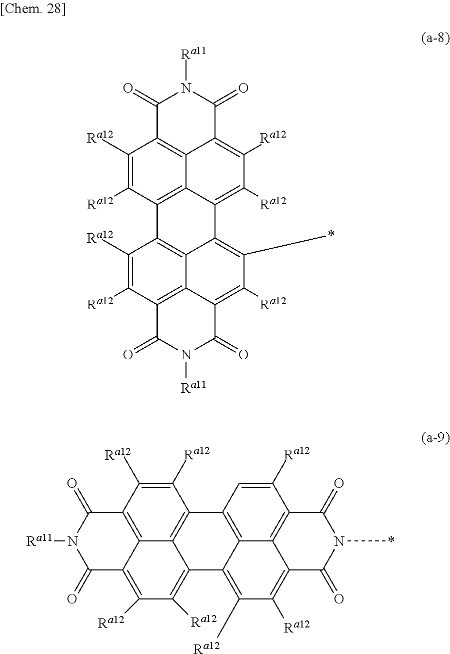

In Formulas (a-8) and (a-9), R^{a11} and R^{a12} have the same meanings as R^{a11} and R^{a12} in Formulas (a-1) to (a-7), and preferred aspects are also the same.

The electron-withdrawing group represented by A¹ or A² is preferably a group represented by any one of the following Formula (a-1-1) to the following Formula (a-1-4) and (a-6-1) and (a-7-1), and is more preferably a group represented by Formula (a-1-1). Here, a plurality of R^{a10}'s each independently represent a hydrogen atom or a substituent, and preferably represent a hydrogen atom, a halogen atom, a cyano group, or an alkyl group optionally having a substituent. R^{a11} and R^{a12} have the same meanings as R^{a11} and R^{a12} in Formulas (a-1) to (a-7), and preferred aspects are also the same.

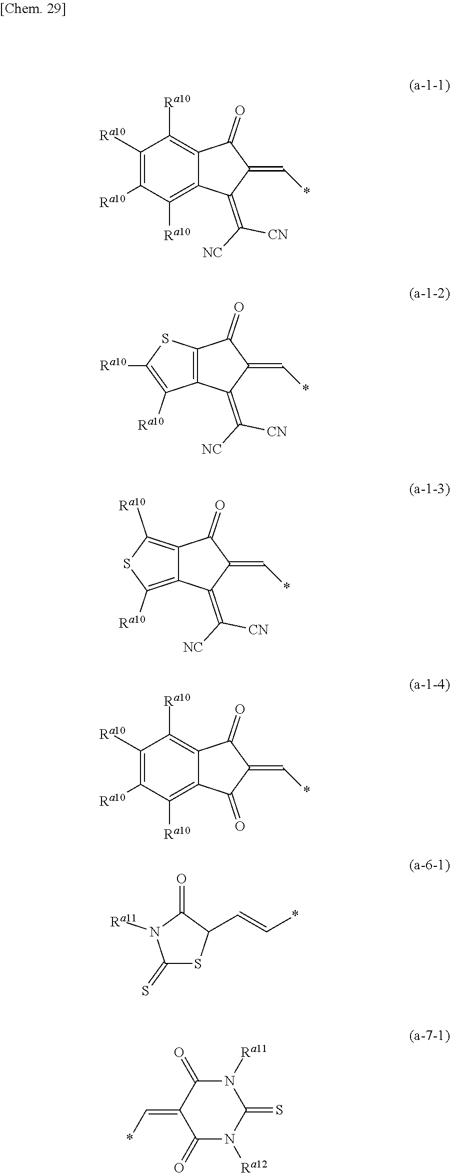

Examples of the group which is represented by B¹⁰ and has a π-conjugated system include a group represented by —(S¹)ₙ₁—B¹¹—(S²)ₙ₂— in a compound represented by Formula (VII) described below.

The non-fullerene compound is preferably a compound represented by the following Formula (VII).

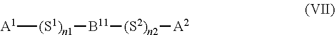

In Formula (VII), A¹ and A² have the same meaning as A¹ and A² in Formula (VI), and preferred aspects are also the same.

S¹ and S² each independently represent a divalent carbocyclic group, a divalent heterocyclic group, or a group represented by —C(R^{s1})═C(R^{s2})— (where R^{s1} and R^{s2} each independently represent a hydrogen atom, a substituent (preferably represents a hydrogen atom, a halogen atom, an alkyl group, or a monovalent heterocyclic group), or a group represented by —C≡C—). These groups optionally have a substituent, and examples of the substituent include the above-described substituent A.

In Formula (VII), n1 and n2 each independently represent an integer of 0 or more and preferably each independently represent 0 or 1, and n1 and n2 more preferably represent 0 or 1 at the same time.

S¹ and S² are each independently preferably a group represented by the following Formula (s-1) or (s-2).

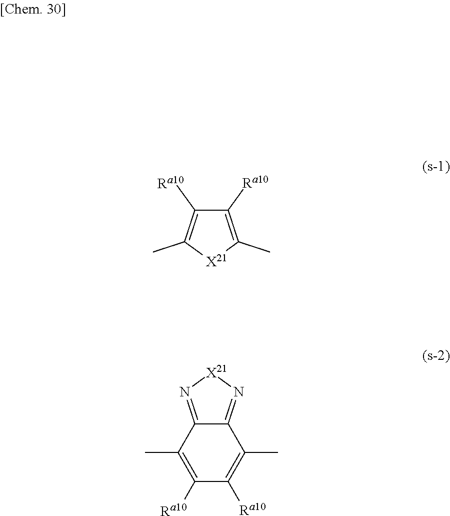

In Formulas (s-1) and (s-2),
X²¹ represents an oxygen atom or a sulfur atom.
R^{a10} has the same meaning as R^{a10} in Formulas (a-1-1) to (a-1-4) and Formulas (a-6-1) and (a-7-1), and preferred aspects are also the same.

In Formula (VII), B¹¹ represents a condensed ring group having two or more structures selected from the group consisting of a carbocyclic structure and a heterocyclic structure, a condensed ring group that does not have an ortho-peri-condensed structure, and a condensed ring group optionally having a substituent.

Here, the condensed ring group means a remaining atomic group excluding one or more hydrogen atoms directly bonded to carbon atoms or heteroatoms constituting a condensed ring.

Examples of a carbocyclic structure that constitutes the condensed ring group represented by B¹¹ include a ring structure represented by the following Formula (Cy1) or (Cy2).

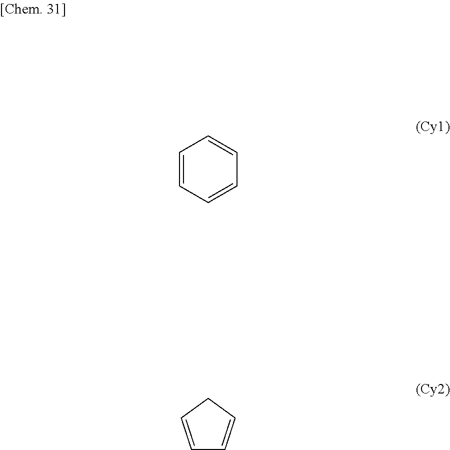 [SMILES: c1ccccc1 ; C1=CCC=C1]

Examples of a heterocyclic structure that constitutes the condensed ring group represented by B¹¹ include a ring structure represented by any one of the following Formulas (Cy3) to (Cy10).

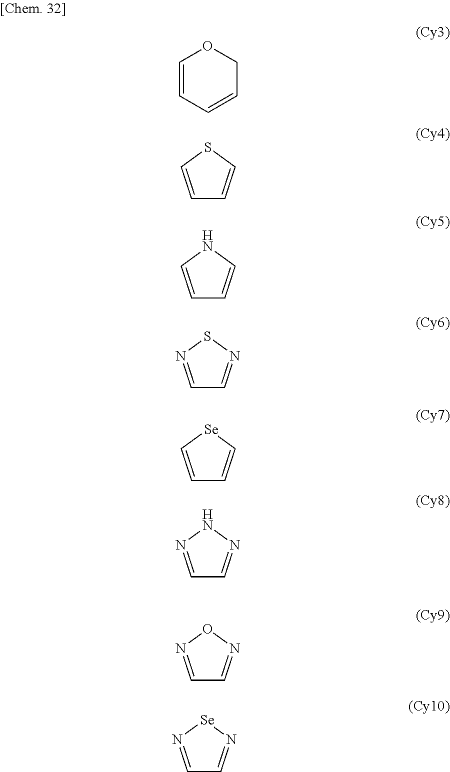

In Formula (VII), B¹¹ is preferably a condensed ring group having two or more structures selected from the group consisting of structures represented by Formulas (Cy1) to (Cy10), a condensed ring group that does not have an ortho-peri-condensed structure, or a condensed ring group optionally having a substituent. B¹¹ may have a structure obtained by condensing two or more identical structures among the structures represented by Formulas (Cy1) to (Cy10).

B¹¹ is more preferably a condensed ring group having two or more structures selected from the group consisting of structures represented by Formulas (Cy1) to (Cy6) and (Cy8), or a condensed ring group that does not have an ortho-peri-condensed structure. The condensed ring group optionally has a substituent, and examples of the substituent include the above-described substituent A.

Examples of the condensed ring group represented by B¹¹ include groups represented by the following Formulas (b-1) to (b-14), and a group in which a hydrogen atom in this group is further substituted with a substituent (preferably, an alkyl group optionally having a substituent, an aryl group optionally having a substituent, an alkyloxy group optionally having a substituent, or a monovalent heterocyclic group optionally having a substituent).

As the condensed ring group represented by B¹¹, a group represented by the following Formula (b-2) or (b-3), or a group in which a hydrogen atom in this group is further substituted with a substituent (preferably, an alkyl group optionally having a substituent, an aryl group optionally having a substituent, an alkyloxy group optionally having a substituent, or a monovalent heterocyclic group optionally having a substituent) is preferable, and a group represented by the following Formula (b-2) or (b-3) is more preferable.

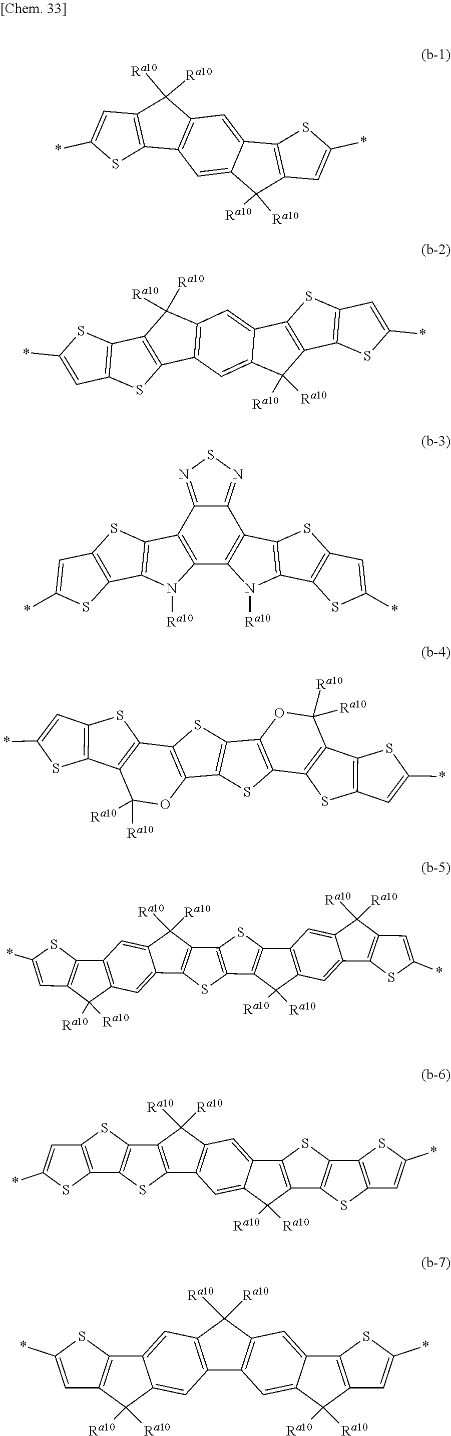

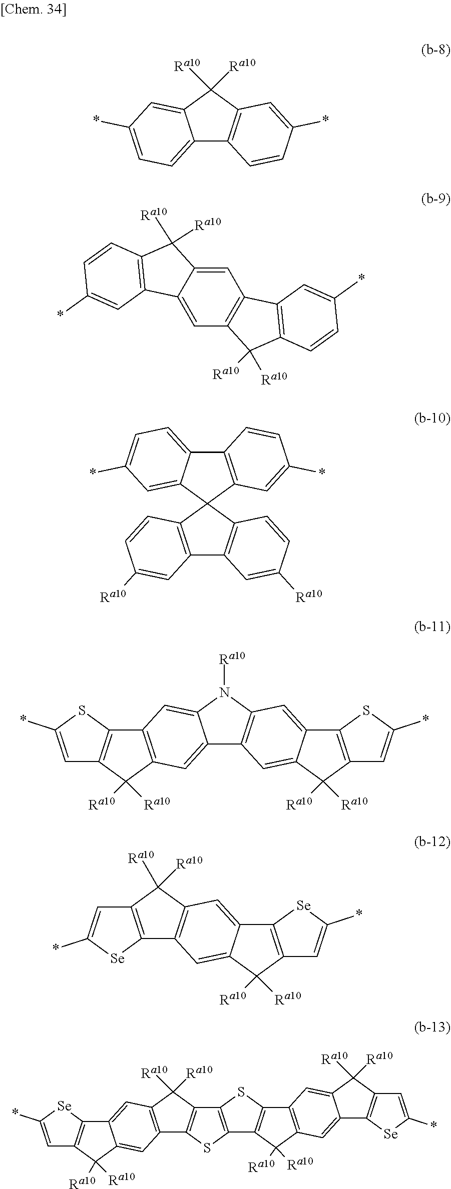

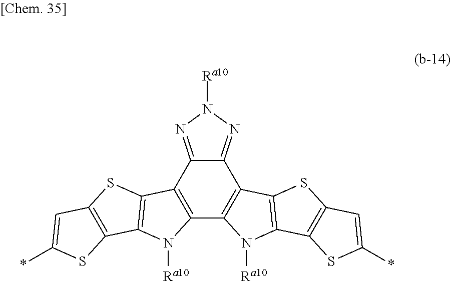

In Formulas (b-1) to (b-14), R^{a10} has the same meaning as R^{a10} in Formulas (a-1-1) to (a-1-4) and Formulas (a-6-1) and (a-7-1), and preferred aspects are also the same.

Examples of the compound represented by Formula (VI) or Formula (VII) include a compound represented by the following formula.

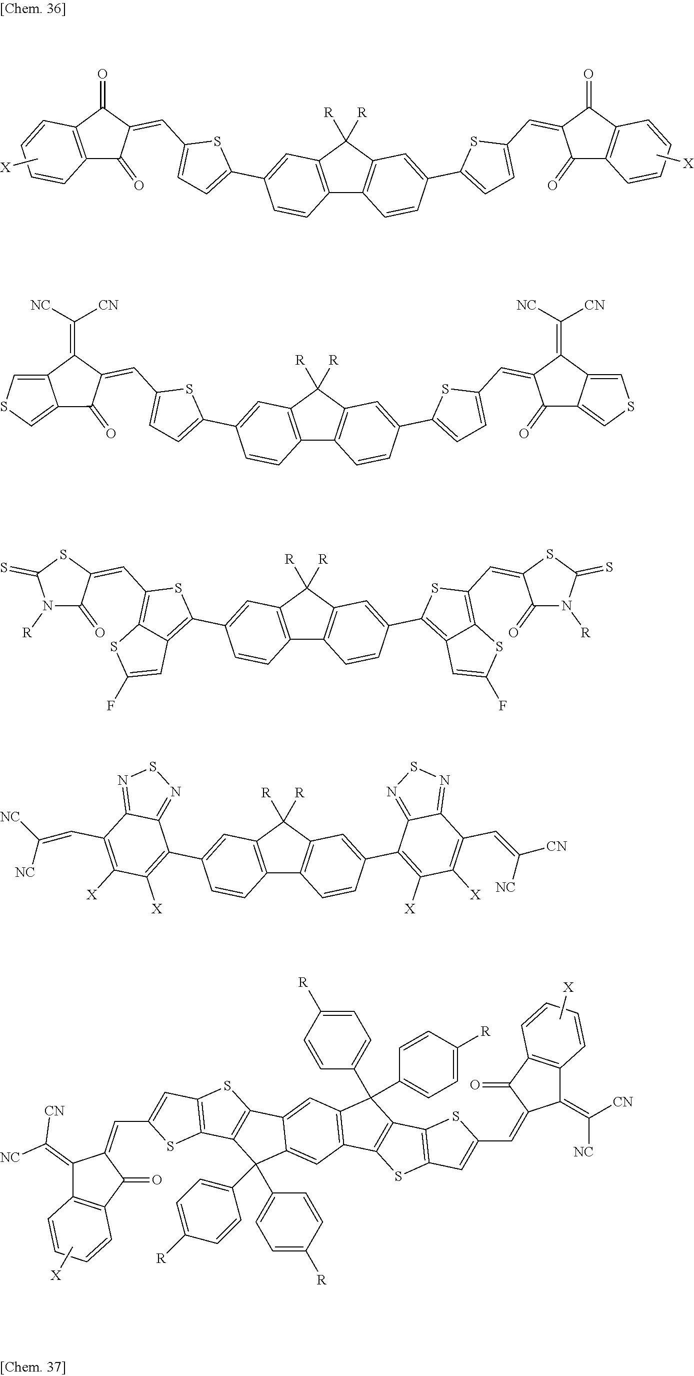

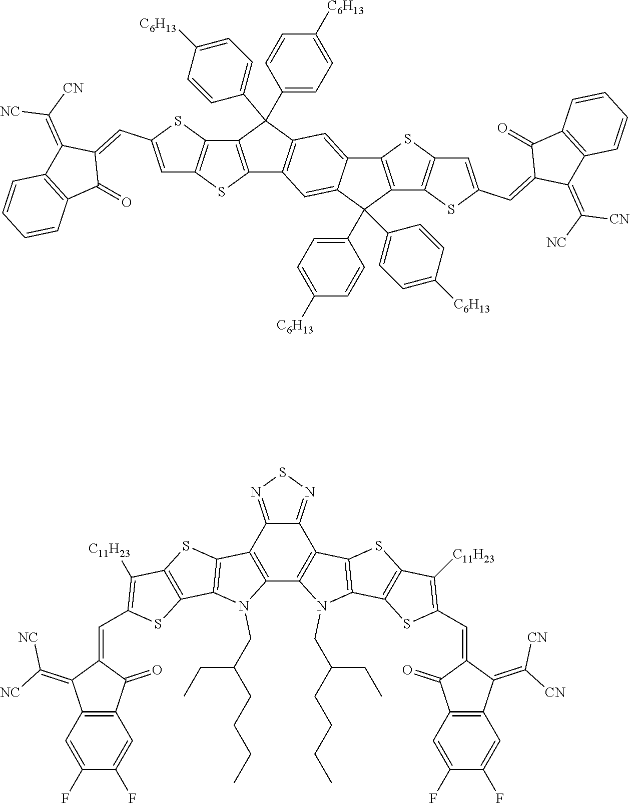

In the above formula, R represents a substituent, and examples of the substituent include the above-described substituent A.

In the above formula, X represents a hydrogen atom, a halogen atom, a cyano group, or an alkyl group.

In the above formula, R is preferably a hydrogen atom, an alkyl group, an aryl group, or an alkyloxy group.

The composition according to the present disclosure may contain only a non-fullerene compound as an electron-accepting compound, may contain only a fullerene compound, or may contain a combination of a non-fullerene compound and a fullerene compound.

Preferred specific examples of the electron-accepting compound contained in the composition include a compound represented by the following formula.

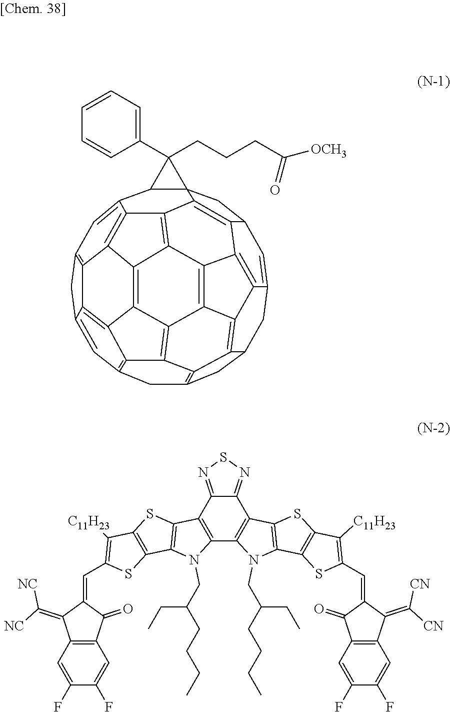

In the composition according to the present disclosure, a content of the electron-accepting compound is preferably 0.1 mass % or more and 20 mass % or less, and more preferably 1 mass % or more and 10 mass % or less, with respect to the mass of the entire composition.

In the composition according to the present disclosure, a content of the polymer according to the present disclosure with respect to the content of the electron-accepting compound (the content of the polymer according to the present disclosure/the content of the electron-accepting compound) is preferably 1/9 or more and 9/1 or less, more preferably 1/5 or more and 5/1 or less, and still more preferably 1/3 or more and 3/1 or less.

In the composition according to the present disclosure, a total content of the polymer according to the present disclosure and the electron-accepting compound is preferably 0.01 mass % or more and 20 mass % or less, more preferably 0.01 mass % or more and 10 mass % or less, still more preferably 0.01 mass % or more and 5 mass % or less, and particularly preferably 0.1 mass % or more and 5 mass % or less, with respect to the mass of the entire composition.

### (Solvent)

The composition according to the present disclosure may contain a solvent as necessary.

Examples of the solvent include an aromatic hydrocarbon, an alkyl halide, an aromatic carbonyl compound, an aromatic ester compound, and a nitrogen-containing heterocyclic compound.

The aromatic hydrocarbon is not particularly limited, and is preferably a compound capable of dissolving the polymer according to the present disclosure.

The aromatic hydrocarbon optionally has a substituent, and examples of the substituent include the above-described substituent A.

Examples of the aromatic hydrocarbon include toluene, xylene (for example, o-xylene, m-xylene, or p-xylene), trimethylbenzene (for example, mesitylene or 1,2,4-trimethylbenzene (pseudocumene)), butylbenzene (for example, n-butylbenzene, sec-butylbenzene, or tert-butylbenzene), methylnaphthalene (for example, 1-methylnaphthalene), 1,2,3,4-tetrahydronaphthalene (tetralin), indane, 1-chloronaphthalene, chlorobenzene, and dichlorobenzene (1,2-dichlorobenzene).

The aromatic hydrocarbon is preferably one or more selected from the group consisting of toluene, o-xylene, m-xylene, p-xylene, mesitylene, 1,2,4-trimethylbenzene, n-butylbenzene, sec-butylbenzene, tert-butylbenzene, methylnaphthalene, tetralin, 1-chloronaphthalene, chlorobenzene, and dichlorobenzene (1,2-dichlorobenzene).

Examples of the alkyl halide include chloroform.

Examples of the aromatic carbonyl compound include acetophenone, propiophenone, butyrophenone, cyclohexyl phenyl ketone, and benzophenone.

Examples of the aromatic ester compound include methyl benzoate, ethyl benzoate, propyl benzoate, butyl benzoate, isopropyl benzoate, benzyl benzoate, cyclohexyl benzoate, and phenyl benzoate.

Examples of the nitrogen-containing heterocyclic compound include pyridine, quinoline, quinoxaline, 1,2,3,4-tetrahydroquinoline, pyrimidine, pyrazine, and quinazoline.

A content of the solvent is preferably 80 mass % or more and 100 mass % or less, and more preferably 90 mass % or more and 100 mass % or less, with respect to the mass of the entire composition.

The composition according to the present disclosure may contain other components as necessary.

Examples of the other components include an ultraviolet absorber, an antioxidant, a sensitizer for sensitizing a function of generating a charge by absorbed light, and a light stabilizer for increasing stability from ultraviolet light.

A content of the other components is preferably 0 mass % or more and 10 mass % or less, and may be 0 mass %, with respect to the mass of the entire composition.

### (Method for Producing Composition)

The composition can be produced by a conventionally known method. The solvent, the polymer according to the present disclosure, and the electron-accepting compound may be mixed by heating to a temperature equal to or lower than a boiling point of the solvent.

After mixing the solvent, the polymer according to the present disclosure, and the electron-accepting compound, the obtained mixture may be filtered using a filter, and the obtained filtrate may be used as a composition. As the filter, for example, a filter formed of a fluororesin such as polytetrafluoroethylene (PTFE) can be used.

### (Application of Composition)

The composition can be preferably used as an ink for forming a film containing the polymer according to the present disclosure and the electron-accepting compound by a coating method.

In the present specification, the “ink” means a liquid material used in a coating method, and is not limited to a colored liquid. In addition, the “coating method” includes a method for forming a film (layer) using a liquid material. Examples of the coating method include a slot die coating method, a slit coating method, a knife coating method, a casting method, a micro-gravure coating method, a gravure coating method, a bar coating method, a roll coating method, a wire bar coating method, a dip coating method, a spray coating method, a screen printing method, a gravure printing method, a flexographic printing method, an offset printing method, an inkjet coating method, a dispenser printing method, a nozzle coating method, and a capillary coating method.

### <Film>

A film according to the present disclosure contains the polymer according to the present disclosure.

The film according to the present disclosure preferably contains the polymer according to the present disclosure and an electron-accepting compound.

A preferred aspect of the polymer contained in the film according to the present disclosure is as described in the description of the polymer according to the present disclosure.

In a case where the film according to the present disclosure contains an electron-accepting compound, examples of the electron-accepting compound contained in the film according to the present disclosure include the same compounds as those contained in the composition according to the present disclosure described above, and preferred aspects are also the same.

In the film according to the present disclosure, a content of the polymer according to the present disclosure is preferably 1 mass % or more and 99 mass % or less, more preferably 10 mass % or more and 90 mass % or less, and still more preferably 20 mass % or more and 80 mass % or less.

In the film according to the present disclosure, a content of the electron-accepting compound is preferably 1 mass % or more and 99 mass % or less, more preferably 10 mass % or more and 90 mass % or less, and still more preferably 20 mass % or more and 80 mass % or less.

In the film according to the present disclosure, a content of the polymer according to the present disclosure with respect to the content of the electron-accepting compound (the content of the polymer according to the present disclosure/the content of the electron-accepting compound) is preferably 1/9 or more and 9/1 or less, more preferably 1/5 or more and 5/1 or less, and still more preferably 1/3 or more and 3/1 or less.

The film according to the present disclosure may contain a solvent, and it is preferable that the film does not substantially contain a solvent.

In the film according to the present disclosure, a content of the solvent is preferably 0 mass % or more and 1 mass % or less, more preferably 0 mass % or more and 0.1 mass % or less, and still more preferably 0 mass %.

An absorption edge intensity of the film according to the present disclosure is preferably 0.17 or less, and from the viewpoint of suppressing dark current, the absorption edge intensity of the film is preferably 0.01 or more and 0.17 or less, more preferably 0.03 or more and 0.17 or less, and still more preferably 0.04 or more and 0.16 or less.

### Measurement of Absorption Edge Intensity of Film

The absorption edge intensity of the film is measured using an ultraviolet-visible infrared spectrophotometer.

The method for measuring the absorption edge intensity of the film is the same as the method for measuring the absorption edge intensity of the polymer described above except that a thin film having the same composition as that of the film and having a thickness of 100 nm is to be measured.

The method for producing a film according to the present disclosure is not particularly limited, and the film is produced by any method.

For example, the film according to the present disclosure can be produced by a production method including a step (i) of applying the composition according to the present disclosure to a target to be applied to obtain a coating film and a step (ii) of removing a solvent from the obtained coating film.

### (Step (i))

In the step (i), as a method for applying the composition to the target to be applied, any conventionally known application method can be used. Specific examples of the coating method are as described above.

In the step (i), the composition is applied to any target to be coated. The composition can be applied to a functional layer that can be included in a photoelectric conversion element, such as an electrode (anode or cathode), an electron transport layer, or a hole transport layer, in a step of manufacturing the photoelectric conversion element.

(Step (ii))

In the step (ii), any preferred method can be used as a method for removing the solvent from the coating film of the composition formed in the step (i).

Examples of the method for removing the solvent include drying methods such as a hot air drying method, an infrared heating drying method, a flash lamp annealing drying method, and a reduced pressure drying method.

The application of the film according to the present disclosure is not particularly limited, but for example, the film can be preferably used as an active layer included in a photoelectric conversion element.

### <Electronic Element>

An electronic element according to the present disclosure contains the polymer according to the present disclosure.

The electronic element according to the present disclosure preferably includes a film containing the polymer according to the present disclosure.

Since the polymer according to the present disclosure can exhibit high electron and/or high hole transporting properties, in a case where the polymer according to the present disclosure is used for an electronic element, electrons and holes injected from an electrode, or charges generated by light absorption can be transported. By taking advantage of these characteristics, it can be preferably used for various electronic elements such as a photoelectric conversion element, an organic thin film transistor, and an organic electroluminescence element. Hereinafter, these elements will be individually described.

### (Photoelectric Conversion Element)

A photoelectric conversion element according to the present disclosure includes a first electrode, a second electrode, and an active layer disposed between the first electrode and the second electrode.

The active layer contains the polymer according to the present disclosure

Hereinafter, a configuration example of an embodiment of the photoelectric conversion element according to the present disclosure will be specifically described with reference to the drawings.

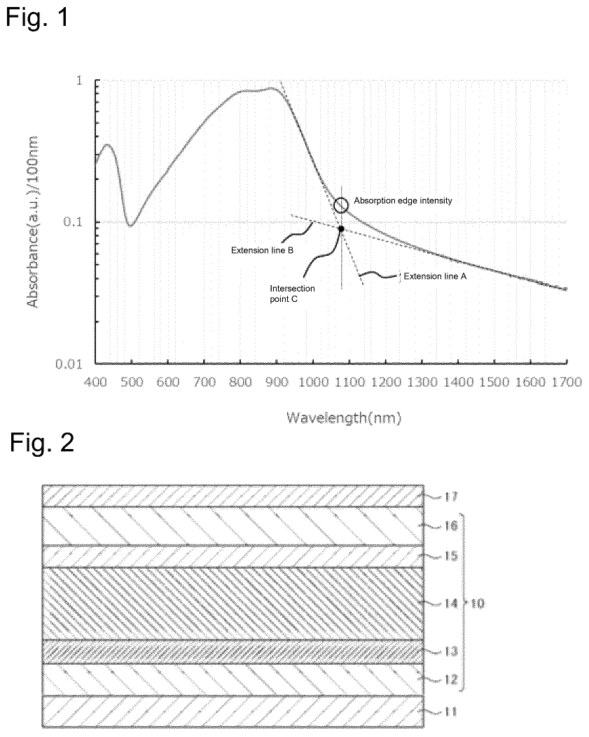

FIG. 2 is a view schematically illustrating a configuration example of the photoelectric conversion element.

As illustrated in FIG. 2, a photoelectric conversion element 10 is provided on a support substrate 11. The photoelectric conversion element 10 includes a first electrode 12 provided so as to be in contact with the support substrate 11, a first intermediate layer 13 provided so as to be in contact with the first electrode 12, an active layer 14 provided so as to be in contact with the first intermediate layer 13, a second intermediate layer 15 provided so as to be in contact with the active layer 14, and a second electrode 16 provided so as to be in contact with the second intermediate layer 15. In this configuration example, a sealing member 17 is further provided so as to be in contact with the second electrode 16. In this configuration example, both the first intermediate layer 13 and the second intermediate layer 15 are provided, but only one of the first intermediate layer 13 and the second intermediate layer 15 may be provided. For example, the first intermediate layer 13 may not be provided. For example, the second intermediate layer 15 may not be provided.

Hereinafter, constituent elements that can be included in an embodiment of the photoelectric conversion element according to the present disclosure will be specifically described.

### (Substrate)

The photoelectric conversion element is usually formed on a substrate (support substrate). In addition, there is also a case where sealing is performed by a substrate (sealing substrate). One of a pair of electrodes including a first electrode and a second electrode is usually formed on the substrate. A material of the substrate is not particularly limited as long as it is a material that is not chemically changed particularly when a layer containing an organic compound is formed.

Examples of the material of the substrate include glass, plastic, a polymer film, and silicon. In a case where an opaque substrate is used, it is preferable that an electrode (in other words, the electrode provided on a side far from the opaque substrate) provided on an opposite side to an electrode provided on the opaque substrate is a transparent or translucent electrode.

### (Electrode)

The photoelectric conversion element includes a first electrode and a second electrode that are a pair of electrodes. At least one electrode of the first electrode and the second electrode is preferably a transparent or translucent electrode in order to allow light to be incident.

Examples of a material of the transparent or translucent electrode include a conductive metal oxide film and a translucent metal thin film. Specific examples of the material of the transparent or translucent electrode include indium oxide, zinc oxide, tin oxide, and a conductive material such as indium tin oxide (ITO), indium zinc oxide (IZO), or NESA, which is a composite thereof, gold, platinum, silver, and copper. As the material of the transparent or translucent electrode, ITO, IZO, or tin oxide is preferable. In addition, as the electrode, a transparent conductive film using an organic compound such as polyaniline and a derivative thereof, or polythiophene and a derivative thereof, as a material, may be used. The transparent or translucent electrode may be the first electrode or the second electrode.

When one electrode of the pair of electrodes is transparent or translucent, the other electrode may be an electrode having low light transmittance. Examples of the material of the electrode having low light transmittance include a metal and a conductive polymer. Specific examples of a material of the electrode having low light transmittance include metals such as lithium, sodium, potassium, rubidium, cesium, magnesium, calcium, strontium, barium, aluminum, scandium, vanadium, zinc, yttrium, indium, cerium, samarium, europium, terbium, and ytterbium, and an alloy of two or more of these metals, an alloy of one or more of these metals and one or more metals selected from the group consisting of gold, silver, platinum, copper, manganese, titanium, cobalt, nickel, tungsten, and tin, graphite, a graphite interlayer compound, polyaniline and a derivative thereof, and polythiophene and a derivative thereof. Examples of the alloy include a magnesium-silver alloy, a magnesium-indium alloy, a magnesium-aluminum alloy, an indium-silver alloy, a lithium-aluminum alloy, a lithium-magnesium alloy, a lithium-indium alloy, and a calcium-aluminum alloy.

### (Active Layer)

The photoelectric conversion element according to the present disclosure includes an active layer containing the polymer according to the present disclosure.

As the active layer, the film according to the present disclosure described above can be applied.

The active layer has a bulk heterojunction type structure.

A thickness of the active layer is not particularly limited. The thickness of the active layer can be any suitable thickness in consideration of a balance between suppression of dark current and extraction of a generated photocurrent. The thickness of the active layer is preferably 100 nm or more and 10 μm or less, more preferably 150 nm or more and 5 μm or less, and still more preferably 200 nm or more and 1 μm or less, particularly from the viewpoint of further reducing the dark current.

### (Intermediate Layer)

As illustrated in FIG. 2, the photoelectric conversion element according to the present disclosure preferably includes an intermediate layer (buffer layer) such as a charge transport layer (an electron transport layer, a hole transport layer, an electron injection layer, or a hole injection layer) as a constituent element for improving characteristics such as photoelectric conversion efficiency.

In addition, examples of a material used for the intermediate layer include a metal such as calcium, an inorganic oxide semiconductor such as molybdenum oxide or zinc oxide, and a mixture (PEDOT:PSS) of poly(3,4-ethylenedioxythiophene) (PEDOT) and poly(4-styrenesulfonate) (PSS).

The intermediate layer can be formed by any suitable conventionally known formation method. The intermediate layer can be formed by a vacuum vapor deposition method or a coating method similar to that in the formation method of the active layer.

As illustrated in FIG. 2, the photoelectric conversion element preferably includes an electron transport layer as the first intermediate layer between the first electrode and the active layer. The photoelectric conversion element may or may not include a hole transport layer as the second intermediate layer between the second electrode and the active layer.

In addition, in still another embodiment, the photoelectric conversion element preferably includes an electron transport layer as the second intermediate layer between the second electrode and the active layer. In addition, in still another embodiment, the photoelectric conversion element may or may not include a hole transport layer as the first intermediate layer between the first electrode and the active layer.

The electron transport layer has a function of transporting electrons from the active layer to the electrode. The hole transport layer has a function of transporting holes from the active layer to the electrode.

The electron transport layer provided in contact with the electrode may be particularly referred to as an electron injection layer. The electron transport layer (electron injection layer) provided in contact with the electrode has a function of promoting injection of electrons into the electrode. The electron transport layer (electron injection layer) may be in contact with the active layer.

The electron transport layer contains an electron transporting material. Examples of the electron transporting material include polyalkyleneimine and a derivative thereof, a polymer compound having a fluorene structure, a metal such as calcium, and a metal oxide.

Examples of the polyalkyleneimine and the derivative thereof include a polymer obtained by polymerizing one or two or more of alkyleneimines having 2 to 8 carbon atoms, such as ethyleneimine, propyleneimine, butyleneimine, dimethylethyleneimine, pentyleneimine, hexyleneimine, heptyleneimine, and octyleneimine, particularly, alkyleneimines having 2 to 4 carbon atoms, by a normal method, and a polymer chemically modified by reacting these alkyleneimines with various compounds. As the polyalkyleneimine and the derivative thereof, polyethyleneimine (PEI) and ethoxylated polyethyleneimine (PEIE) are preferable.

Examples of the polymer compound having a fluorene structure include poly[(9,9-bis(3′-(N,N-dimethylamino)propyl)-2,7-fluoren)-ortho-2,7-(9,9′-dioctylfluorene)] (PFN) and PFN-P2.

Examples of the metal oxide include zinc oxide, gallium-doped zinc oxide, aluminum-doped zinc oxide, titanium oxide, and niobium oxide. As the metal oxide, a metal oxide containing zinc is preferable, and zinc oxide is particularly preferable.

Examples of other electron transporting materials include poly(4-vinylphenol) and perylene diimide.

The hole transport layer provided in contact with the electrode may be particularly referred to as a hole injection layer. The hole transport layer (hole injection layer) provided in contact with the electrode has a function of promoting injection of holes generated in the active layer into the electrode.

The hole transport layer contains a hole transporting material. Examples of the hole transporting material include polythiophene and a derivative thereof, an aromatic amine compound, a polymer compound containing a structural unit having an aromatic amine residue, CuSCN, CuI, NiO, tungsten oxide (WO₃), and molybdenum oxide (MoO₃).

### (Sealing Member)

It is preferable that the photoelectric conversion element according to the present disclosure further includes a sealing member and is a sealing body sealed by a sealing member.

Any suitable conventionally known member can be used as the sealing member. Examples of the sealing member include a combination of a glass substrate as a substrate (sealing substrate) and a sealing material (adhesive) as a UV curable resin.

The sealing member may be a sealing layer having a layer structure of one or more layers. Examples of the layer constituting the sealing layer include a gas barrier layer and a gas barrier film.

The sealing layer is preferably formed of a material having a property of blocking moisture (water vapor barrier property) or a property of blocking oxygen (oxygen barrier property). Examples of a preferred material as the material of the sealing layer include an organic material such as polyethylene trifluoride, polytrifluoroethylene chloride (PCTFE), polyimide, polycarbonate, polyethylene terephthalate, alicyclic polyolefin, or an ethylene vinyl alcohol copolymer, and an inorganic material such as silicon oxide, silicon nitride, aluminum oxide, or diamond-like carbon.

The sealing member is usually formed of a material that can withstand a heat treatment performed when the sealing member is incorporated into a device to which a photoelectric conversion element is applied, for example, a device of an application example described below.

In another embodiment, both or any of the first intermediate layer 13 and the second intermediate layer 15 may not be provided.

### (Method for Manufacturing Photoelectric Conversion Element)

The photoelectric conversion element can be manufactured by any suitable conventionally known manufacturing method. The photoelectric conversion element can be manufactured by combining steps suitable for the material selected for forming the constituent elements.

Hereinafter, as an example of the method for manufacturing a photoelectric conversion element, a method for manufacturing a photoelectric conversion element having a configuration in which a substrate (support substrate), a first electrode, a hole transport layer, an active layer, an electron transport layer, and a second electrode are in contact with each other in this order will be described.

### (Step of Preparing Substrate)

In the present step, for example, a support substrate provided with a first electrode is prepared. In addition, it is possible to prepare a support substrate provided with a first electrode by obtaining a substrate provided with a conductive thin film formed of the electrode material described above from the market and patterning the conductive thin film to form the first electrode, if necessary.

In the method for manufacturing a photoelectric conversion element according to the present disclosure, the method for forming the first electrode in the case of forming the first electrode on the support substrate is not particularly limited. The first electrode can be formed on a structure (for example, a support substrate, an active layer, or a hole transport layer) in which the first electrode is to be formed by any suitable conventionally known method such as a vacuum vapor deposition method, a sputtering method, an ion-plating method, a plating method, or a coating method.

### (Step of Forming Hole Transport Layer)

The method for manufacturing a photoelectric conversion element may include a step of forming a hole transport layer (hole injection layer) provided between the active layer and the first electrode.

A method for forming the hole transport layer is not particularly limited. From the viewpoint of further simplifying the step of forming the hole transport layer, it is preferable to form a hole transport layer by any suitable conventionally known coating method. The hole transport layer can be formed, for example, by a coating method or a vacuum vapor deposition method using a coating liquid containing the material that can constitute the hole transport layer described above and a solvent.

### (Step of Forming Active Layer)

In the method for manufacturing the photoelectric conversion element, an active layer is formed on the hole transport layer. The active layer can be formed by any suitable conventionally known forming step. The active layer can be produced by a coating method using the composition according to the present disclosure described above.

The active layer can be formed in the same manner as the previously described film according to the present disclosure. The active layer can be formed by a step including a step of applying a composition containing the polymer (p-type semiconductor) according to the present disclosure, an electron-accepting compound (n-type semiconductor), a surfactant, and a solvent onto the hole transport layer to form a coating film, and then a step of drying the coating film.

### (Step of Forming Electron Transport Layer)

The method for manufacturing a photoelectric conversion element may include a step of forming an electron transport layer (electron injection layer) provided so as to be in contact with the active layer.

A method for forming the electron transport layer is not particularly limited. From the viewpoint of further simplifying the step of forming the electron transport layer, it is preferable to form an electron transport layer by any suitable conventionally known vacuum vapor deposition method.

### (Step of Forming Second Electrode)

A method for forming the second electrode is not particularly limited. The second electrode can be formed using the electrode material exemplified above by any suitable conventionally known method such as a coating method, a vacuum vapor deposition method, a sputtering method, an ion-plating method, or a plating method. Through the steps described above, the photoelectric conversion element according to the present disclosure is manufactured.

### (Step of Forming Sealing Body)

In forming a sealing body, any suitable conventionally known sealing material (adhesive) and substrate (sealing substrate) are used. Specifically, a sealing material such as a UV curable resin is applied onto the support substrate so as to surround the periphery of the manufactured photoelectric conversion element, and bonding is performed with the sealing material without a gap, and then, the photoelectric conversion element is sealed in a gap between the support substrate and the sealing substrate using a method suitable for the selected sealing material such as irradiation with UV rays, such that a sealing body of the photoelectric conversion element can be obtained.

### (Application Examples of Photoelectric Conversion Element)

Examples of applications of the photoelectric conversion element according to the present disclosure include a photodetection element and a solar cell. The photoelectric conversion element according to the present disclosure can generate photovoltaic power between the electrodes by being irradiated with light, and can be operated as a solar cell. A solar cell module can also be formed by integrating a plurality of photoelectric conversion elements.

The photoelectric conversion element according to the present disclosure can allow a photocurrent to flow by radiating light from the transparent or translucent electrode in a state in which a voltage (reverse bias voltage) is applied between the electrodes, and can be operated as a photodetection element (photosensor). In addition, the photodetection element can also be used as an image sensor by integrating a plurality of photodetection elements. The photoelectric conversion element according to the present disclosure can be particularly suitably used as a photodetection element.

The photoelectric conversion element according to the present disclosure can be suitably applied, as a photodetection element, to a detection unit included in various electronic devices such as a workstation, a personal computer, a portable information terminal, an access management system, a digital camera, and a medical device.

The photoelectric conversion element according to the present disclosure can be preferably applied to an image detection unit (for example, an image sensor such as an X-ray sensor) for a solid-state imaging device such as an X-ray imaging device or a CMOS image sensor, a detection unit (for example, a near-infrared sensor) of a biometric information authentication device that detects predetermined characteristics of a part of a living body, such as a fingerprint detection unit, a face detection unit, a vein detection unit, or an iris detection unit, and a detection unit of an optical biosensor such as a pulse oximeter, which are included in the electronic devices described above.

### EXAMPLES

Examples will be described below, but the present invention is not limited to these Examples at all. Note that, in the following description, “part(s)” and “%” are all on a mass basis, unless otherwise specified.

### <NMR Measurement>

A proton NMR measurement (hereinafter, referred to as ¹H-NMR measurement) for confirming production of a compound was performed by dissolving the compound in deuterated chloroform and using a nuclear magnetic resonance (NMR) apparatus (manufactured by JEOL Ltd., proton resonance frequency of 400 MHz).

Note that J_{HH} represents a binding constant.

### Synthesis of Compound Represented by Formula (I-R)

### Synthesis of Compound 4

A compound 4, which is a compound represented by Formula (I-R), was synthesized by the following procedure.

### Synthesis of Compound 2

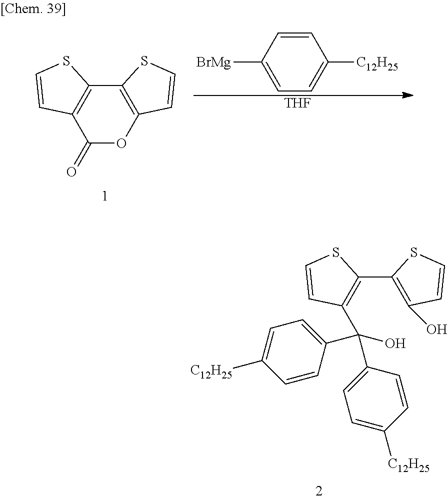

Magnesium (3.22 g, 0.133 mol), THF (93.7 g), and iodine (63.5 mg) were added to a four-necked flask having a volume of 1 L and purged with nitrogen, and stirring was performed. After the purple color of iodine disappeared, 10 mass % of a solution containing 1-bromo-4-dodechylbenzene (40.7 g, 0.125 mmol) and THF (72.9 g) was added dropwise to a four-necked flask, and then, heating was performed to 55° C., thereby generating a Grignard reagent. Thereafter, cooling was performed to 35° C., and then, a solution containing 1-bromo-4-dodechylbenzene and THF was added dropwise to the four-necked flask without exceeding 45° C. Thereafter, stirring was performed at room temperature for 2 hours.

A solution containing the compound 1 (10.4 g, 0.050 mol) and THF (213 g) was added dropwise to the four-necked flask so that the internal temperature did not exceed 35° C. Thereafter, stirring was performed for 1 hour, and the resulting product was allowed to stand overnight.

A 6% NH4Cl aqueous solution was poured into the reaction solution for quenching, and an organic layer was extracted. Toluene was added to the organic layer, washing was performed once with saturated saline, dehydration was performed with magnesium sulfate, magnesium sulfate was removed by filtration, and then, the filtrate was concentrated by a rotary evaporator, thereby obtaining 42.65 g of a crude product of a compound 2 as a yellow liquid.

### Synthesis of Compound 3

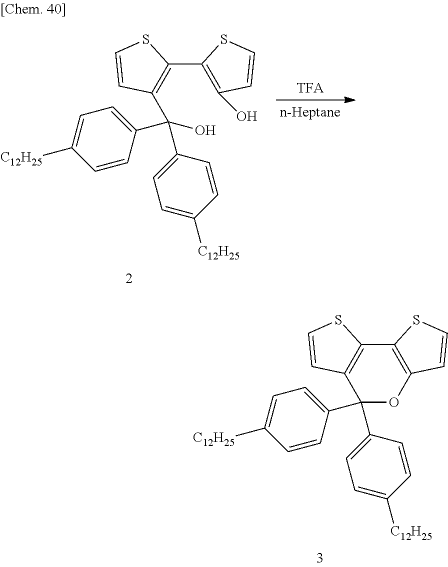

A four-necked flask having a volume of 1 L was charged with the crude product of the compound 2 (42.65 g) and heptane (321 g), and nitrogen purge was performed for 30 minutes. Trifluoroacetic acid (0.986 g, 0.0087 mmol) was charged into the four-necked flask, and then, the temperature was raised to 60° C. After reaching 60° C., stirring was performed for 30 minutes, and then, cooling was performed to room temperature, thereby obtaining a reaction solution.

The reaction solution was washed twice with water, dried with magnesium sulfate, purified with a silica gel column (heptane was used as a developing solvent), and then concentrated by a rotary evaporator to obtain 33 g of a crude product of a compound 3 as a yellow liquid.

### Synthesis of Compound 4

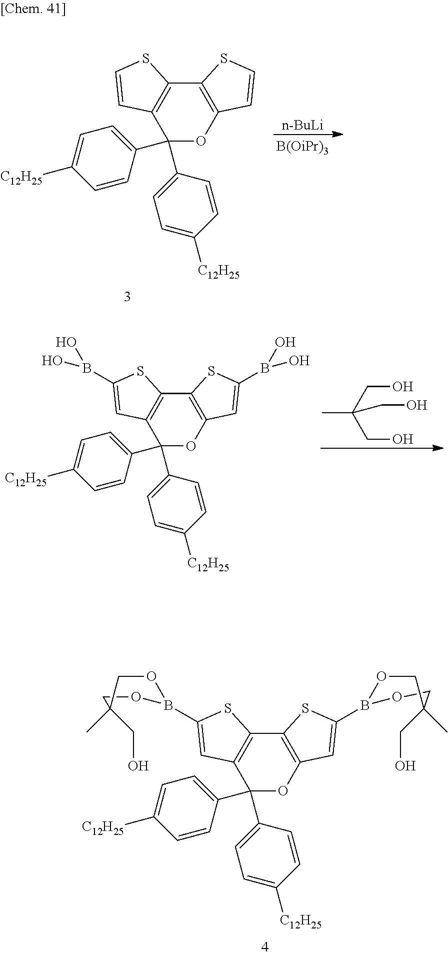

The crude product of the compound 3 (8.56 g), tetramethylethylenediamine (1.16 g, 0.010 mol) and dehydrated THF (106 g) were charged into a four-necked flask having a volume of 300 mL and purged with nitrogen and dissolved, and after confirming that an oxygen concentration was below 0.02%, the flask was immersed in a cooling bath containing dry ice and acetone and cooled until the internal temperature reached −60° C. or lower. A 1.6 mol/L nBuLi hexane solution (16 mL, 2.5 eq, 0.025 mmol) was slowly added dropwise to the four-necked flask so that the internal temperature did not exceed −60° C. After maintaining the temperature for 2 hours, a solution prepared by diluting isopropyl borate (5.27 g, 2.8 eq, 0.028 mmol) with 9.6 g of dehydrated THF was slowly added dropwise to the four-necked flask so that the internal temperature did not exceed −60° C. After keeping the temperature for 1 hour, the flask was removed from the bath and allowed to warm naturally to room temperature. The resulting product was quenched by adding 75.6 g of hydrochloric acid having a concentration of 2% dropwise into the four-necked flask, and liquid separation was performed to remove an aqueous layer. Toluene, magnesium sulfate, and trimethylolethane (3.60 g, 0.030 mmol, 3.0 eq.) were added to an organic layer, stirring was performed at room temperature for 1 hour, and then, the resulting product was allowed to stand overnight. Magnesium sulfate was removed by filtration, the filtrate was concentrated by an evaporator, toluene was added, and then, insoluble matter was removed by filtration.

Concentration was performed again by an evaporator, recrystallization was performed by adding ethanol and hexane to the concentrate, and thereafter, filtration was performed and washing was performed with cooled hexane. The obtained solid was dried at 40° C. under reduced pressure overnight.

5.19 g of the compound 4 was obtained as a white solid.

### Synthesis of Compound 7

A compound 7, which is a compound represented by Formula (I-R), was synthesized by the following procedure.

### Synthesis of Compound 5

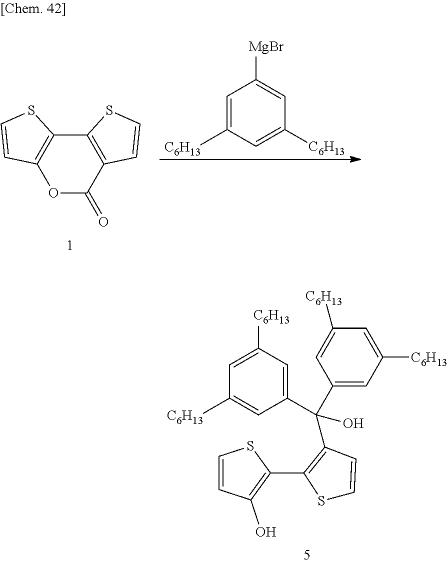

Magnesium (3.28 g, 135 mmol), a small amount (5 grains) of iodine, and THF (110 mL) were charged into a four-necked flask having a volume of 1 L and purged with nitrogen, and the internal temperature was raised to 45° C. in an oil bath. A solution obtained by dissolving 3,5-dihexyl-1-bromobenzene in THF (85 mL) was added dropwise to a four-necked flask so that the internal temperature was maintained at about 45° C., thereby preparing a Grignard reagent. The Grignard reagent solution was cooled to room temperature, and a solution obtained by dissolving the compound 1 (10.4 g, 50.0 mmol) in THF (250 mL) was added dropwise thereto. After the dropwise addition, stirring was performed at room temperature for 1 hour, and then, a saturated ammonium chloride aqueous solution and hexane were added and stirred to wash an organic layer. The obtained organic layer was further washed once with saturated saline. Thereafter, drying was performed with anhydrous sodium sulfate, filtration was performed, and the solvent was distilled off under reduced pressure, thereby obtaining 46.1 g of a crude product of a compound 5 as a yellowish brown oil.

### Synthesis of Compound 6

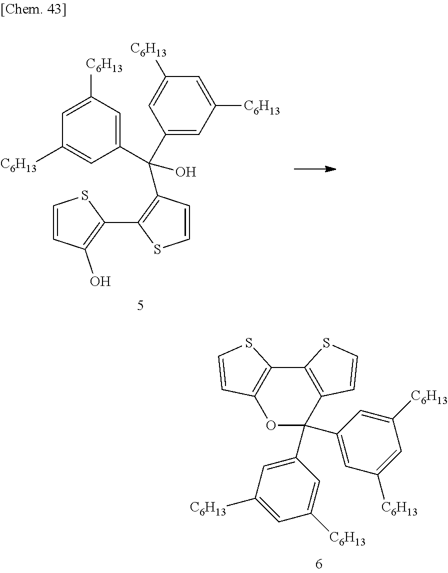

The crude product of the compound 5 (46.1 g, 50.0 mmol), p-toluenesulfonic acid monohydrate (1.62 g, 8.50 mmol), and toluene (250 mL) were charged into a three-necked flask having a volume of 500 mL and purged with nitrogen, and heating and stirring were performed in an oil bath set at 80° C. for 2 hours. After completion of the reaction was confirmed by liquid chromatography, water was added to the reaction solution to stop the reaction, and then, an organic layer was further washed once with water and once with saturated saline. The obtained organic layer was dried with anhydrous magnesium sulfate and then filtered, and the solvent was distilled off under reduced pressure. The obtained crude product was purified by a silica gel column (hexane and ethyl acetate were used as developing solvents) to obtain 33.6 g of a compound 6 as a pale yellow oil.

The ¹H-NMR measurement results of the compound 6 are as follows.

δ (ppm):7.00 (d, J_{HH}=5.0 Hz, 1H), 6.94 (d, J_{HH}=5.5 Hz, 1H), 6.89 (s, 2H), 6.88 (s, 4H), 6.78 (d, J_{HH}=5.5 Hz, 1H), 6.45 (d, J_{HH}=5.0 Hz, 1H), 2.50 (t, J_{HH}=7.5 Hz, 8H), 1.48-1.54 (m, 8H), 1.24-1.29 (m, 24H), 0.84-0.89 (m, 12H).

### Synthesis of Compound 7

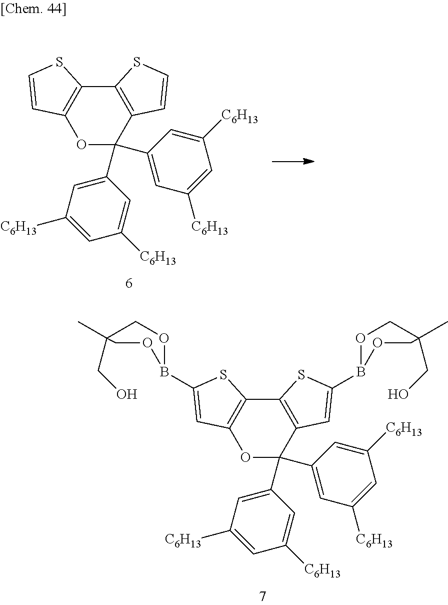

Into a four-necked flask having a volume of 500 mL and purged with nitrogen, the compound 6 (10.3 g, 15.0 mmol), tetraethylethylenediamine (1.74 g, 15 mmol), and dehydrated THF (150 mL) were charged, and stirring was performed for dissolution. Next, cooling was performed to −78° C. in a cooling bath containing dry ice and acetone, a 1.6 mol/L nBuLi hexane solution (24.0 mL) was added dropwise, and then, stirring was performed at −78° C. for 2 hours. A solution obtained by dissolving triisopropoxyborane (7.90 g, 42.0 mmol) in tetrahydrofuran (17 mL) was added dropwise to the four-necked flask while maintaining the temperature at −78° C., stirring was further performed at −78° C. for 1 hour, and then, heating was performed to room temperature. Next, 122 g of hydrochloric acid having a concentration of 2% mp was added to the reaction solution, and liquid separation and washing were performed to extract an organic layer. Anhydrous magnesium sulfate was added to the organic layer, stirring was performed for 5 minutes, 2-hydroxymethylene-2-methyl-1,3-propanediol (5.41 g, 45.0 mmol) was added, and then, stirring was performed for 30 minutes. After filtration, the solvent was distilled off under reduced pressure, toluene was added, and filtration was performed again. The solvent of the obtained solution was distilled off under reduced pressure to obtain 16.05 g of a crude product of a compound 7 as a light yellow green oil (containing toluene, crude yield of 114%, liquid chromatography purity of 99.4%).

The ¹H-NMR measurement results of the compound 7 are as follows.

δ (ppm):7.14 (s, 1H), 6.88 (s, 2H), 6.87 (s, 1H), 6.84 (s, 4H), 3.62-3.95 (br, 12H), 2.48 (t, J_{HH}=7.8 Hz, 8H), 1.51 (br, 8H), 1.24-1.31 (br, 24H), 0.97 (s, 3H), 0.96 (s, 3H), 0.85 (t, J_{HH}=7.2 Hz, 12H).

### Synthesis of Compound 10

A compound 10, which is a compound represented by Formula (I-R), was synthesized by the following procedure.

### Synthesis of Compound 8

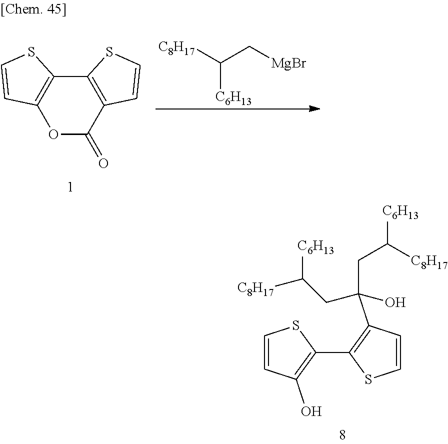

Magnesium (8.21 g, 338 mmol), a small amount of iodine (3 grains), and tetrahydrofuran (270 mL) were charged into a four-necked flask having a volume of 2 L and purged with nitrogen. A solution obtained by dissolving 2-hexyl-1-bromodecane (94.9 g, 31 mmol) in THF (200 mL) was added dropwise thereto so that the internal temperature was maintained at 30° C. or lower, thereby preparing a Grignard reagent. The Grignard reagent solution was cooled to room temperature, and a solution obtained by dissolving the compound 1 (10.3 g, 49.2 mmol) in THF (197 mL) was added dropwise thereto. After the dropwise addition, stirring was performed at room temperature for 1 hour, and then, a saturated ammonium chloride aqueous solution and hexane were added and stirred to wash an organic layer. Next, the obtained organic layer was washed once with saturated saline. Thereafter, drying was performed with anhydrous magnesium sulfate, filtration was performed, and the solvent was distilled off under reduced pressure. The obtained crude product was purified by a silica gel column (hexane and ethyl acetate were used as developing solvents) to obtain 22.4 g of a compound 8 as a pale yellow oil.

The ¹H-NMR measurement results of the compound 8 are as follows.

δ (ppm):7.56 (s, 1H), 7.25 (d, J_{HH}=4.8 Hz, 1H), 7.16 (d, J_{HH}=5.5 Hz, 1H), 6.84 (t, J_{HH}=4.8 Hz, 1H), 6.74 (d, J_{HH}=5.5 Hz, 1H), 2.34 (s, 1H), 1.77 (m, 4H), 1.10-1.31 (m, 50H), 0.84-0.90 (m, 12H)

### Synthesis of Compound 9

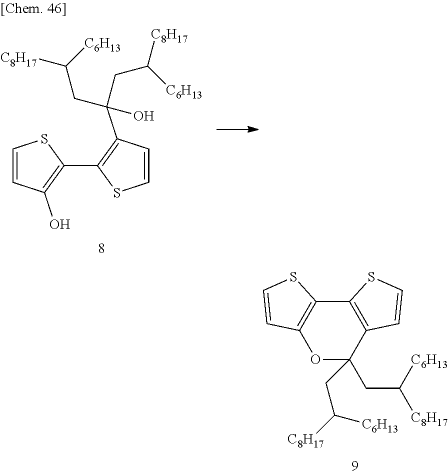

Into a three-necked flask having a volume of 500 mL and purged with nitrogen, the compound 8 (22.4 g, 34.0 mmol) and heptane (230 mL) were charged, and cooling was performed to 0° C. Trifluoroacetic acid (19.4 g, 170 mmol) was added dropwise thereto, and stirring was performed at 0° C. for 5 hours. After water was added to stop the reaction, an organic layer was further washed once with water and once with saturated saline. The obtained organic layer was dried with anhydrous magnesium sulfate and then filtered, and the solvent was distilled off under reduced pressure. The obtained crude product was purified by a silica gel column (hexane and ethyl acetate were used as developing solvents) to obtain 15.3 g of a compound 9 as a pale yellow oil.

The ¹H-NMR measurement results of the compound 9 are as follows.

δ (ppm): 6.97 (d, J_{HH}=5.0 Hz, 1H), 6.92 (d, J_{HH}=5.0 Hz, 1H), 6.65 (d, J_{HH}=5.0 Hz, 1H), 6.57 (d, J_{HH}=5.0 Hz, 1H), 1.73-1.82 (m, 4H), 1.04-1.29 (m, 50H), 0.83-0.90 (m, 12H)

### Synthesis of Compound 10

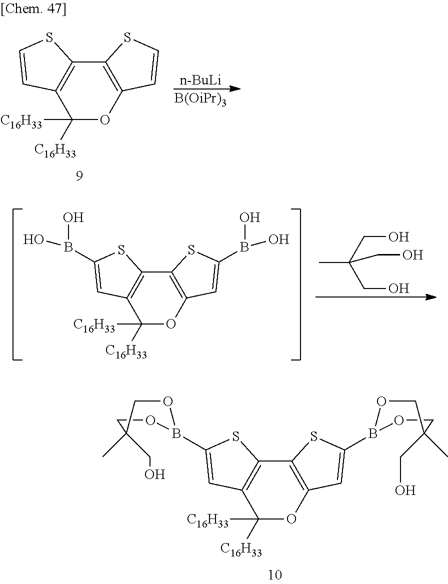

The compound 9 (10.08 g), tetramethylethylenediamine (1.82 g) and dehydrated THF (141 g) were charged into a four-necked flask having a volume of 500 mL and purged with nitrogen and dissolved, and after confirming that an oxygen concentration was below 0.02%, the flask was immersed in a cooling bath containing dry ice and acetone and cooled until the internal temperature reached −60° C. or lower. A 1.6 mol/L nBuLi hexane solution (24.97 mL, 2.5 eq) was slowly added dropwise to the four-necked flask so that the internal temperature did not exceed −60° C. After maintaining the temperature for 2 hours, a solution prepared by diluting isopropyl borate (10.06 ml, 2.8 eq) with dehydrated THF (16 mL) was slowly added dropwise so that the internal temperature did not exceed −60° C. After keeping the temperature for 1 hour, the flask was removed from the cooling bath and allowed to warm naturally to room temperature. The resulting product was quenched by adding 136 g of a hydrochloric acid solution having a concentration of 2% dropwise, and liquid separation was performed to remove an aqueous layer. Toluene, magnesium sulfate, and trimethylolethane (5.65 g, 3.0 eq.) were added to an organic layer, stirring was performed at room temperature for 1 hour, and then, the resulting product was allowed to stand overnight. Magnesium sulfate was removed by filtration, the filtrate was concentrated by an evaporator, toluene was added, and then, trimethylolethane was removed by filtration.

Concentration was performed by an evaporator, and then, recrystallization was performed with heptane. Thereafter, filtration was performed, and washing was performed with cooled hexane. The obtained solid was dried at 40° C. under reduced pressure overnight. 9.1 g of the compound 10 was obtained as a white solid.

### Synthesis of Compound 13

A compound 13, which is a compound represented by Formula (I-R), was synthesized by the following procedure.

### Synthesis of Compound 11

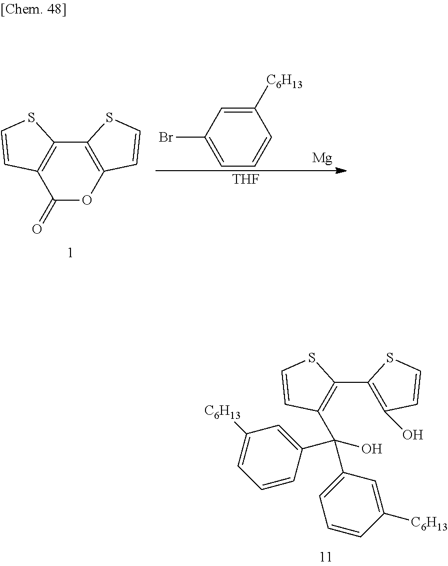

Magnesium (9.79 g), THF (316 mL), and iodine (2 grains) were added to a four-necked flask having a volume of 2 L and purged with nitrogen, and stirring was performed. After the purple color of iodine purple color, a solution of 1-bromo-3-hexyllbenzene (91.6 g) in THF (221 mL) was added dropwise for 30 minutes.

Thereafter, the temperature was raised to 30° C., and stirring was performed for 1 hour.

A solution containing the compound 1 (31.6 g) and THF (649 mL) was added dropwise to the four-necked flask so that the internal temperature did not exceed 35° C. Thereafter, stirring was performed overnight.

A 10% NH₄Cl aqueous solution was poured into the reaction solution for quenching, and an organic layer was extracted. Toluene was added to the organic layer, washing was performed once with water, dehydration was performed with magnesium sulfate, magnesium sulfate was removed by filtration, and then, the filtrate was concentrated by a rotary evaporator. The obtained crude product was purified by a silica gel column (hexane and ethyl acetate were used as developing solvents) to obtain 78.5 g of a compound 11.

### Synthesis of Compound 12

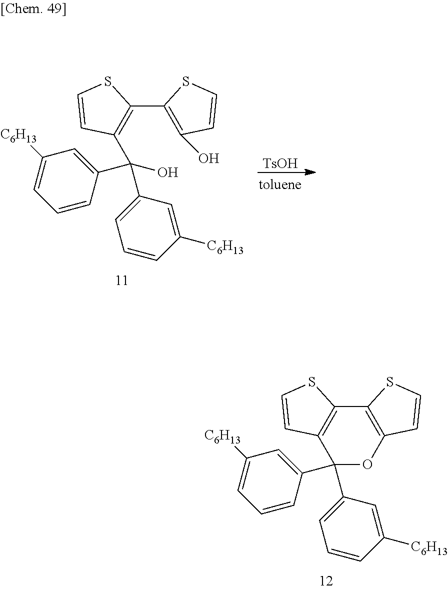

The compound 11 (78.5 g), p-toluenesulfonic acid monohydrate (4.67 g), and toluene (785 mL) were charged into a four-necked flask having a volume of 2 L and purged with nitrogen, heated to 100° C., stirred for 1 hour and a half, and then cooled. After water was added to stop the reaction, an organic layer was further washed once with water. The obtained organic layer was dried with anhydrous magnesium sulfate and then filtered, and the solvent was distilled off under reduced pressure. The obtained crude product was purified by a silica gel column (hexane was used as a developing solvent) to obtain 71.8 g of a compound 12.

### Synthesis of Compound 13

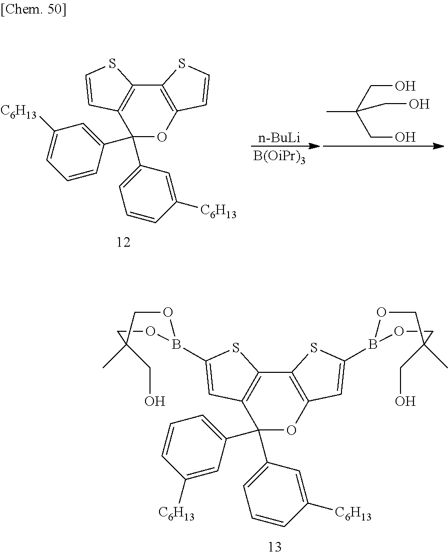

The compound 12 (42.9 g), tetramethylethylenediamine (12.4 mL) and dehydrated THF (1,073 mL) were charged into a four-necked flask having a volume of 2 L and purged with nitrogen and dissolved, and after confirming that an oxygen concentration was below 0.02%, the flask was immersed in a cooling bath containing dry ice and acetone and cooled until the internal temperature reached −60° C. or lower. A 1.6 mol/L nBuLi hexane solution (132 mL, 2.5 eq) was slowly added dropwise so that the internal temperature did not exceed −60° C. After maintaining the temperature for 2 hours, a solution prepared by diluting isopropyl borate (43.88 g, 2.8 eq) with 27 mL of dehydrated THF was slowly added dropwise to the four-necked flask so that the internal temperature did not exceed −60° C. After keeping the temperature for 1 hour, the flask was removed from the bath and allowed to warm naturally to room temperature. Quenching was performed by adding 629 mL of a hydrochloric acid solution having a concentration of 2%, 536 mL of THF was added, and then, water separation was performed to remove an aqueous layer.

Magnesium sulfate and trimethylolethane (30.4 g, 3.0 eq.) were added to an organic layer, stirring was performed at room temperature for 1 hour, and then, the resulting product was allowed to stand overnight. Magnesium sulfate was removed by filtration, the filtrate was concentrated by an evaporator, toluene was added, and then, insoluble matter was removed by filtration.

Concentration was performed by an evaporator, recrystallization was performed by adding hexane, and thereafter, filtration was performed and washing was performed with cooled hexane. The obtained solid was dried at 40° C. under reduced pressure overnight. 53.7 g of the compound 13 was obtained.

### Synthesis of Compound 17

A compound 17, which is a compound represented by Formula (I-R), was synthesized by the following procedure.

### Synthesis of Compound 14

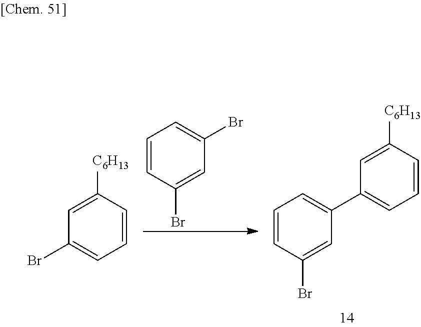

Magnesium (65.2 g, 2.68 mol), THF (275 mL), and iodine (2 grains) were added to a flask purged with nitrogen, and stirring was performed. After the purple color of iodine disappeared, a solution of 1-bromo-3-hexylbenzene (612.9 g, 2.54 mol) in THF (4730 mL) was added dropwise to generate a Grignard reagent.

To another flask, 1,3-dibromobenzene (550 g, 2.33 mol), THF (2,783 mL), and PdCl₂ (dppf)·CH₂Cl₂ (7.62 g, 9.33 mmol) were added, stirring was performed, and cooling was performed to 10° C. The prepared Grignard reagent was added dropwise to the flask so that the internal temperature did not exceed 10° C. to obtain a reaction solution. Thereafter, stirring was performed for 1 hour, water was poured into the reaction solution to stop the reaction, and liquid separation was performed. An organic layer was dehydrated with performed with magnesium sulfate, magnesium sulfate was removed by filtration, and then, the filtrate was concentrated by a rotary evaporator.

Purification was performed by silica gel column chromatography (hexane solvent) to obtain 532.2 g of a compound 14 (1.68 mol, yield 67%).

The ¹H-NMR measurement results of the compound 14 are as follows.

δ (ppm): 7.73 (t, 1H), 7.52-7.50 (dt, 1H), 7.48-7.45 (dq, 1H), 7.38-7.28 (m, 4H), 7.21-7.18 (m, 1H), 2.67 (t, 2H), 1.69-1.58 (m, 2H), 1.40-1.28 (m, 6H), 0.89 (t, 3H)

### Synthesis of Compound 15

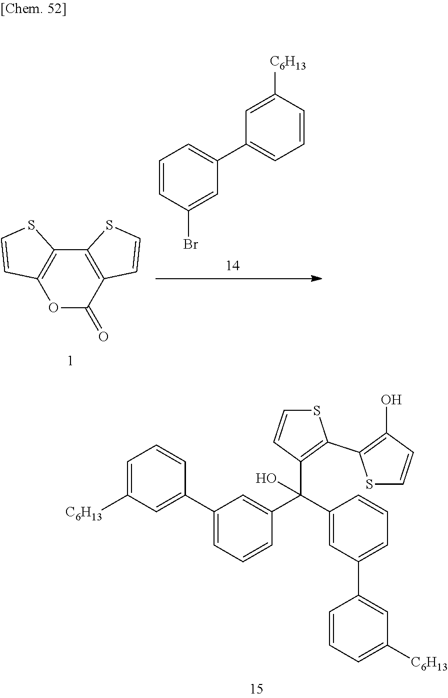

Magnesium (1.61 g, 0.066 mol), THF (47 g), and iodine (32 mg) were added to a four-necked flask having a volume of 1 L and purged with nitrogen, and stirring was performed. After the purple color of iodine disappeared, a solution of the compound 14 (19.8 g, 0.063 mmol) in THF (36 g) was added dropwise to generate a Grignard reagent.

A solution containing the compound 1 (5.21 g, 0.025 mol) synthesized by the method described in WO 2011/136311 A and THF (107 g) was added dropwise to a four-necked flask so that the internal temperature did not exceed 40° C. to obtain a reaction solution. Thereafter, stirring was performed for 1 hour, an ammonium chloride aqueous solution was poured into the reaction solution to stop the reaction, and liquid separation was performed. An organic layer was dehydrated with performed with magnesium sulfate, magnesium sulfate was removed by filtration, and then, the filtrate was concentrated by a rotary evaporator.

Purification was performed by silica gel column chromatography (hexane and ethyl acetate were used as developing solvents) to obtain 14.21 g of a compound 15 (20.7 mmol, yield 83%).

The ¹H-NMR measurement results of the compound 15 are as follows.

δ (ppm): 7.82-7.76 (m, 1H), 7.64 (s, 2H), 7.43 (m, 2H), 7.31 (m, 10H), 7.25 (m, 2H), 7.21 (m, 1H), 7.13 (m, 2H), 6.91 (d, 1H), 6.64 (d, 1H), 6.43 (d, 1H), 3.72-3.64 (m, 1H), 2.63 (t, 4H), 1.61 (m, 4H), 1.22-1.34 (m, 12H), 0.86 (t, 6H)

### Synthesis of Compound 16

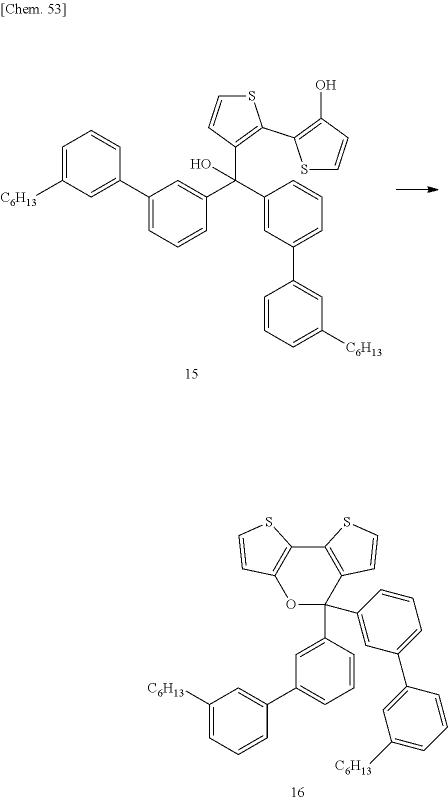

The compound 15 (14.21 g, 0.0208 mmol) and heptane (130 g) were charged into a four-necked flask having a volume of 500 mL, and the inside of the reaction vessel was purged with nitrogen, trifluoroacetic acid (0.409 g, 0.0036 mmol) was charged, the temperature was raised to 60° C., stirring was performed for 30 minutes, and then, cooling was performed to room temperature, thereby obtaining a reaction solution.

The reaction solution was washed twice with water, an organic layer was dehydrated with magnesium sulfate, the resulting solution was passed through a Kiriyama funnel filled with silica gel, and the filtrate was concentrated by a rotary evaporator, thereby obtaining 13.37 g of a compound 16 (yield 96.6%).

The ¹H-NMR measurement results of the compound 16 are as follows.

δ (ppm):7.73 (s, 2H), 7.64 (s, 2H), 7.45-7.43 (m, 7H), 7.33-7.31 (m, 2H), 7.26 (s, 2H), 7.22 (s, 1H), 7.16-7.13 (m, 1H), 6.93 (d, 1H), 6.65 (d, 1H), 6.44 (d, 1H), 2.64 (t, 4H), 1.67-1.58 (m, 4H), 1.34-1.26 (m, 12H), 0.86 (t, 6H)

### Synthesis of Compound 17

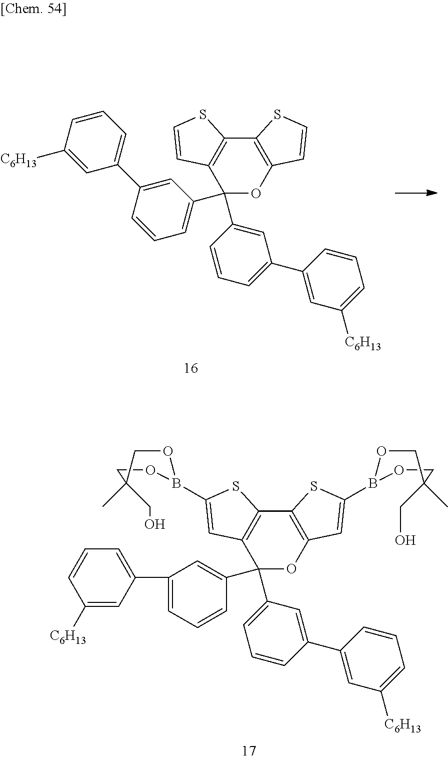

The compound 16 (25.0 g), tetraethylethylenediamine (5.6 mL), and dehydrated tetrahydrofuran (436 mL) were charged into a flask purged with argon, and stirring was performed for dissolution. Next, cooling was performed to −65° C. in a cooling bath containing dry ice and acetone, a 1.6 mol/L nBuLi hexane solution (58.9 mL) was added dropwise to the flask, and stirring was performed at −65° C. for 2 hours. A solution obtained by dissolving triisopropoxyborane (19.74 g) in 40 mL of THF was added dropwise to the flask while maintaining the temperature at −65° C., stirring was further performed at −65° C. for 1 hour, and then, the temperature was raised to room temperature, thereby obtaining a reaction solution. Next, 290 mL of hydrochloric acid having a concentration of 2% was added to the reaction solution, and liquid separation was performed. Magnesium sulfate and trimethylolethane (13.5 g) were added to an organic layer, and stirring was performed at room temperature for 1 hour. Magnesium sulfate was removed by filtration to obtain a filtrate. The solvent was distilled off from the filtrate under reduced pressure, toluene (700 mL) was added to remove the precipitated solid by filtration, hexane was added to remove a supernatant, and then the solvent was removed under reduced pressure, thereby obtaining 37.7 g of a compound 17 (yield 109%).

### Synthesis of Compound 20

A compound 20, which is a compound represented by Formula (I-R), was synthesized by the following procedure.

### Synthesis of Compound 18

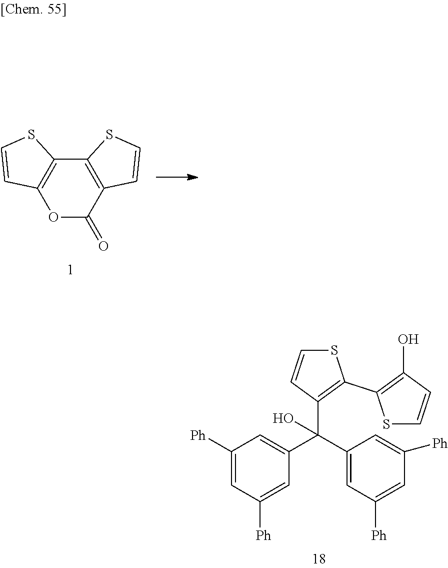 [SMILES: O=c1oc2ccsc2c2sccc12 ; Oc1ccsc1-c1sccc1C(O)(c1cc(-c2ccccc2)cc(-c2ccccc2)c1)c1cc(-c2ccccc2)cc(-c2ccccc2)c1]

Magnesium (12.37 g), THF (360 mL), and iodine (two grains) were added to a flask purged with argon, and stirring was performed. After the purple color of iodine disappeared, a solution containing 1-bromo-3,5-diphenylbenzene (148.48 g) and THF (280 mL) was added dropwise to generate a Grignard reagent.

A solution of the compound 1 (35.88 g) synthesized by the method described in WO 2011/136311 A in THF (820 mL) was added dropwise so that the internal temperature did not exceed 40° C. to obtain a reaction solution. Thereafter, stirring was performed overnight, an ammonium chloride aqueous solution (450 mL) having a concentration of 10% was poured into the reaction solution to stop the reaction, and liquid separation was performed. An organic layer was dehydrated with performed with magnesium sulfate, magnesium sulfate was removed by filtration, and then, the filtrate was concentrated by a rotary evaporator.

Purification was performed by silica gel column chromatography (hexane and ethyl acetate were used as developing solvents) to obtain 128.6 g of a compound 18 (yield 99%).

### Synthesis of Compound 19

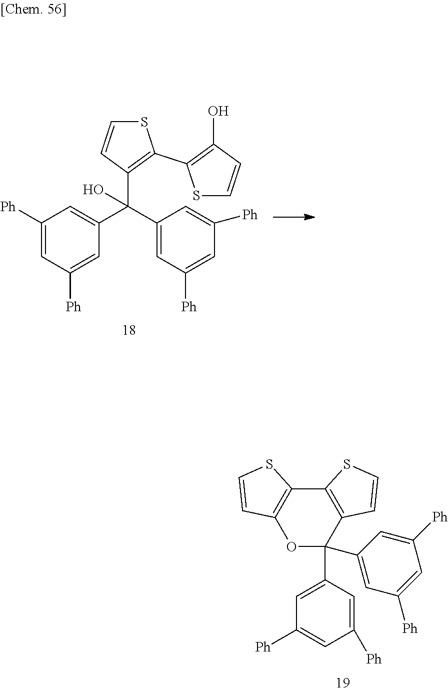 [SMILES: Oc1ccsc1-c1sccc1C(O)(c1cc(-c2ccccc2)cc(-c2ccccc2)c1)c1cc(-c2ccccc2)cc(-c2ccccc2)c1 ; c1ccc(-c2cc(-c3ccccc3)cc(C3(c4cc(-c5ccccc5)cc(-c5ccccc5)c4)Oc4ccsc4-c4sccc43)c2)cc1]

Into a flask purged with argon, the compound 18 (128.6 g) and toluene (1376 mL) were charged, the inside of a reaction vessel was purged with nitrogen, p-toluenesulfonic acid monohydrate (5.39 g) was charged, the temperature was raised to 100° C., stirring was performed for 1.5 hours, and then, cooling was performed to room temperature, thereby obtaining a reaction solution.

After washing the reaction solution with water, an organic layer was dehydrated with performed with magnesium sulfate, magnesium sulfate was removed by filtration, and then, the filtrate was concentrated by a rotary evaporator.

Hexane (150 mL) was added to precipitate a solid, toluene (50 mL) and hexane (50 mL) were added, ice cooling was performed for 60 minutes, and then, the precipitated solid was filtered and dried to obtain 106 g (yield 96%) of a compound 19.

### Synthesis of Compound 20

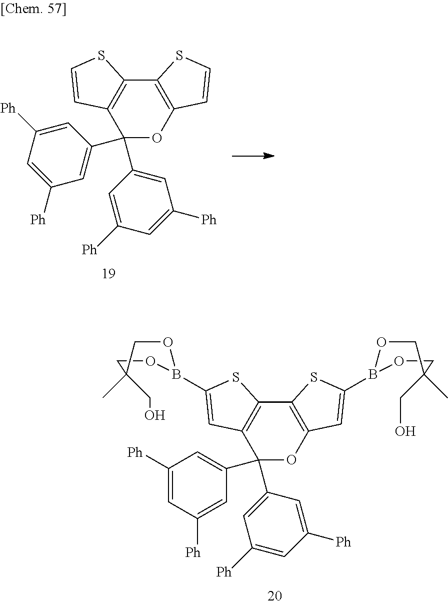

Into a flask purged with argon, the compound 19 (28.38 g), tetraethylethylenediamine (6.5 mL), and 568 mL of dehydrated THF were charged, and stirring was performed for dissolution. Next, cooling was performed to −65° C. in a cooling bath containing dry ice and acetone, a 1.6 mol/L nBuLi hexane solution (69.9 mL) was added dropwise, and then, stirring was performed at −65° C. for 1 hour. A solution obtained by dissolving triisopropoxyborane (22.96 g) in 11.4 mL of THF was added dropwise while maintaining the temperature at −65° C., stirring was further performed at −65° C. for 1 hour, and then, the temperature was raised to room temperature. Next, 329 mL of hydrochloric acid having a concentration of 10% was added to the reaction solution, and liquid separation was performed. Magnesium sulfate and trimethylolethane (15.72 g) were added to an organic layer, and stirring was performed at room temperature for 1 hour. Magnesium sulfate was removed by filtration. The solvent was distilled off from the filtrate under reduced pressure, chloroform (480 mL) was added, cold storage was performed overnight to remove the precipitated solid, and then, the solvent was distilled off from the filtrate under reduced pressure, thereby obtaining a crude product. The obtained crude product was recrystallized with ethanol and hexane to obtain 36.18 g of a compound 20 (yield 91.5%).

### Synthesis of Compound 22

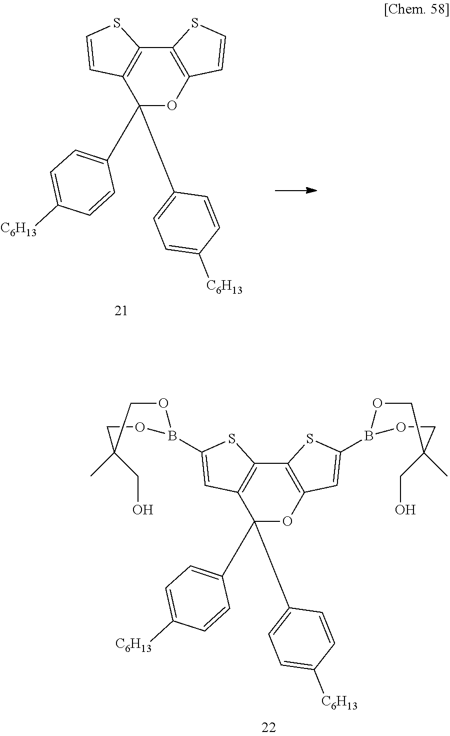

The compound 21 (20.27 g) synthesized by the method described in the document (Dyes and Pigments, 2015,112,145.), tetraethylethylenediamine (5.87 mL), and dehydrated THF (506 mL) were charged into a flask purged with argon, and stirring was performed for dissolution. Next, cooling was performed to −65° C. in a cooling bath containing dry ice and acetone, a 1.6 mol/L nBuLi hexane solution (62.7 mL) was added dropwise, and then, stirring was performed at −65° C. for 1 hour. A solution obtained by dissolving triisopropoxyborane (20.73 g) in THF (28.4 mL) was added dropwise while maintaining the temperature at −65° C., stirring was further performed at −65° C. for 1 hour, and then, the temperature was raised to room temperature, thereby obtaining a reaction solution. Next, 296 mL of hydrochloric acid having a concentration of 10% was added to the reaction solution, and liquid separation was performed. Magnesium sulfate and trimethylolethane (120.15 g) were added to an organic layer, and stirring was performed at room temperature for 1 hour. Magnesium sulfate was removed by filtration. The filtrate was distilled off under reduced pressure, hexane (480 mL) was added, cooling was performed with ice water, and the precipitated solid was collected by filtration.

The obtained solid was dissolved in toluene (480 mL), and insoluble components were removed by filtration. The solvent was distilled off from the filtrate under reduced pressure to obtain a crude product. The obtained crude product was recrystallized with ethanol and hexane to obtain 26.94 g of a compound 22 (yield 88.8%).

### Synthesis of Compound 23

A compound 23, which is a compound represented by Formula (I-R), was synthesized by the procedure described in the document (JP 6070722 B2).

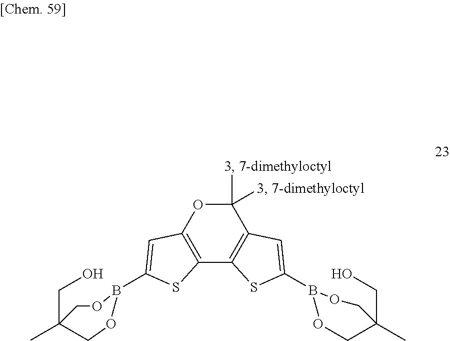

### Synthesis of Compound 24

A compound 24, which is a compound represented by Formula (I-R), was synthesized by the procedure described in the document (JP 6070722 B2).

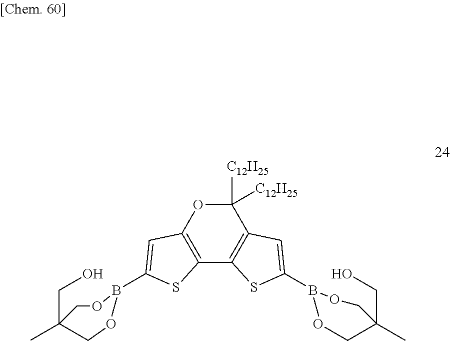

### Example 1

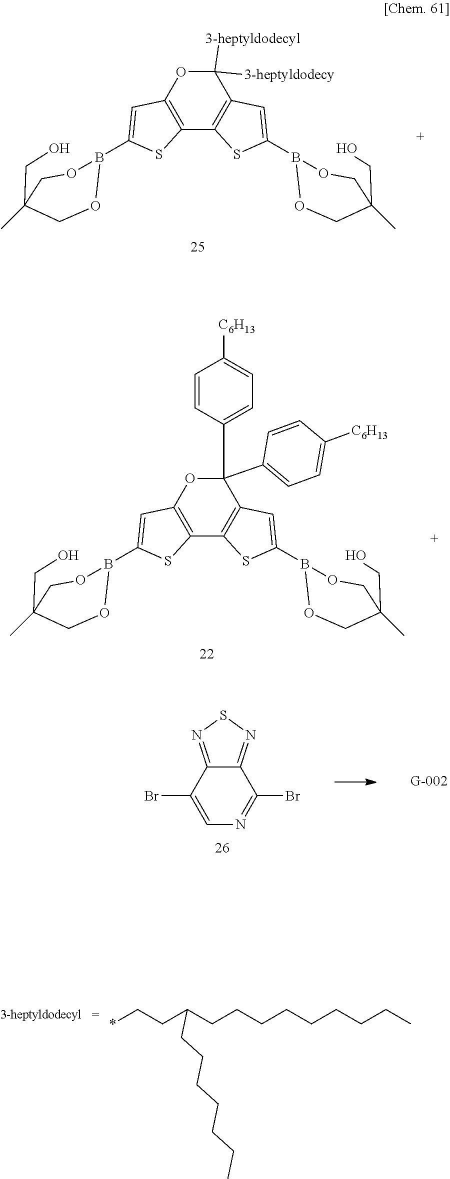

First, a compound 25 and a compound 26 were synthesized by the method described in WO 2014/112656 A.

Next, the compound 26 (1.2 mmol), the compound 22 (0.588 mmol), the compound 25 (0.588 mmol), water (35.7 g), a potassium phosphate aqueous solution (4.3 mL) having a concentration of 40 mass %, THF (28 mL), tetralin (12 mL), and bis(tri-tert-butylphosphine)palladium(0) (0.01 mmol) were added as raw materials to a glass reaction vessel equipped with a cooling device at room temperature, and stirring was performed at 65° C. for 1 hour. A mixed solution of phenylboric acid (1.2 mmol) and a potassium phosphate aqueous solution (6.3 mL) having a concentration of 40 mass % was added to a reaction vessel as a raw material, and stirring was performed at 65° C. for 1 hour. The resulting organic layer was washed with a sodium diethyldithiocarbamate aqueous solution, acetic acid water, and water, the washed organic layer was added to methanol, and the precipitated solid was collected as a crude polymer by filtration.

The obtained crude polymer was dissolved in tetralin, allowed to pass through 5B (JIS P 3801: Type 5B) filter paper, and then added again to methanol to recover the precipitated solid by filtration, thereby obtaining a polymer G-002.

### Comparative Example 1

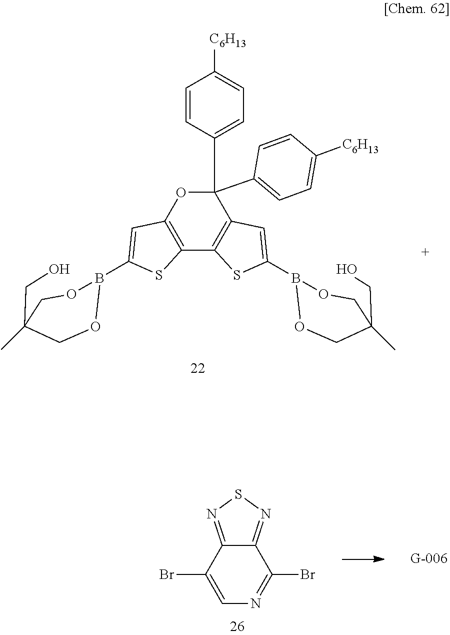

A polymer G-006 was synthesized in the same manner as that of the polymer G-002, except that the added raw materials were the compound 26 (1.6 mmol), the compound 22 (1.488 mmol), water (47.6 g), a potassium phosphate aqueous solution (5.8 mL) having a concentration of 40 mass %, THF (37.3 mL), tetralin (16 mL), and bis(tri-tert-butylphosphine)palladium(0) (0.02 mmol), and a mixed solution of phenylboric acid (1.6 mmol) and a potassium phosphate aqueous solution having a concentration of 40 mass % (8.4 mL).

### Comparative Example 2

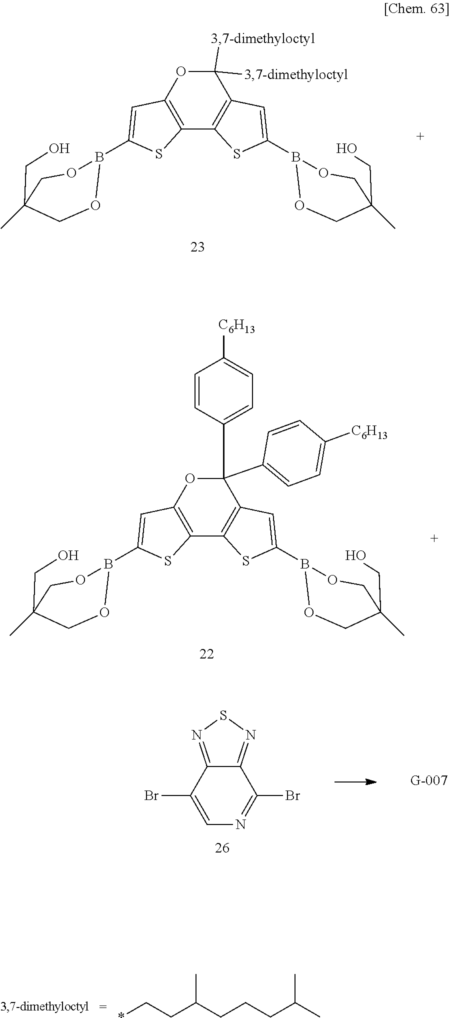

A polymer G-007 was synthesized in the same manner as that of the polymer G-002, except that the added raw materials were the compound 26 (1.6 mmol), the compound 22 (0.744 mmol), the compound 23 (0.744 mmol), water (41.6 g), a potassium phosphate aqueous solution (5.0 mL) having a concentration of 40 mass %, THF (37.3 mL), tetralin (16 mL), bis(tri-tert-butylphosphine)palladium(0) (0.02 mmol), phenylboric acid (1.6 mmol), and a potassium phosphate aqueous solution having a concentration of 40 mass % (8.4 mL).

### Comparative Example 3

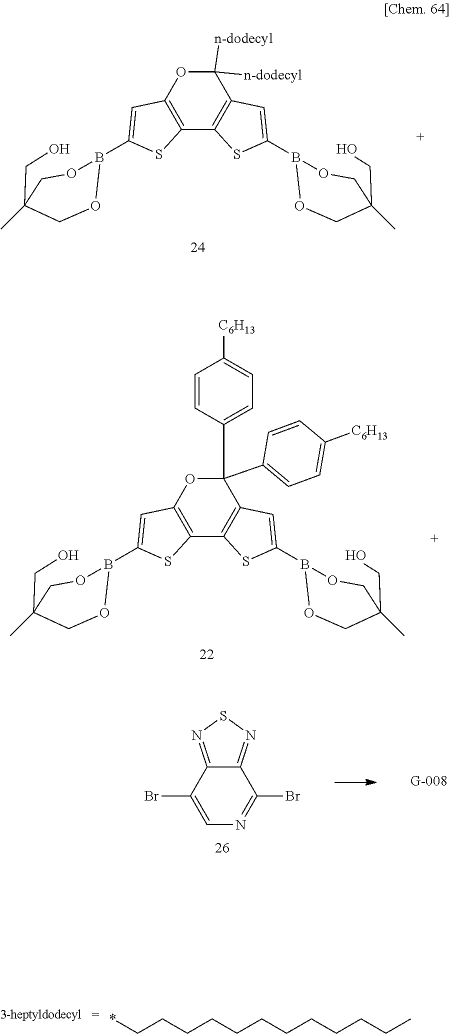

A polymer G-008 was synthesized in the same manner as that of the polymer G-002, except that the added raw materials were the compound 26 (1.4 mmol), the compound 22 (0.6545 mmol), the compound 24 (0.6545 mmol), water (41.6 g), a potassium phosphate aqueous solution (5.0 mL) having a concentration of 40 mass %, THF (32.7 mL), tetralin (16 mL), and bis(tri-1ert-butylphosphine)palladium(0) (0.01 mmol), and a mixed solution of phenylboric acid (1.4 mmol) and a potassium phosphate aqueous solution having a concentration of 40 mass % (7.4 mL).

### Example 2

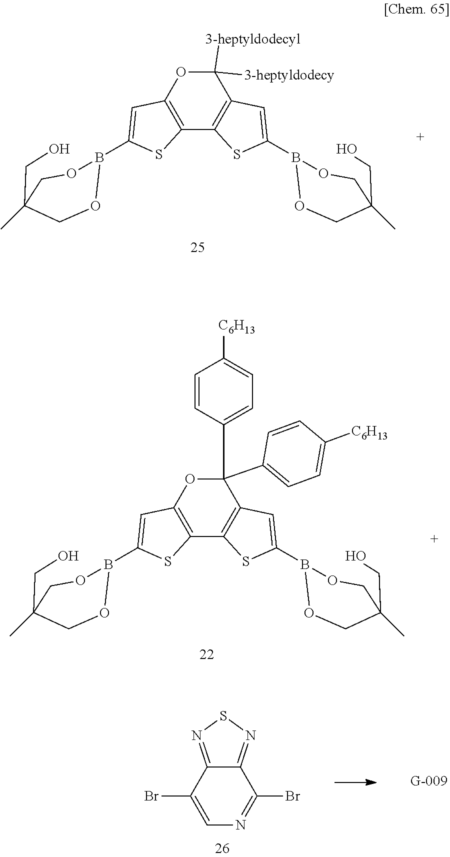

A polymer G-009 was synthesized in the same manner as that of the polymer G-002, except that the added raw materials were the compound 26 (1.5 mmol), the compound 22 (1.2555 mmol), the compound 25 (0.1395 mmol), water (44.6 g), a potassium phosphate aqueous solution (5.4 mL) having a concentration of 40 mass %, THF (35 mL), tetralin (15 mL), and bis(tri-1ert-butylphosphine)palladium(0) (0.02 mmol), and a mixed solution of phenylboric acid (1.5 mmol) and a potassium phosphate aqueous solution having a concentration of 40 mass % (7.9 mL).

### Example 3

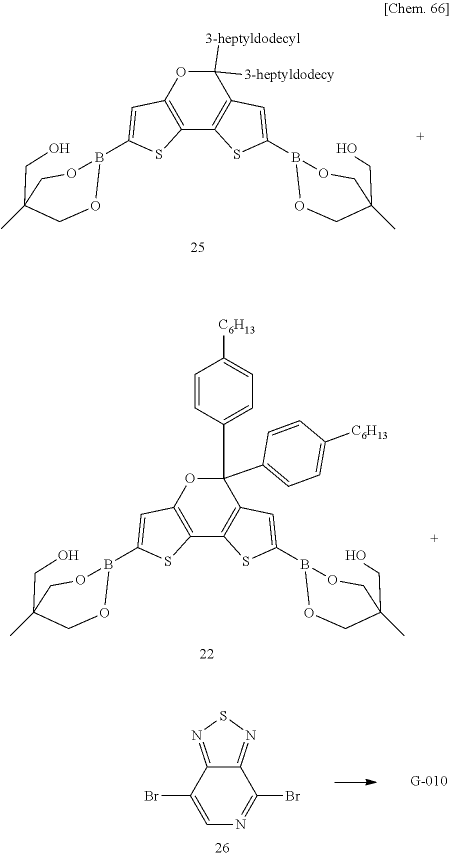

A polymer G-010 was synthesized in the same manner as that of the polymer G-002, except that the added raw materials were the compound 26 (1.5 mmol), the compound 22 (1.116 mmol), the compound 25 (0.279 mmol), water (44.6 g), a potassium phosphate aqueous solution (5.4 mL) having a concentration of 40 mass %, THF (35 mL), tetralin (15 mL), and bis(tri-1ert-butylphosphine)palladium(0) (0.02 mmol), and a mixed solution of phenylboric acid (1.5 mmol) and a potassium phosphate aqueous solution having a concentration of 40 mass % (7.9 mL).

### Example 4

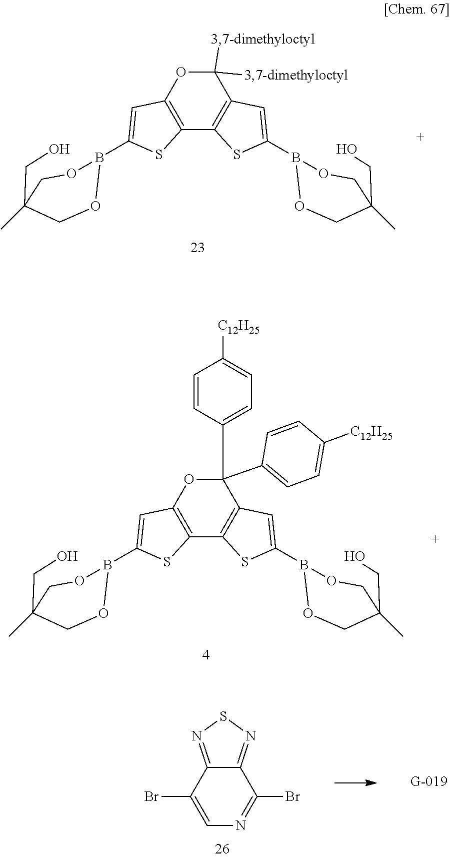

A polymer G-019 was synthesized in the same manner as that of the polymer G-002, except that the added raw materials were the compound 26 (2.1 mmol), the compound 4 (0.987 mmol), the compound 23 (0.987 mmol), water (62.4 g), a potassium phosphate aqueous solution (7.6 mL) having a concentration of 40 mass %, THF (49 mL), tetralin (21 mL), and bis(tri-1ert-butylphosphine)palladium(0) (0.02 mmol), and a mixed solution of phenylboric acid (2.1 mmol) and a potassium phosphate aqueous solution having a concentration of 40 mass % (11.0 mL).

### Example 5

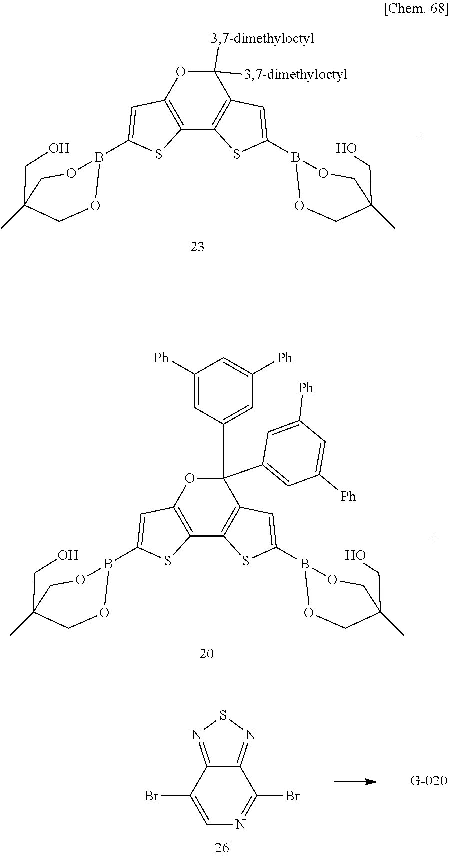

A polymer G-020 was synthesized in the same manner as that of the polymer G-002, except that the added raw materials were the compound 26 (2.3 mmol), the compound 20 (1.081 mmol), the compound 23 (1.081 mmol), water (68.4 g), a potassium phosphate aqueous solution (8.3 mL) having a concentration of 40 mass %, THF (53.7 mL), tetralin (23 mL), and bis(tri-1ert-butylphosphine)palladium(0) (0.02 mmol), and a mixed solution of phenylboric acid (2.3 mmol) and a potassium phosphate aqueous solution having a concentration of 40 mass % (12.1 mL).

### Example 6

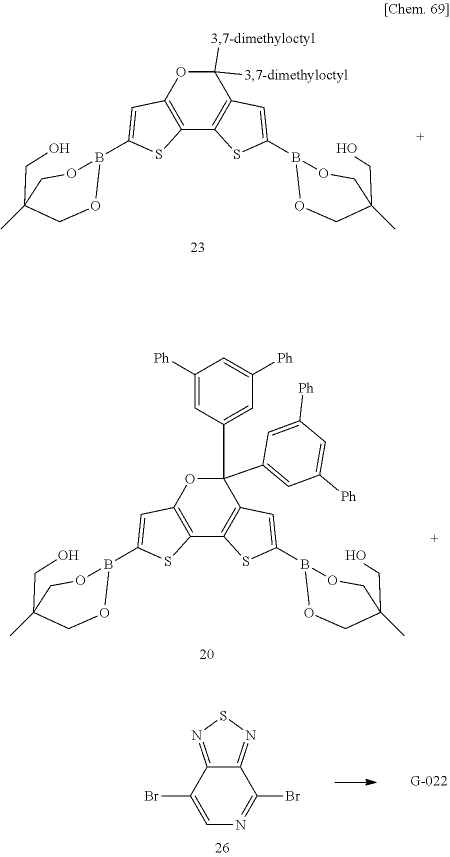

A polymer G-022 was synthesized in the same manner as that of the polymer G-002, except that the added raw materials were the compound 26 (2.3 mmol), the compound 20 (1.150 mmol), the compound 23 (1.150 mmol), water (68.4 g), a potassium phosphate aqueous solution (8.3 mL) having a concentration of 40 mass %, THF (53.7 mL), tetralin (23 mL), and bis(tri-1ert-butylphosphine)palladium(0) (0.02 mmol), and a mixed solution of phenylboric acid (2.3 mmol) and a potassium phosphate aqueous solution having a concentration of 40 mass % (12.1 mL).

### Comparative Example 4

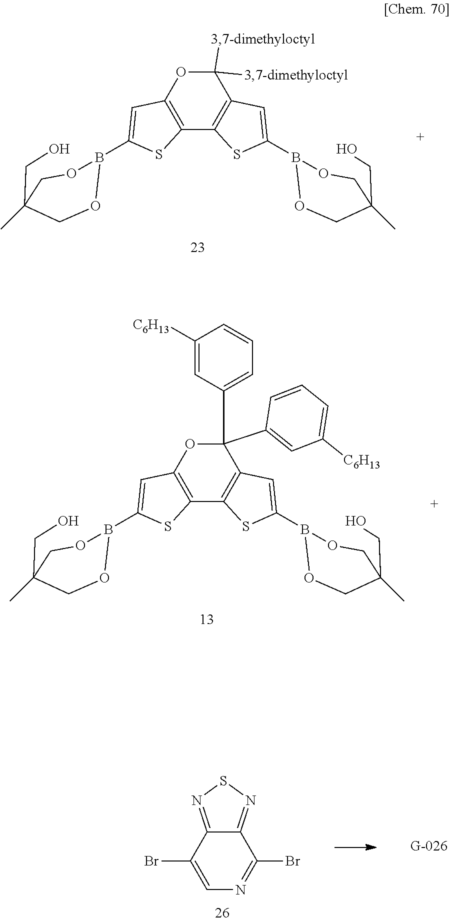

A polymer G-026 was synthesized in the same manner as that of the polymer G-002, except that the added raw materials were the compound 26 (2.6 mmol), the compound 13 (1.235 mmol), the compound 23 (1.235 mmol), water (77.3 g), a potassium phosphate aqueous solution (9.4 mL) having a concentration of 40 mass %, THF (60.7 mL), tetralin (26 mL), and bis(tri-1ert-butylphosphine)palladium(0) (0.03 mmol), and a mixed solution of phenylboric acid (2.6 mmol) and a potassium phosphate aqueous solution having a concentration of 40 mass % (13.7 mL).

### Example 7

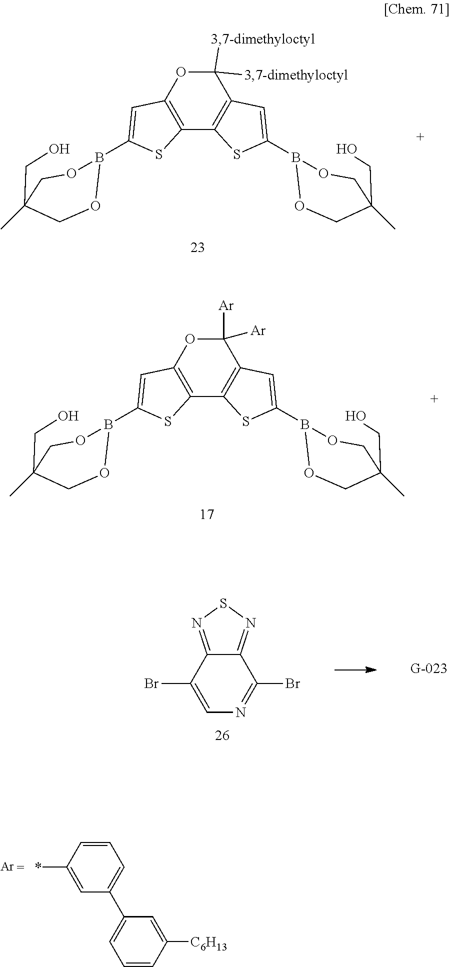

A polymer G-023 was synthesized in the same manner as that of the polymer G-002, except that the added raw materials were the compound 26 (2.1 mmol), the compound 17 (1.029 mmol), the compound 23 (1.029 mmol), water (62.5 g), a potassium phosphate aqueous solution (7.6 mL) having a concentration of 40 mass %, THF (49 mL), tetralin (21 mL), and bis(tri-1ert-butylphosphine)palladium(0) (0.02 mmol), and a mixed solution of phenylboric acid (2.1 mmol) and a potassium phosphate aqueous solution having a concentration of 40 mass % (11.0 mL).

### Example 8

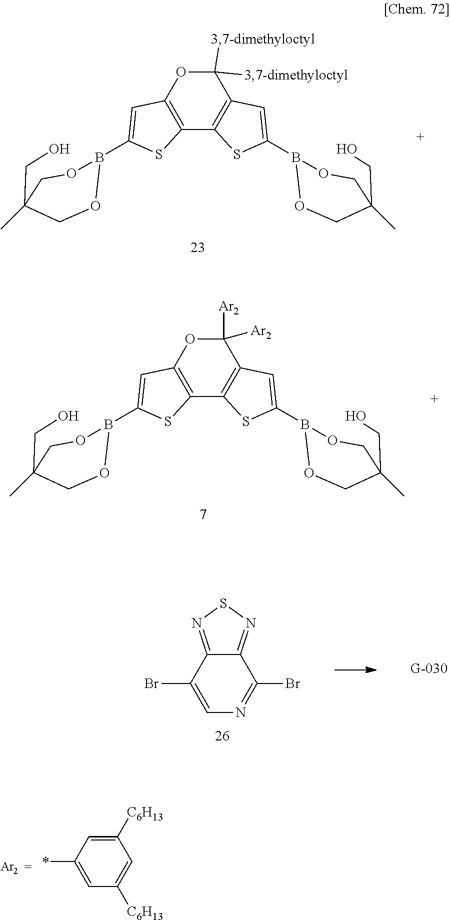

A polymer G-030 was synthesized in the same manner as that of the polymer G-002, except that the added raw materials were the compound 26 (2.3 mmol), the compound 7 (1.127 mmol), the compound 23 (1.127 mmol), water (68.4 g), a potassium phosphate aqueous solution (8.3 mL) having a concentration of 40 mass %, THF (53.7 mL), tetralin (23 mL), and bis(tri-1ert-butylphosphine)palladium(0) (0.02 mmol), and a mixed solution of phenylboric acid (2.3 mmol) and a potassium phosphate aqueous solution having a concentration of 40 mass % (12.1 mL).

### Example 9

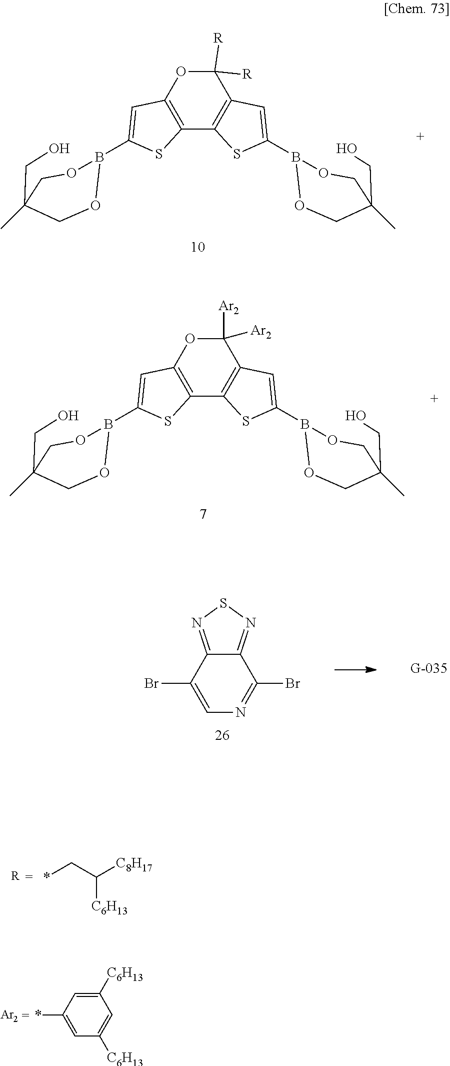

A polymer G-035 was synthesized in the same manner as that of the polymer G-002, except that the added raw materials were the compound 26 (1.484 mmol), the compound 7 (0.71246 mmol), the compound 10 (0.71246 mmol), water (44.1 g), a potassium phosphate aqueous solution (5.3 mL) having a concentration of 40 mass %, THF (34.6 mL), tetralin (14.8 mL), and bis(tri-1ert-butylphosphine)palladium(0) (0.01 mmol), and a mixed solution of phenylboric acid (1.484 mmol) and a potassium phosphate aqueous solution having a concentration of 40 mass % (7.8 mL).

### Comparative Example 5

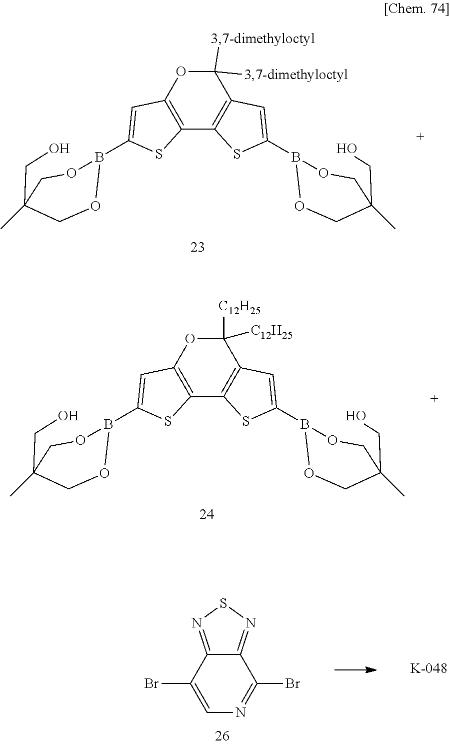

A polymer K-048 was synthesized in the same manner as that of the polymer G-002, the added raw materials were the compound 26 (26.5 mmol), the compound 23 (13.05 mmol), the compound 24 (13.05 mmol), water (794 g), a potassium phosphate aqueous solution (137 g) having a concentration of 40 mass %, 1-methylcyclohexanol (410 g), and tetralin (424 g), and a mixed solution of phenylboric acid (26.5 mmol) and a potassium phosphate aqueous solution having a concentration of 40 mass % (129 mL).

### Structure of Polymer Obtained in Each Example

The specific structure of the polymer obtained in each example is shown below.

TABLE 3-1

| Poly- | |
|---|---|
| mer | Structural formula |
| G- | Same as G-002 in Table 2 |
| 002 | |
| G- 006 | 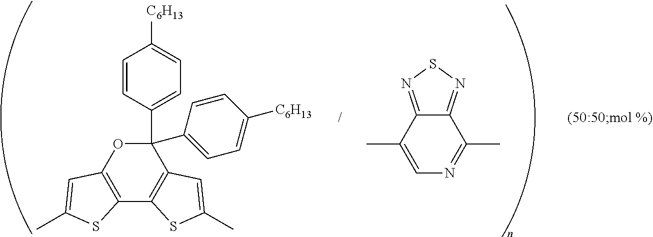 |
| G- 007 | 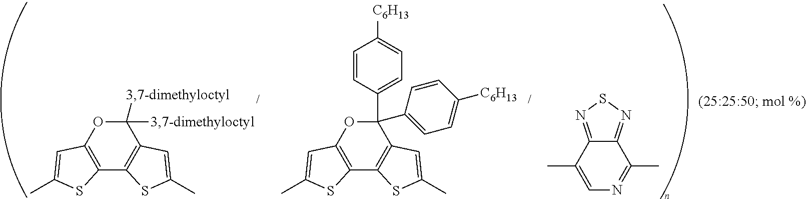 |
| G- 008 | 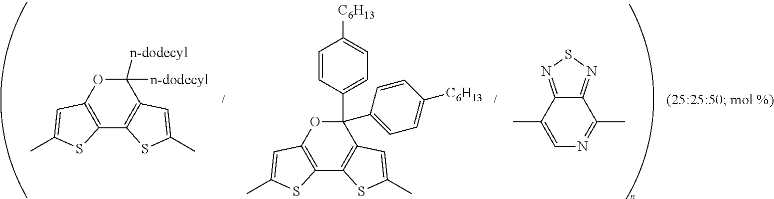 |
| G- | Same as G-009 in Table 2 |
| 009 | |
| G- | Same as G-010 in Table 2 |
| 010 | |
| G- | Same as G-019 in Table 2 |
| 019 | |
| G- | Same as G-020 in Table 2 |
| 020 | |
| G- | Same as G-022 in Table 2 |
| 022 | |
| G- | Same as G-023 in Table 2 |
| 023 | |

TABLE 3-2

| Poly- | |
|---|---|
| mer | Structural formula |
| G- 026 | 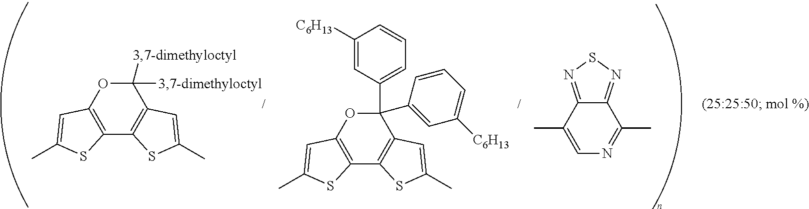 |
| G- | Same as G-030 in Table 2 |
| 030 | |
| G- | Same as G-035 in Table 2 |
| 035 | |
| K- 048 | 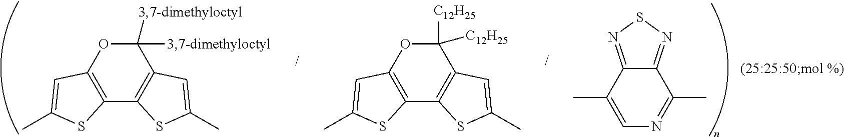 |

### <Preparation of Ink and Photoelectric Conversion Element>

Using the polymer obtained in each example, an ink and a photoelectric conversion element were prepared by the following procedure.

### (Preparation of Ink)

1,2,4-Trimethylbenzene and butyl benzoate were mixed in amounts of 97 mass % and 3 mass %, respectively, to obtain a mixture (a).

The polymer obtained in each example as a p-type semiconductor and an n-type semiconductor were mixed with the mixture (a) to obtain a mixture (b). As the n-type semiconductor material (electron-accepting compound), trade name “Guard Surf NC-1010” (manufactured by HARVES Co., Ltd.) was used. The mixing amount of the p-type semiconductor was 1.5 mass % with respect to the entire mixture (b). The mixing amount of the n-type semiconductor was 1.5 mass % with respect to the total mass of the mixture (b). The obtained mixture (b) was stirred at 60° C. for 8 hours, and then filtered through a filter to obtain an ink.

### (Manufacture of Photoelectric Conversion Element)

### —Preparation of Substrate—

A glass substrate having a thickness of 45 nm on which an ITO film as a first electrode was formed by a sputtering method (hereinafter, simply referred to as a glass substrate) was prepared. Next, the glass substrate was subjected to a surface treatment by an ozone ultraviolet (UV) treatment.

### —Formation of Active Layer—

The ink was applied onto the ITO film of the glass substrate by a spin coating method to form a coating film. The glass substrate on which the coating film was formed was placed on a hot plate, and the coating film was dried in the air under a condition of 70° C. for 2 minutes. Subsequently, the glass substrate on which the coating film was formed was placed on a hot plate, and the coating film was further dried in a nitrogen gas atmosphere under a condition of 100° C. for 10 minutes. As a result, an active layer was formed on the ITO film. A thickness of the formed active layer was about 250 nm.

### —Formation of Electron Transport Layer—

45 mass % of an isopropanol dispersion (manufactured by TAYCA CORPORATION, HTD-711Z) of zinc oxide nanoparticles (particle diameter of 20 to 30 nm) was diluted 10 times the parts by mass of the isopropanol dispersion with 3-pentanol, thereby preparing a coating liquid. The coating liquid was applied onto the active layer formed by a spin coating method at a thickness of 40 nm, and the active layer was subjected to a heat treatment at 70° C. for 5 minutes. As a result, an electron transport layer was formed on the active layer.

### —Formation of Electrode—

Thereafter, an Ag film as an electrode (second electrode) was formed on the electron transport layer at a thickness of about 80 nm using a resistance heating vapor deposition device.

### —Formation of Sealing Layer—

Next, an ultraviolet (UV)-curable sealing agent was applied to the periphery of the glass substrate on which the electrode (second electrode) was formed, a glass plate was bonded to an upper portion of the electrode, and then, the sealing agent was cured and sealed by irradiation with UV rays, thereby obtaining a photoelectric conversion element. The shape of the obtained photoelectric conversion element was a square of 2 mm×2 mm.

By the above manufacturing method, a photoelectric conversion element in which a glass substrate, a first electrode, an active layer, an electron transport layer, and a second electrode were provided in this order was obtained.

### <Evaluation>

### (Measurement of Dark Current)

J-V measurement was performed on the photoelectric conversion element in a dark place to determine dark current (Jd) at −5 V. For the J-V measurement, a source meter (model 2450, manufactured by Keithley Instruments Inc.) was used. Hereinafter, the value of the measured dark current is also referred to as “measured dark current”.

The measurement results are shown in “Measured dark current” in Table 4.

### (Prediction of Dark Current)

Multiple regression analysis was performed with “measured dark current” as a target variable and “1,000/specific side chain average formula amount” and “absorption edge intensity of polymer” as explanatory variables. Multiple regression analysis was performed using a data analysis tool of spreadsheet software Excel manufactured by Microsoft Corporation. The multiple regression analysis was performed using a total of 14 data. A predicted value of dark current was calculated using coefficients obtained by the multiple regression analysis. Hereinafter, the value of the dark current predicted by the multiple regression analysis is also referred to as “predicted dark current”.

The prediction results are shown in “Predicted dark current” in Table 4.

Note that the “1,000/specific side chain average formula amount” and the “absorption edge intensity of polymer” used for the explanatory variables are as follows.

In addition, “Energy level of HOMO” and “1,240/absorption edge wavelength” shown in Table 4 are as follows.
The energy level of HOMO means the energy order of the highest occupied molecular orbital (HOMO) of the polymer. The energy level of HOMO was calculated as follows.

The polymer obtained in each example was added to a mixed solvent of 1,2,4-trimethylbenzene and 1,2-dimethoxybenzene (1,2,4-trimethylbenzene/1,2-dimethoxybenzene=97/3 (mass ratio)) so as to have a concentration of 1.5 wt %. Heating and stirring were performed in a nitrogen atmosphere at 65° C. for 4 hours to prepare a polymer solution. The polymer solution was filtered through an RC filter (pore diameter 0.45 μm, Minisart RC, hydrophilic, 15 mm, manufacturer: Sartorius), and the filtrate was used as a coating liquid. The coating liquid was placed on a glass substrate whose surface was washed with UV-ozone, and a film was formed by spin coating at a rotation speed at which a film thickness of 100 nm was obtained. The glass substrate on which the coating film was formed was placed on a hot plate and dried in the air under a condition of 70° C. for 5 minutes.

Subsequently, annealing was performed at 100° C. for 10 minutes under nitrogen to obtain a thin film for HOMO energy level measurement. The HOMO energy level was measured using AC-2 manufactured by RIKEN KEIKI CO., LTD.
The 1,000/specific side chain average formula amount is a value calculated by the following formula.
Formula: 1,000/specific side chain average formula amount of polymer
The 1,240/absorption edge wavelength is a value calculated by the following formula.
Formula: 1,240/absorption edge wavelength

The measurement procedure of the absorption edge wavelength will be described below (Measurement of Absorption Edge Intensity of Polymer).
The absorption edge intensity of the polymer is the absorption edge intensity of the polymer measured by the procedure of (Measurement of Absorption Edge Intensity of Polymer) described below.

### (Measurement of Absorption Edge Intensity of Polymer)

The polymer obtained in each example was added to a mixed solvent of 1,2,4-trimethylbenzene and 1,2-dimethoxybenzene (1,2,4-trimethylbenzene/1,2-dimethoxybenzene=97/3 (mass ratio)) so as to have a concentration of 1.5 wt %. Heating and stirring were performed in a nitrogen atmosphere at 65° C. for 4 hours to prepare a polymer solution. The polymer solution was filtered through an RC filter (pore diameter 0.45 μm, Minisart RC, hydrophilic, 15 mm, manufacturer: Sartorius), and the filtrate was used as a coating liquid. The coating liquid was placed on a glass substrate whose surface was washed with UV-ozone, and a film was formed by spin coating at a rotation speed at which a film thickness of 100 nm was obtained. The coating film obtained by spin coating was placed on a hot plate and dried in the air at 70° C. for 5 minutes. Subsequently, annealing was performed at 100° C. for 10 minutes under nitrogen to obtain a thin film for UV-Vis spectrum measurement.

Using the thin film, the absorption edge intensity of the polymer was measured by the procedure described in “·Measurement of Absorption Edge Intensity of Polymer”. In addition, the wavelength at the intersection point C in FIG. 1 was defined as an absorption edge wavelength.

In the calculation of the absorption edge intensity, normalization was performed at the peak top of the spectrum, and the absorption edge intensity was calculated as a relative value with respect to the peak top.

### (Measurement of Absorption Edge Intensity of Active Layer)

The ink prepared in (Preparation of Ink) was used as a coating liquid. The coating liquid was placed on a glass substrate whose surface was washed with UV-ozone, and a film was formed by spin coating at a rotation speed at which a film thickness of 100 nm was obtained. The coating film obtained by spin coating was placed on a hot plate and dried in the air at 70° C. for 5 minutes. Subsequently, annealing was performed at 100° C. for 10 minutes under nitrogen to obtain a thin film for UV-Vis spectrum measurement.

Using the thin film, the absorption edge intensity of the active layer was measured by the procedure described in “Measurement of Absorption Edge Intensity of Film”.

TABLE 4

| | | 1,240/ | 1,000/ | | Polymer | Specific | Absorption | | | |
|---|---|---|---|---|---|---|---|---|---|---|
| | Energy | absorption | specific side | Absorption | weight average | side chain | edge | Absorption | Measured | Predicted |
| | level of | edge | chain average | edge | molecular | average | intensity | edge | dark | dark |
| | HOMO | wavelength | formula | intensity | weight | formula | of active | wavelength | current | current |
| | (eV) | (nm) | amount | of polymer | (×1,000) | amount | layer | (nm) | (nA/cm²) | (nA/cm²) |
| Example 1 | 5.06 | 1.216 | 4.664 | 0.070 | 47 | 214.4 | 0.16 | 1020 | 8 | 4 |
| Example 2 | 5.01 | 1.240 | 5.818 | 0.076 | 41 | 171.9 | 0.16 | 1000 | 12 | 12 |
| Example 3 | 5.03 | 1.228 | 5.479 | 0.070 | 27 | 182.5 | 0.16 | 1010 | 8 | 7 |
| Example 4 | 5.02 | 1.216 | 5.158 | 0.073 | 64 | 193.9 | 0.16 | 1020 | 12 | 11 |
| Example 5 | 5.06 | 1.181 | 2.698 | 0.078 | 15 | 185.3 | 0.17 | 1050 | 5 | 7 |
| Example 6 | 5.08 | 1.192 | 5.397 | 0.073 | 59 | 185.3 | 0.15 | 1040 | 16 | 19 |
| Example 7 | 5.00 | 1.216 | 5.282 | 0.068 | 21 | 189.3 | 0.15 | 1020 | 8 | 6 |
| Example 8 | 5.00 | 1.204 | 5.172 | 0.066 | 32 | 193.4 | 0.15 | 1030 | 4 | 6 |
| Example 9 | 5.05 | 1.228 | 5.172 | 0.072 | 19 | 193.4 | 0.15 | 1010 | 6 | 7 |
| Comparative | 4.99 | 1.253 | 6.201 | 0.089 | 52 | 161.3 | 0.18 | 990 | 25 | 25 |
| Example 1 | | | | | | | | | | |
| Comparative | 5.02 | 1.216 | 6.610 | 0.086 | 54 | 151.3 | 0.18 | 1020 | 47 | 35 |
| Example 2 | | | | | | | | | | |
| Comparative | 4.99 | 1.164 | 6.052 | 0.082 | 48 | 165.2 | 0.18 | 1065 | 29 | 28 |
| Example 3 | | | | | | | | | | |
| Comparative | 4.99 | 1.228 | 6.610 | 0.083 | 25 | 151.3 | 0.18 | 1010 | 21 | 28 |
| Example 4 | | | | | | | | | | |
| Comparative | 4.98 | 1.187 | 6.442 | 0.098 | 78 | 155.2 | 0.20 | 1045 | 53 | 54 |
| Example 5 | | | | | | | | | | |

From the above results, it is found that the polymers of Examples suppress the dark current in the photoelectric conversion element.

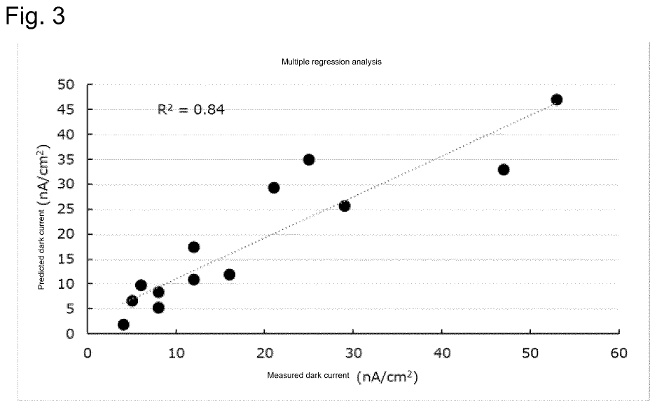

In addition, when the predicted dark current was plotted against the measured dark current, the coefficient of determination R² was as high as 0.84 (see FIG. 3). Therefore, it is understood that the specific side chain average formula amount and the absorption edge intensity of the polymer affect the suppression of dark current.

### DESCRIPTION OF REFERENCE SIGNS

10 Photoelectric conversion element
11 Support substrate
12 First electrode
13 First intermediate layer
14 Active layer
15 Intermediate layer
16 Second electrode
17 Sealing member

1. A polymer comprising a structural unit having a main chain and a side chain, wherein
a weighted average of formula weights of the side chains weighted by a molar ratio of the structural units contained in the polymer is 160 or more, and
an absorption edge intensity is 0.08 or less.

2. The polymer according to claim 1, wherein the side chain is at least one selected from the group consisting of an alkyl group optionally having a substituent, an aryl group optionally having a substituent, and a monovalent heterocyclic group optionally having a substituent.

3. The polymer according to claim 1, wherein the polymer contains at least one selected from the group consisting of a structural unit represented by the following Formula (I) and a structural unit represented by the following Formula (Y1). 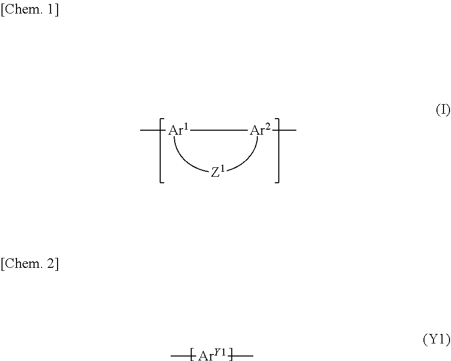
(in Formula (I),
Z¹ is a divalent group,
Ar¹ and Ar² each independently represent a trivalent aromatic hydrocarbon ring group or a trivalent heterocyclic group, and
in Formula (Y1), Ar^{Y1} represents an arylene group, a divalent heterocyclic group, or a divalent group in which an arylene group and a divalent heterocyclic group are bonded, and these groups optionally have a substituent.)

4. The polymer according to claim 3, wherein the polymer contains two different types of structural units represented by Formula (I).

5. The polymer according to claim 3, wherein in the structural unit represented by Formula (I), Z¹ is a group represented by the following Formula (Z-1), the following Formula (Z-2), the following Formula (Z-3), the following Formula (Z-4), the following Formula (Z-5), the following Formula (Z-6), or the following Formula (Z-7). 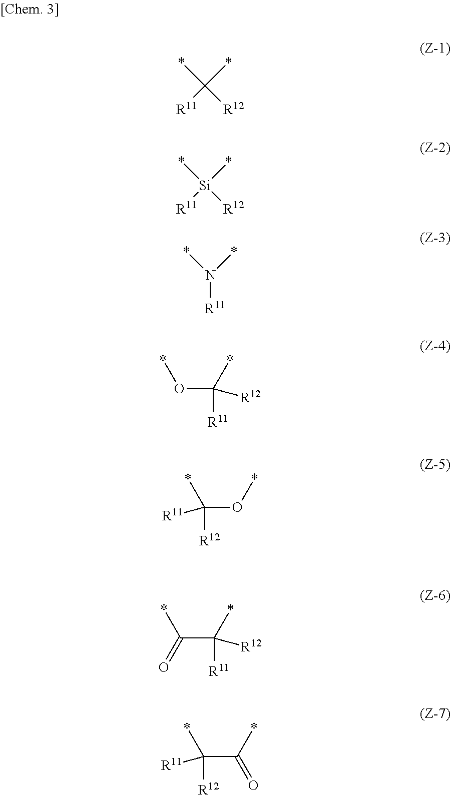
(in Formulas (Z-1) to (Z-7),
* represents a bond, and
R¹¹ and R¹² each independently represent a hydrogen atom or a monovalent group optionally having a substituent and may be the same as or different from each other.)

6. The polymer according to claim 3, wherein the structural unit represented by Formula (Y1) is a structural unit represented by the following Formula (Y1-B5), the following Formula (Y1-B6), the following Formula (Y1-B7), the following Formula (Y1-B8), the following Formula (Y1-B9), or the following Formula (Y1-B10). 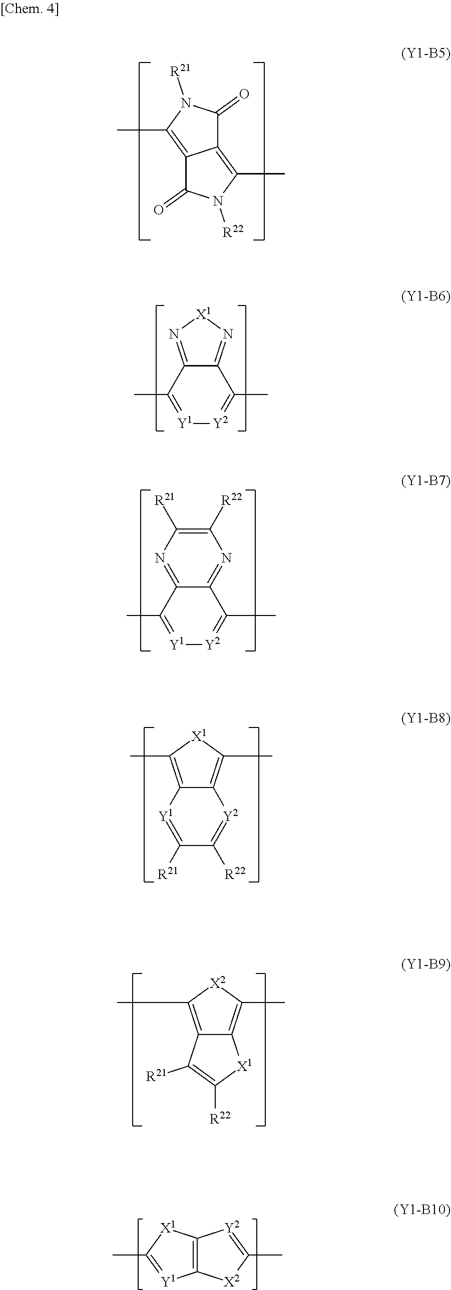
(in Formulas (Y1-B5) to (Y1-B10),
X¹ and X² each independently represent a sulfur atom, an oxygen atom, or a selenium atom,
Y¹ and Y² each independently represent a nitrogen atom or a group represented by ═CR^{2b}—, and
R²¹, R²², and R^{2b} each independently represent a hydrogen atom or a substituent.)

7. The polymer according to claim 5, wherein in Formulas (Z-1) to (Z-7), at least one of R¹¹ and R¹² is a group represented by the following Formula (SC). 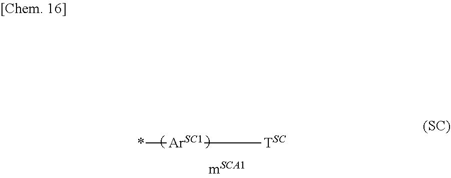
(in Formula (SC),
m^{SCA1} represents an integer of 1 or more and 10 or less,
Ar^{SC1} represents an arylene group optionally having a substituent, and
T^{SC} represents an aryl group optionally having a substituent.)

8. The polymer according to claim 3, wherein the structural unit represented by Formula (I) is a structural unit represented by the following Formula (I-8). 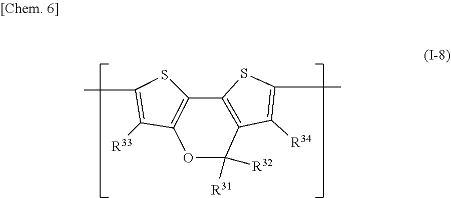
(in Formula (I-8), R³¹ to R³⁴ each independently represent a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, an amide group, an acid imide group, an imino group, an amino group, a silyl group, a silyloxy group, a silylthio group, a silylamino group, a heterocyclic group, a heterocyclic oxy group, a heterocyclic thio group, an arylalkenyl group, an arylalkynyl group, a carboxyl group, or a cyano group, and these groups optionally have a substituent.)

9. The polymer according to claim 1, wherein a weight average molecular weight is 6,000 or more.

10. A polymer comprising at least one selected from the group consisting of a structural unit represented by the following Formula (I) and a structural unit represented by the following Formula (Y1). 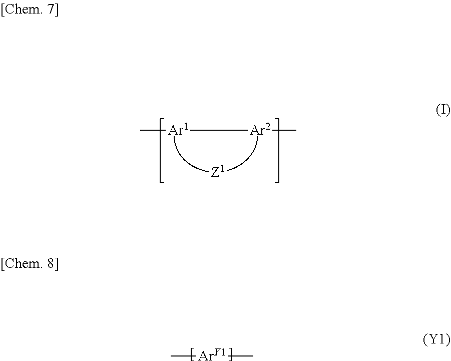
(in Formula (I),
Z¹ is a group represented by the following Formula (Z-1), the following Formula (Z-2), the following Formula (Z-3), the following Formula (Z-4), the following Formula (Z-5), the following Formula (Z-6), or the following Formula (Z-7), and
Ar¹ and Ar² each independently represent a trivalent aromatic hydrocarbon ring group or a trivalent heterocyclic group,
in Formula (Y¹), Ar^{Y1} represents an arylene group, a divalent heterocyclic group, or a divalent group in which an arylene group and a divalent heterocyclic group are bonded,
in the groups represented by the following Formulas (Z-1) to (Z-7), at least one of R¹¹ and R¹² is a group represented by the following Formula (SC), and
in Formula (SC), m^{SCA1} represents an integer of 1 or more and 10 or less, Ar^{SC1} represents an arylene group, T^{SC} represents an aryl group, and these groups optionally have a substituent.)

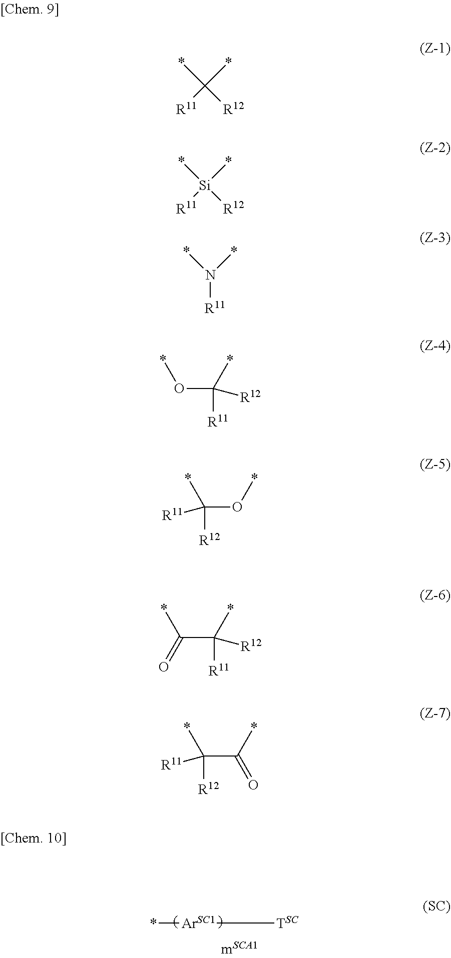

11. A film comprising the polymer according to claim 1.

12. The film according to claim 11, wherein the film contains an electron-accepting compound.

13. The film according to claim 12, wherein an absorption edge intensity is 0.17 or less.

14. A composition comprising the polymer according to claim 1 and an electron-accepting compound.

15. An ink comprising the polymer according to claim 1 and a solvent.

16. An electronic element comprising the polymer according to claim 1.

17. A photoelectric conversion element comprising:
a first electrode;
a second electrode; and
an active layer disposed between the first electrode and the second electrode,
wherein the active layer contains the polymer according to claim 1.

18. A solar cell module comprising the photoelectric conversion element according to claim 17.

19. An image sensor comprising the photoelectric conversion element according to claim 17.
